(19) United States
(12) Patent Application Publication
(10) Pub. No.: US 2018/0321589 A1
(43) Pub. Date: Nov. 8, 2018

(54) PATTERN FORMING METHOD AND METHOD FOR MANUFACTURING ELECTRONIC DEVICE

(71) Applicant: FUJIFILM Corporation, Tokyo (JP)

(72) Inventors: Tomotaka TSUCHIMURA, Haibara-gun (JP); Akihiro KANEKO, Haibara-gun (JP); Wataru NIHASHI, Haibara-gun (JP)

(73) Assignee: FUJIFILM Corporation, Tokyo (JP)

(21) Appl. No.: 16/039,450

(22) Filed: Jul. 19, 2018

Related U.S. Application Data
(63) Continuation of application No. PCT/JP2016/088303, filed on Dec. 22, 2016.

(30) Foreign Application Priority Data
Feb. 12, 2016 (JP) 2016-025352

(51) Int. Cl. G03F 7/038; G03F 7/40; H01L 21/027; G03F 7/20; G03F 7/16; G03F 7/32; C08F 212/14; C08F 220/58; C08F 220/16; C08F 212/32; G03F 7/039; G03F 7/38

(52) U.S. Cl. CPC G03F 7/038; G03F 7/40; H01L 21/0274; G03F 7/2004; G03F 7/2037; G03F 7/16; G03F 7/38; C08F 212/14; C08F 220/58; C08F 220/16; C08F 212/32; G03F 7/039; G03F 7/168; G03F 7/325

(57) ABSTRACT

The pattern forming method includes (1) a step of forming a film using an actinic ray-sensitive or radiation-sensitive resin composition, (2) a step of exposing the film with actinic rays or radiation, and (3) a step of developing the exposed film using a developer containing an organic solvent, in which the actinic ray-sensitive or radiation-sensitive resin composition contains an acid-decomposable resin (1) having a repeating unit (a) having an aromatic ring and a repeating unit (b) represented by a specific general formula, and the content of the repeating unit (a) is 55% by mole or more with respect to all the repeating units of the acid-decomposable resin (1). The method for manufacturing an electronic device includes the pattern forming method.

### CROSS-REFERENCE TO RELATED APPLICATIONS

This application is a Continuation of PCT International Application No. PCT/JP2016/088303 filed on Dec. 22, 2016, which claims priority under 35 U.S.C § 119(a) to Japanese Patent Application No. 2016-025352 filed on Feb. 12, 2016. Each of the above application(s) is hereby expressly incorporated by reference, in its entirety, into the present application.

### BACKGROUND OF THE INVENTION

### 1. Field of the Invention

The present invention relates to a pattern forming method and a method for manufacturing an electronic device.

More specifically, the present invention relates to a pattern forming method which is used for a process for manufacturing a semiconductor such as an IC, the manufacture of a circuit board for a liquid crystal, a thermal head, or the like, and other lithographic processes for photofabrication, and the like, as well as a method for manufacturing an electronic device, including the pattern forming method.

### 2. Description of the Related Art

In processes for manufacturing semiconductor devices such as an integrated circuit (IC) and a large scale integrated circuit (LSI) in the related art, microfabrication by lithography using a resist composition has been carried out. Formation of an ultrafine pattern in a submicron region or quarter-micron region has been demanded in accordance with realization of high integration for integrated circuits in recent years. With such a demand, exposure has been performed using g-rays in the related art, but it is now performed using i-rays, and further using KrF excimer laser light and a tendency that an exposure wavelength becomes shorter is observed. Moreover, developments in lithography using electron beams, X-rays, or extreme ultraviolet rays (EUV), in addition to the excimer laser light, has also been processing.

In such lithography, after a film has been formed with a resist composition, the obtained film has been formed developed with a developer.

For example, JP2008-292975A describes a pattern forming method in which a positive tone resist composition including a resin having an aromatic repeating unit and a repeating unit protected with an alicyclic protective group is applied onto a substrate, and the resultant is exposed and then developed using a negative tone developer.

JP2011-170316A describes a pattern forming method in which a resist composition including a polymer compound containing a repeating unit having a naphthol group which may be substituted with an acid-unstable group, an acid generator, and an organic solvent is applied onto a substrate, and the resultant is exposed, subjected to a heating treatment, and then developed using a developer including an organic solvent.

JP2015-081960A describes a pattern forming method in which a radiation-sensitive resin composition including a polymer including a structural unit including an acid-dissociative group and an aromatic repeating unit is applied onto a substrate, and the resultant is exposed and then developed using a developer including an organic solvent.

In addition, JP2014-034667A describes a pattern forming method in which a resist composition including a polymer having a repeating unit protected with an alicyclic protective group is applied onto a substrate, and the resultant is exposed and then developed using a developer including an organic solvent.

### SUMMARY OF THE INVENTION

In recent years, as higher novel functionality has been required for various types of electronic equipment, it has been required to manufacture finer wirings.

As the fineness of patterning is improved, the aspect ratio in the cross-section of a formed pattern tends to increase, and thus a pattern film easily collapses. As a result, it is necessary to set a solution to cope with the problem, such as reduction in the thickness of the pattern film.

However, as the thickness of the pattern film is smaller, it becomes difficult to obtain sufficient etching resistance, or particularly in a case where the pattern is an isolated pattern, for example, the pattern is removed unintentionally, and thus, it is difficult to obtain an expected resolution.

Furthermore, in a case where a resist film is exposed, particularly with EUV, exposure is usually performed under vacuum, and as a result, a gas derived from reaction products in an exposed area tends to easily occur from the resist film, and there is a concern that such the gas may also damage an exposure machine.

Therefore, a pattern formation method which expresses excellent performance in terms of all of resolution, dry etching resistance, and outgassing performance, in the formation of an isolated pattern which is a thin film and ultrafine has been required.

An object of the present invention is to provide a pattern forming method capable of forming a pattern which is excellent in all of resolution, dry etching resistance, and outgassing performance, particularly in formation of an isolated pattern which is a thin film (for example, with a thickness of 40 nm or less) and is ultrafine (for example, with a line width of 20 nm or less), and a method for manufacturing an electronic device, including the pattern forming method.

The present inventors have conducted extensive studies on the object, and as a result, they have found that the object can be accomplished by using an actinic ray-sensitive or radiation-sensitive resin composition including an acid-decomposable resin having a repeating unit having an aromatic ring structure in a specific amount or more and a repeating unit protected with a specific alicyclic structure.

That is, the present inventors have found that the objects of the present invention can be accomplished by the following configuration.

<1> A pattern forming method comprising:

(1) a step of forming a film using an actinic ray-sensitive or radiation-sensitive resin composition;

(2) a step of exposing the film with actinic rays or radiation; and

(3) a step of developing the exposed film using a developer containing an organic solvent,

in which the actinic ray-sensitive or radiation-sensitive resin composition contains an acid-decomposable resin (1) having a repeating unit (a) having an aromatic ring and a repeating unit (b) represented by General Formula (AI), and

the content of the repeating unit (a) is 55% by mole or more with respect to all the repeating units of the acid-decomposable resin (1).

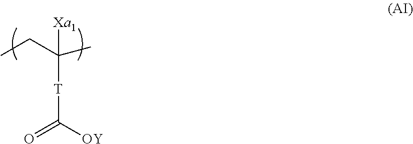

In General Formula (AI),

Xa₁ represents a hydrogen atom or an alkyl group.

T represents a single bond or a divalent linking group.

Y is a group that leaves by the action of an acid, and represents a group represented by General Formula (Y1).

—C(Rx1)(Rx2)(Rx3) General Formula (Y1):

In General Formula (Y1), Rx1 to Rx3 each independently represent an alkyl group or a cycloalkyl group, the total number of carbon atoms of Rx1 to Rx3 is 10 or less, and two of Rx1 to Rx3 are bonded to form a ring. The ring may include an ether bond or ester bond in the ring.

<2> The pattern forming method as described in <1>,

in which the acid-decomposable resin (1) has a repeating unit represented by General Formula (I) as the repeating unit (a).

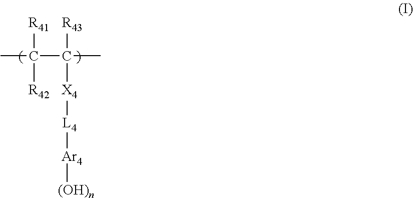

In General Formula (I),

R₄₁, R₄₂, and R₄₃ each independently represent a hydrogen atom, an alkyl group, a cycloalkyl group, a halogen atom, a cyano group, or an alkoxycarbonyl group, provided that R₄₂ may be bonded to Ar₄ to form a ring, and R₄₂ in such a case represents a single bond or an alkylene group.

X₄ represents a single bond, —COO—, or —CONR₆₄—, and R₆₄ represents a hydrogen atom or an alkyl group.

L₄ represents a single bond or a divalent linking group.

Ar₄ represents an (n+1)-valent aromatic ring group, and in a case where Ar₄ is bonded to R₄₂ to form a ring, it represents an (n+2)-valent aromatic ring group.

n represents an integer of 1 to 5.

<3> The pattern forming method as described in <1> or <2>,

in which the total number of carbon atoms of Rx1 to Rx3 of General Formula (Y1) of the repeating unit (b) is 8 or less.

<4> The pattern forming method as described in any one of <1> to <3>,

in which a ring formed by the bonding of two of Rx1 to Rx3 of General Formula (Y1) of the repeating unit (b) is a 5- or 6-membered ring.

<5> The pattern forming method as described in any one of <1> to <4>,

in which a ring formed by the bonding of two of Rx1 to Rx3 of General Formula (Y1) of the repeating unit (b) is a monocycle.

<6> The pattern forming method as described in any one of <1> to <5>,

in which the content of the repeating unit (a) of the acid-decomposable resin (1) is 70% by mole or more with respect to all the repeating units of the acid-decomposable resin (1).

<7> The pattern forming method as described in any one of <1> to <6>,

in which the actinic ray-sensitive or radiation-sensitive resin composition further includes a compound that generates an acid with actinic rays or radiation.

<8> The pattern forming method as described in any one of <1> to <7>,

in which the actinic rays or radiation is an electron beam or an extreme ultraviolet ray.

<9> The pattern forming method as described in any one of <1> to <8>,

in which the organic solvent is a ketone-based solvent or an ester-based solvent.

<10> The pattern forming method as described in any one of <1> to <9>, further comprising a step (4) of rinsing the developed film after the step (3).

<11> A method for manufacturing an electronic device, comprising the pattern forming method as described in any one of <1> to <10>.

According to the present invention, it is possible to provide a pattern forming method capable of forming a pattern which is excellent in all of resolution, dry etching resistance, and outgassing performance, particularly in formation of an isolated pattern which is a thin film (for example, with a thickness of 40 nm or less) and is ultrafine (for example, with a line width of 20 nm or less), and a method for manufacturing an electronic device, including the pattern forming method.

### DESCRIPTION OF THE PREFERRED EMBODIMENTS

Hereinafter, embodiments for carrying out the present invention will be described.

In citations for a group and an atomic group in the present specification, in a case where the group is denoted without specifying whether it is substituted or unsubstituted, the group includes both a group and an atomic group not having a substituent, and a group and an atomic group having a substituent. For example, an “alkyl group” which is not denoted about whether it is substituted or unsubstituted includes not only an alkyl group not having a substituent (unsubstituted alkyl group), but also an alkyl group having a substituent (substituted alkyl group).

In the present invention, “actinic rays” or “radiation” means, for example, a bright line spectrum of a mercury lamp, far ultraviolet rays typified by an excimer laser, extreme ultraviolet rays (EUV light), X-rays, and particle rays such as electron beams and ion beams, or the like. In addition, in the present invention, “light” means actinic rays or radiation.

Furthermore, “exposure” in the present specification includes, unless otherwise specified, not only exposure by a bright line spectrum of a mercury lamp, far ultraviolet rays typified by an excimer laser, X-rays, extreme ultraviolet rays (EUV), or the like, but also lithography by particle rays such as electron beams and ion beams.

In the present specification, “(meth)acrylate” means “at least one of acrylate or methacrylate”. Similarly, “(meth)acrylic acid” means “at least one of acrylic acid or methacrylic acid”.

In the present specification, “(a value) to (a value)” means a range including the numerical values described before and after “to” as a lower limit value and an upper limit value, respectively.

In the present specification, the weight-average molecular weight of the resin is a value measured in terms of polystyrene by a gel permeation chromatography (GPC) method. GPC can be in accordance with a method using HLC-8120 (manufactured by Tosoh Corporation), TSK gel Multipore HXL-M (manufactured by Tosoh Corporation, 7.8 mmID×30.0 cm) as a column, and tetrahydrofuran (THF) as an eluent.

<Pattern Forming Method>

The pattern forming method of the present invention includes:

(1) a step of forming a film using an actinic ray-sensitive or radiation-sensitive resin composition (film forming step),

(2) a step of exposing the film with actinic rays or radiation (exposing step), and

(3) a step of developing the exposed film using a developer containing an organic solvent (developing step),

in which the actinic ray-sensitive or radiation-sensitive resin composition has an acid-decomposable resin (1) having a repeating unit (a) (hereinafter also referred to as a “repeating unit (a)”) having an aromatic ring and a repeating unit (b) represented by General Formula (AI) (hereinafter also referred to as a “repeating unit (b)”), and

the content of the repeating unit (a) is 55% by mole or more with respect to all the repeating units of the acid-decomposable resin (1).

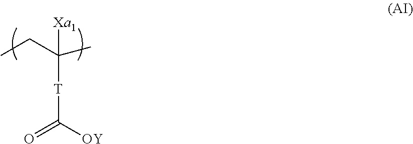

In General Formula (AI),

Xa₁ represents a hydrogen atom or an alkyl group.

T represents a single bond or a divalent linking group.

Y is a group that leaves by the action of an acid, and represents a group represented by General Formula (Y1).

—C(Rx1)(Rx2)(Rx3) General Formula (Y1):

In General Formula (Y1), Rx1 to Rx3 each independently represent an alkyl group or a cycloalkyl group, the total number of carbon atoms of Rx1 to Rx3 is 10 or less, and two of Rx1 to Rx3 are bonded to form a ring. The ring may include an ether bond or ester bond in the ring.

Thus, it is possible to form a pattern which is excellent in all of resolution, dry etching resistance, and outgassing performance.

Details of a reason why the object can be accomplished according to the present invention are not clear, but the present inventors have presumed that the reason would be as follows.

According to the pattern forming method of the present invention, first, the acid-decomposable resin in an actinic ray-sensitive or radiation-sensitive resin composition has a repeating unit represented by General Formula (AI). Here, Y which is a group that leaves by the action of an acid is represented by General Formula (Y1), the total number of carbon atoms of Rx1 to Rx3 is 10 or less, and the number of carbon atoms of the group that leaves by the action of an acid is suppressed. In a case where the number of carbon atoms constituting the group that leaves by the action of an acid, the amount of the leaving components increases, and thus, the resist film before exposure is easily shrunk (a shrink amount increases) after exposure and development. As a result, particularly, the resolution or the dry etching resistance of an isolated pattern is easily reduced. Further, as the amount of the leaving components increases, there is a concern that the amount of a gas (outgas) generated from the leaving components may increase.

On the other hand, in the present invention, as the number of carbon atoms of the group that leaves by the action of an acid is suppressed as described above, the shrink amount is suppressed. As a result, it is thought the resolution and the dry etching resistance are improved, particularly in formation of an isolated pattern which is a thin film (for example, with a thickness of 40 nm or less) and is ultrafine (for example, with a line width of 20 nm or less). Further, it is thought that the outgassing performance is also improved.

Moreover, in the present invention, two of Rx1 to Rx3 in General Formula (Y1) are bonded to form a ring. In a case where two of Rx1 to Rx3 are not bonded to form a ring, there is tendency that the glass transition point (Tg) of the resist film is lowered, as compared with a case of forming the ring. Thus, an acid generated from a photoacid generator (PAG) in an exposed area is easily diffused into an unexposed area, and particularly, the resolution of the isolated pattern is easily reduced. On the other hand, in the present invention, it is thought that since two of Rx1 to Rx3 in General Formula (Y1) are bonded to form a ring, and thus, the glass transition point of the resist film is suppressed from being lowered, the excessive diffusion of an acid into an unexposed area is suppressed, and thus, the resolution is improved, particularly in the formation of the isolated pattern which is a thin film and is ultrafine.

In addition, in the present invention, the content of the repeating unit having an aromatic ring included in the acid-decomposable resin (1) in the actinic ray-sensitive or radiation-sensitive resin composition is 55 mol % or more with respect to all the repeating units of the acid-decomposable resin (1). The repeating unit having an aromatic ring contributes to dry etching resistance, and in a case where the content of the repeating unit is less than 55 mol %, there is tendency that the dry etching resistance is reduced. In the present invention, it is thought that since the content of the repeating unit having an aromatic ring is 55 mol % or more with respect to all the repeating units of the acid-decomposable resin (1), the dry etching resistance is improved, particularly in the formation of the isolated pattern which is a thin film and is ultrafine.

[Film Forming Step]

A film forming step is a step of forming a film (resist film) using an actinic ray-sensitive or radiation-sensitive resin composition, and can be carried out by the following method, for example. Further, the actinic ray-sensitive or radiation-sensitive resin composition will be described later.

In order to form a resist film on a substrate, using an actinic ray-sensitive or radiation-sensitive resin composition, it is preferable that the respective components which will be described later are dissolved in a solvent to prepare an actinic ray-sensitive or radiation-sensitive resin composition, filtered using a filter, as desired, and then applied onto a substrate. As the filter, a polytetrafluoroethylene-, polyethylene-, or nylon-made filter having a pore size of preferably 0.1 μm or less, more preferably 0.05 μm or less, and still more preferably 0.03 μm or less is preferable.

The actinic ray-sensitive or radiation-sensitive resin composition is applied onto a substrate (example: silicon/silicon dioxide coating) for use in the manufacture of an integrated circuit element by a suitable coating method such as use of a spinner. Then, the resultant is dried to form a resist film. As desired, various underlying films (inorganic films, organic films, and antireflection films) may also be formed on the underlayer of the resist film.

As the drying method, a method involving drying by heating is generally used. Heating may be carried out using an ordinary means installed in an exposure machine or a development machine, or may also be carried out using a hot plate, or the like. The heating is carried out at a heating temperature of preferably 80° C. to 150° C., more preferably 80° C. to 140° C., and still more preferably 80° C. to 130° C. The heating time is preferably 30 to 1,000 seconds, more preferably 60 to 800 seconds, and still more preferably 60 to 600 seconds.

The film thickness of the resist film is generally 200 nm or less, and preferably 10 nm or less.

For example, in order to resolve a 1:1 line-and-space pattern with a line width of 20 nm or less, the film thickness of a formed resist film is preferably 40 nm or less. In a case where the film thickness is 40 nm or less, it is more difficult for pattern collapse to occur upon application of a development step which will be described later, and thus, superior resolving performance is obtained.

A range of the film thickness is more preferably 15 nm to 40 nm. In the film thickness is 15 nm or more, sufficient etching resistance is obtained. In a case where the film thickness falls within this range, etching resistance and superior resolving performance can be simultaneously satisfied.

Furthermore, in the pattern forming method of the present invention, an upper layer film (topcoat) may be formed on the upper layer of the resist film. It is preferable that the topcoat is not mixed with the resist film, and can be uniformly on the upper layer of the resist film.

[Composition for Forming Topcoat]

A composition for forming a topcoat (a composition for forming an upper layer film) will be described.

It is preferable that the topcoat (upper layer film) is not mixed with the resist film, and can be uniformly on the upper layer of the resist film.

The topcoat is not particularly limited, a topcoat known in the related art can be formed by a method known in the related art, and the topcoat can be formed in accordance with, for example, the descriptions in paragraphs 0072 to 0082 of JP2014-059543A.

It is preferable that a topcoat containing the basic compound described in JP2013-61648A, for example, is formed on the resist film. Specific examples of the basic compound that be contained in the topcoat are the same as those of the basic compound in the actinic ray-sensitive or radiation-sensitive resin composition.

Furthermore, it is preferable that the topcoat includes a compound including at least one group or bond selected from the group consisting of an ether bond, a thioether bond, a hydroxyl group, a thiol group, a carbonyl bond, an ester bond.

Moreover, it is preferable that the topcoat contains a resin. The resin that can be contained in the topcoat is not particularly limited, but the same resins as a hydrophobic resin that can be included in the resist composition can be used.

With regard to the hydrophobic resin, reference can be made to <0017> to <0023> of JP2013-61647A (<0017> to <0023> of the corresponding US2013/244438A), and <0016> to <0165> of JP2014-56194A, the contents of which are incorporated herein by reference.

It is preferable that the topcoat includes a resin containing a repeating unit having an aromatic ring. By incorporation of the repeating unit having an aromatic ring, secondary electron generation efficiency and acid generation efficiency from a compound that generates an acid with actinic rays or radiation increase, particularly during exposure with electron beams or EUV, and thus, during pattern formation, an effect of realization of high sensitivity and high resolution can be expected.

In a case where the resin is used in ArF the liquid immersion exposure, it is preferable that the resin substantially does not have an aromatic group in a view of transparency to ArF light.

The weight-average molecular weight of the resin is preferably 3,000 to 100,000, still more preferably 3,000 to 30,000, and most preferably 5,000 to 20,000. The blend amount of the resin in the composition for forming a topcoat is preferably 50% to 99.9% by mass, more preferably 70% to 99.7% by mass, and still more preferably 80% to 99.5% by mass, in the total solid content.

In a case where the topcoat includes a plurality of resins, it is preferable that the topcoat includes at least one resin (XA) having a fluorine atom and/or a silicon atom. It is more preferable that the composition for forming a topcoat includes at least one resin (XA) having a fluorine atom and/or a silicon atom, and a resin (XB) having a smaller content of the fluorine atom and/or the silicon atom than that of the resin (XA). Thus, at a time of forming the topcoat film, the resin (XA) is localized on the surface of a topcoat film, and therefore, performance such as development characteristics and immersion liquid tracking properties can be improved.

The content of the resin (XA) is preferably 0.01% to 30% by mass, more preferably 0.1% to 10% by mass, still more preferably 0.1% to 8% by mass, and particularly preferably 0.1% to 5% by mass, with respect to the total solid content included in the composition for forming a topcoat. The content of the resin (XB) is preferably 50.0% to 99.9% by mass, more preferably 60% to 99.9% by mass, still more preferably 70% to 99.9% by mass, and particularly preferably 80% to 99.9% by mass, with respect to the total solid content included in the composition for forming a topcoat.

A preferred range of the fluorine atom contained in the resin (XA) is preferably 5% to 80% by mass, and more preferably 10% to 80% by mass, with respect to the weight-average molecular weight of the resin (XA).

A preferred range of the silicon atom contained in the resin (XA) is preferably 2% to 50% by mass, and more preferably 2% to 30% by mass, with respect to the weight-average molecular weight of the resin (XA).

An embodiment that the resin (XB) substantially does not a fluorine atom and a silicon atom is preferable, and in this case, specifically, the total content of the repeating unit having a fluorine atom and the repeating unit having a silicon atom is preferably 0% to 20% by mole, more preferably 0% to 10% by mole, still more preferably 0% to 5% by mole, and particularly preferably 0% to 3% by mole, and ideally 0% by mole, that is, not containing a fluorine atom and a silicon atom, with respect to all the repeating units in the resin (XB).

The blend amount of the resin in the entire composition for forming a topcoat is preferably 50% to 99.9% by mass, and more preferably 60% to 99.0% by mass, in the total solid content.

Moreover, the topcoat may contain an acid generator, a basic compound, a surfactant, a crosslinking agent, or the like. As the acid generator, the basic compound, the surfactant, the crosslinking agent, or the like, any of known ones can be employed, and particularly, specific and preferred examples of the acid generator, the basic compound, and the surfactant include the specific and preferred examples of the photoacid generator, the basic compound, and the surfactant which will be described later in the description of the actinic ray-sensitive or radiation-sensitive resin composition.

The topcoat is typically formed with the composition for forming a topcoat.

For the composition for forming a topcoat, it is preferable that the respective components are dissolved in a solvent (topcoat solvent), and the solution is filtered through a filter. The filter is preferably a polytetrafluoroethylene-, polyethylene-, or nylon-made filter having a pore size of 0.1 μm or less, more preferably 0.05 μm or less, and still more preferably 0.03 μm or less. Further, two or more kinds of filters may be connected in series or in parallel, and used. Incidentally, the composition may be filtered a plurality of times, and a step of filtering plural times may be a circulatory filtration step. Incidentally, the composition may also be subjected to a deaeration treatment or the like before and after the filtration through the filter. It is preferable that the composition for forming a topcoat of the present invention does not include impurities such as a metal. The content of the metal components included in these materials is preferably 10 ppm or less, more preferably 5 ppm or less, and still more preferably 1 ppm or less, but the materials substantially not having the metal components (at a detection limit of a measurement device or less) is particularly preferable.

Examples of the metals and the like as the impurities include Na, K, Ca, Fe, Cu, Mn, Mg, Al, Cr, Ni, Zn, Ag, Sn, Pb, Li, or salts thereof.

In a case where the exposure which will be described later is a liquid immersion exposure, the topcoat is arranged between the resist film and the immersion liquid, and the resist film functions as a layer which is not brought into direct contact with the immersion liquid. In this case, preferred characteristics required for the topcoat (composition for forming a topcoat) are coating suitability onto the resist film, radiation, transparency, particularly to light at 193 nm, and poor solubility in an immersion liquid (preferably water). Further, it is preferable that the topcoat can be uniformly applied onto the surface of the resist film while not being mixed with the resist film.

Moreover, in order to uniformly apply the composition for forming a topcoat onto the surface of the resist film while not dissolving the resist film, it is preferable that the composition for forming a topcoat contains a solvent in which the resist film is not dissolved. It is more preferable that as the solvent in which the resist film is not dissolved, a solvent of components other than a developer containing an organic solvent (organic developer) is used.

A method for coating the composition for forming a topcoat is not particularly limited, a spin coating method, a spray method, a roll coating method, a dip method, or the like, which has been known in the related art, can be used.

The film thickness of the topcoat is not particularly limited, but from the viewpoint of transparency to an exposure light source, the film is formed, which has a thickness of usually 5 nm to 300 nm, preferably 10 nm to 300 nm, more preferably 20 nm to 200 nm, and still more preferably 30 nm to 100 nm.

After forming the topcoat, the substrate is heated, if desired.

From the viewpoint of resolution, it is preferable that the refractive index of the topcoat is close to that of the resist film.

The topcoat is preferably insoluble in an immersion liquid, and more preferably insoluble in water.

With regard to a receding contact angle of the topcoat, the receding contact angle (23° C.) of an immersion liquid onto the topcoat is preferably 50 to 100 degrees, and more preferably 80 to 100 degrees, from the viewpoint of immersion liquid tracking properties.

In the liquid immersion exposure, from the viewpoint that the immersion liquid needs to move on a wafer following the movement of an exposure head that is scanning the wafer at a high speed and forming an exposure pattern, the contact angle of the immersion liquid with respect to the topcoat in a dynamic state is important, and in order to obtain better resist performance, the immersion liquid preferably has a receding contact angle in the above range.

In a case where the topcoat is released, an organic developer may be used, and another release agent may also be used. As the release agent, a solvent hardly permeating the resist film is preferable. In a view that the release of the topcoat can be carried out simultaneously with the development of the resist film, the topcoat is preferably releasable with an organic developer. The organic developer used for release is not particularly limited as long as it makes it possible to dissolve and remove a less exposed area of the resist film.

From the viewpoint of release with an organic developer, the dissolution rate of the topcoat in the organic developer is preferably 1 to 300 nm/sec, and more preferably 10 to 100 nm/sec.

Here, the dissolution rate of a topcoat in the organic developer refers to a film thickness decreasing rate in a case where the topcoat is exposed to a developer after film formation, and is a rate in a case where immersing in a butyl acetate solution at 23° C. in the present invention.

An effect of reducing development defects after developing a resist film is accomplished by setting the dissolution rate of a topcoat in the organic developer to 1 nm/sec or more, and preferably 10 nm/sec or more. Further, an effect that the line edge roughness of a pattern after the development of the resist film is improved is accomplished by the influence of reduction in the exposure unevenness during liquid immersion exposure by setting the dissolution rate to 300 nm/sec or less, and preferably 100 nm/sec or less.

The topcoat may also be removed using other known developers, for example, an aqueous alkali solution. Specific examples of the usable aqueous alkali solution include an aqueous tetramethylammonium hydroxide solution.

A step of applying a pre-wetting solvent on the resist film may be included in the pattern forming method of the present invention. Thus, the coatability of the composition for forming a topcoat is improved, and thus, saving liquefaction can be achieved.

The pre-wetting solvent is not particularly limited as long as it has a small solubility for the resist film, but a pre-wetting solvent for an upper layer film, containing at least one compound selected from an alcohol-based solvent, a fluorine-based solvent, an ether-based solvent, a hydrocarbon-based solvent, or an ester-based solvent can be used.

These solvents are used singly or as a mixture of a plurality thereof. By mixing a solvent other than the above-mentioned solvents, the solubility in the resist film, the solubility of the resin in the topcoat composition, the elution characteristics from the resist film, or the like can be appropriately adjusted.

[Exposing Step]

The exposing step is a step of exposing the resist film, can be carried out, for example, the following method.

A resist film formed as described above is irradiated with actinic rays or radiation through a predetermined mask. Further, in the irradiation with electron beams, lithography which is not conducted through a mask (direct lithography) is generally used.

Actinic rays or radiation is not particularly limited, but is, for example, KrF excimer laser, ArF excimer laser, extreme ultraviolet rays (EUV), electron beams (EB), or the like, and particularly preferably extreme ultraviolet rays or electron beams. The exposure may be liquid immersion exposure.

[Baking]

In the pattern forming method of the present invention, baking (heating) is preferably carried out after the exposure and before performing the development. By the baking, the reaction in the exposed areas is accelerated, and thus, the sensitivity or the pattern shape is improved.

The heating temperature is preferably 80° C. to 150° C., more preferably 80° C. to 140° C., and still more preferably 80° C. to 130° C.

The heating time is preferably 30 to 1,000 seconds, more preferably 60 to 800 seconds, and still more preferably 60 to 600 seconds.

The heating can be carried out by a means equipped in a normal exposure or development machine, and may also be carried out by using a hot plate or the like.

[Developing Step]

The developing step is a step of developing the exposed resist film with a developer containing an organic solvent (hereinafter also referred to as a “developing step using an organic developer” in some cases).

Hereinafter, an organic solvent included in the developer containing an organic solvent (organic developer) will be described.

The vapor pressure (total vapor pressure in a case of a mixed solvent) of the organic solvent is preferably 5 kPa or less, more preferably 3 kPa or less, and particularly preferably 2 kPa or less, at 20° C. By setting the vapor pressure of the organic solvent to 5 kPa or less, the evaporation of the developer on a substrate or in a development cup is suppressed, and the temperature evenness within a wafer plane is improved, whereby the dimensional evenness within a wafer plane is enhanced.

As the organic solvent used in the organic developer, various organic solvents are widely used, and solvents such as an ester-based solvent, a ketone-based solvent, an alcohol-based solvent, an amide-based solvent, an ether-based solvent, and a hydrocarbon-based solvent, for example, can be used.

As the organic solvent, at least one organic solvent selected from the group consisting of a hydrocarbon-based solvent, a ketone-based solvent, an ester-based solvent, an alcohol-based solvent, an amide-based solvent, an ether-based solvent, and an organic solvent containing at least one of a fluorine atom or a silicon atom is preferable, a hydrocarbon-based solvent, an ester-based solvent, or a ketone-based solvent is more preferable, and an ester-based solvent or a ketone-based solvent is still more preferable. From the viewpoint of suppression of permeation into the resist film, a hydrocarbon-based solvent having 5 or more carbon atoms or a ketone-based solvent having 5 or more carbon atoms is more preferable, and a hydrocarbon-based solvent having 7 or more carbon atoms or a ketone-based solvent having 7 or more carbon atoms is particularly preferable.

The ester-based solvent refers to a solvent having an ester bond in the molecule, the ketone-based solvent refers to a solvent having a ketone group in the molecule, the alcohol-based solvent refers to a solvent having an alcoholic hydroxyl group in the molecule, the amide-based solvent refers to a solvent having an amido group in the molecule, and the ether-based solvent refers to a solvent having an ether bond in the molecule. Among these, a solvent having a plurality of functional groups described above in one molecule may also be present, but in this case, it is assumed that the solvent also corresponds to any solvent type including the functional group which the solvent has. For example, it is assumed that diethylene glycol monomethyl ether also corresponds to any of the alcohol-based solvent and the ether-based solvent in the above classification. In addition, the hydrocarbon-based solvent is a hydrocarbon solvent having no substituent.

Examples of the hydrocarbon-based solvent include aliphatic hydrocarbon-based solvents such as pentane, hexane, octane, nonane, decane, dodecane, undecane, and hexadecane, aromatic hydrocarbon-based solvents such as toluene, xylene, ethylbenzene, propylbenzene, 1-methylpropylbenzene, 2-methylpropylbenzene, dimethylbenzene, diethylbenzene, ethylmethylbenzene, trimethylbenzene, ethyldimethylbenzene, and dipropylbenzene, branched aliphatic hydrocarbon-based solvents such as 2,2,4-trimethylpentane, 2,2,3-trimethylhexane, isohexane, isoheptane, isooctane, isodecane, isododecane, isoundecane, isohexadecane, isotetradecane, isopentadecane, limonene, isopropylcyclopentane, and tert-butylcyclohexane, and unsaturated hydrocarbon-based solvents such as octene, nonene, decene, undecene, dodecene, and hexadecene.

Double bonds or triple bonds contained in the unsaturated hydrocarbon solvent may be present in plural numbers, and may be present in any position in the hydrocarbon chain. Cis isomers and Trans isomers due to the presence of the double bonds may be present in mixture.

Furthermore, the hydrocarbon-based solvent may be a mixture of compounds having the same carbon atoms and different structures. For example, in a case where decane is used as the aliphatic hydrocarbon-based solvent, 2-methylnonane, 2,2-dimethyloctane, 4-ethyloctane, isodecane, or the like, which is a compound having the same carbon atoms and different structures, may be included in the aliphatic hydrocarbon-based solvent.

Incidentally, one kind of the compound having the same carbon atoms and different structures may be included, or a plurality of kinds of the compound as described above may be included.

The hydrocarbon-based solvent preferably has 5 or more carbon atoms, more preferably 7 or more carbon atoms, and still more preferably 10 or more carbon atoms. The hydrocarbon-based solvent is preferably, for example, decane, undecane, isodecane, isododecane, isoundecane, isohexadecane, isotetradecane, or isopentadecane, and particularly preferably decane or undecane. The treatment liquid of the present invention particularly preferably includes at least one of decane or undecane. By incorporation of a branched aliphatic hydrocarbon-based solvent having 10 or more carbon atoms, it is possible to achieve both good pattern collapse characteristics and good bridge characteristics.

The upper limit value in the number of carbon atoms of the hydrocarbon-based solvent is not particularly limited, but may be, for example, 16 or less, preferably 14 or less, and more preferably 12 or less. Thus, the dry efficiency during spin drying is improved, and thus, the defect generation in a wafer plane can be suppressed.

Examples of the ester-based solvent can include methyl acetate, ethyl acetate, butyl acetate, isobutyl acetate, pentyl acetate, propyl acetate, isopropyl acetate, amyl acetate (pentyl acetate), isoamyl acetate (isopentyl acetate, 3-methylbutyl acetate), 2-methylbutyl acetate, 1-methylbutyl acetate, hexyl acetate, heptyl acetate, octyl acetate, methoxyethyl acetate, ethoxyethyl acetate, butyl butyrate, methyl 2-hydroxyisobutyrate, propylene glycol monomethyl ether acetate (PGMEA; also referred to as 1-methoxy-2-acetoxypropane), ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monoethyl ether acetate, diethylene glycol monophenyl ether acetate, diethylene glycol monobutyl ether acetate, diethylene glycol monoethyl ether acetate, 2-methoxybutylacetate, 3-methoxybutylacetate, 4-methoxybutylacetate, 3-methyl-3-methoxybutylacetate, 3-ethyl-3-methoxybutylacetate, propylene glycol monoethyl ether acetate, propylene glycol monopropyl ether acetate, 2-ethoxybutylacetate, 4-ethoxybutylacetate, 4-propoxybutylacetate, 2-methoxypentylacetate, 3-methoxypentylacetate, 4-methoxypentylacetate, 2-methyl-3-methoxypentylacetate, 3-methyl-3-methoxypentylacetate, 3-methyl-4-methoxypentylacetate, 4-methyl-4-methoxypentylacetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, butyl propionate, pentyl propionate, hexyl propionate, heptyl propionate, butyl butanoate, isobutyl butanoate, pentyl butanoate, hexyl butanoate, isobutyl isobutanoate, propyl pentanoate, isopropyl pentanoate, butyl pentanoate, pentyl pentanoate, ethyl hexanoate, propyl hexanoate, butyl hexanoate, isobutyl hexanoate, methyl heptanoate, ethyl heptanoate, propyl heptanoate, cyclohexyl acetate, cycloheptyl acetate, 2-ethylhexyl acetate, cyclopentylpropionate, methyl 2-hydroxypropionate, ethyl 2-hydroxypropionate, methyl-3-methoxypropionate, ethyl-3-methoxypropionate, ethyl-3-ethoxypropionate, and propyl-3-methoxypropionate. Among these, butyl acetate, amyl acetate, isoamyl acetate, 2-methylbutyl acetate, 1-methylbutyl acetate, hexyl acetate, pentyl propionate, hexyl propionate, heptyl propionate, or butyl butanoate is preferably used, and butyl acetate or isoamyl acetate is particularly preferably used.

Examples of the ketone-based solvent include 1-octanone, 2-octanone, 1-nonanone, 2-nonanone, acetone, 2-heptanone, 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonylacetone, ionone, diacetonyl alcohol, acetyl carbinol, acetophenone, methyl naphthyl ketone, isophorone, propylene carbonate, and γ-butyrolactone, and among those, diisobutyl ketone is preferable.

Furthermore, the ketone-based solvent may be a ketone-based solvent having a branched alkyl group. The ketone-based solvent having a branched alkyl group is a solvent having a branched alkyl group and a ketone group in the molecule, and preferably a cyclic aliphatic ketone-based solvent having a branched alkyl group or an acyclic aliphatic ketone-based solvent having a branched alkyl group.

Examples of the cyclic aliphatic ketone-based solvent having a branched alkyl group include 2-isopropylcyclohexanone, 3-isopropylcyclohexanone, 4-isopropylcyclohexanone, 2-isopropylcycloheptanone, 3-isopropylcycloheptanone, 4-isopropylcycloheptanone, and 2-isopropylcyclooctanone.

Examples of the acyclic aliphatic ketone-based solvent having a branched alkyl group include diisohexyl ketone, methyl isopentyl ketone, ethyl isopentyl ketone, propyl isopentyl ketone, diisopentyl ketone, methyl isobutyl ketone, ethyl isobutyl ketone, propyl isobutyl ketone, diisobutyl ketone, diisopropyl ketone, ethyl isopropyl ketone, and methyl isopropyl ketone, and the acyclic aliphatic ketone-based solvent having a branched alkyl group is particularly preferably diisobutyl ketone.

Examples of the alcohol-based solvent include alcohols (monovalent alcohols) such methanol, ethanol, 1-propanol, isopropanol, 1-butanol, 2-butanol, 3-methyl-1-butanol, tert-butyl alcohol, 1-pentanol, 2-pentanol, 1-hexanol, 1-heptanol, 1-octanol, 1-decanol, 2-hexanol, 2-heptanol, 2-octanol, 3-hexanol, 3-heptanol, 3-octanol, 4-octanol, 3-methyl-3-pentanol, cyclopentanol, 2,3-dimethyl-2-butanol, 3,3-dimethyl-2-butanol, 2-methyl-2-pentanol, 2-methyl-3-pentanol, 3-methyl-2-pentanol, 3-methyl-3-pentanol, 4-methyl-2-pentanol, 4-methyl-3-pentanol, cyclohexanol, 5-methyl-2-hexanol, 4-methyl-2-hexanol, 4,5-dimethyl-2-hexanol, 6-methyl-2-heptanol, 7-methyl-2-octanol, 8-methyl-2-nonanol, 9-methyl-2-decanol, and 3-methoxy-1-butanol, glycol-based solvents such as ethylene glycol, diethylene glycol, and triethylene glycol, and hydroxyl group-containing glycol ether-based solvents such as ethylene glycol monomethyl ether, propylene glycol monomethyl ether (PGME; also referred to as 1-methoxy-2-propanol), diethylene glycol monomethyl ether, triethylene glycol monoethyl ether, methoxymethylbutanol, ethylene glycol monoethyl ether, ethylene glycol monopropyl ether, ethylene glycol monobutyl ether, propylene glycol monoethyl ether, propylene glycol monopropyl ether, propylene glycol monobutyl ether, and propylene glycol monophenyl ether. Among these, the glycol ether-based solvent is preferably used.

Examples of the ether-based solvent include glycol ether-based solvents having no hydroxyl group, such as propylene glycol dimethyl ether, propylene glycol diethyl ether, dipropylene glycol dimethyl ether, dipropylene glycol diethyl ether, diethylene glycol dimethyl ether, and diethylene glycol diethyl ether, aromatic ether solvents such as anisole and phenetole, dioxane, tetrahydrofuran, tetrahydropyran, perfluoro-2-butyltetrahydrofuran, perfluorotetrahydrofuran, and 1,4-dioxane, in addition to the glycol ether-based solvents containing a hydroxyl group. Other examples thereof include a cyclic aliphatic ether-based solvent having a branched alkyl group, such as cyclopentylisopropyl ether, cyclopentyl sec-butyl ether, cyclopentyl tert-butyl ether, cyclohexylisopropyl ether, cyclohexyl sec-butyl ether, and cyclohexyl tert-butyl ether, an acyclic aliphatic ether-based solvent having a linear alkyl group, such as di-n-propyl ether, di-n-butyl ether, di-n-pentyl ether, and di-n-hexyl ether, and an acyclic aliphatic ether-based solvent having a branched alkyl group, such as diisohexyl ether, methylisopentyl ether, ethylisopentyl ether, propylisopentyl ether, diisopentyl ether, methylisobutyl ether, ethylisobutyl ether, propylisobutyl ether, diisobutyl ether, diisopropyl ether, ethylisopropyl ether, and methylisopropyl ether. Among those, from the viewpoint of uniformity in the wafer plane, an acyclic aliphatic ether-based solvent having 8 to 12 carbon atoms is preferable, an acyclic aliphatic ether-based solvent having a branched alkyl group having 8 to 12 carbon atoms is more preferable, and diisobutyl ether, diisopentyl ether, or diisohexyl ether is particularly preferable.

As the amide-based solvent, for example, N-methyl-2-pyrrolidone, N,N-dimethylacetamide, N,N-dimethylformamide, hexamethylphosphoric triamide, and 1,3-dimethyl-2-imidazolidinone can be used.

In a case of using EUV and EB in the exposing step, the organic solvent included in the organic developer preferably uses an ester-based solvent having 7 or more carbon atoms (preferably 7 to 14 carbon atoms, more preferably 7 to 12 carbon atoms, and still more preferably 7 to 10 carbon atoms) and 2 or less heteroatoms in a view that swelling of the resist film can be suppressed.

The heteroatom of the ester-based solvent is an atom other than a carbon atom and a hydrogen atom, and examples thereof include an oxygen atom, a nitrogen atom, and a sulfur atom. The number of heteroatoms is preferably 2 or less.

Preferred examples of the ester-based solvent having 7 or more carbon atoms and 2 or less heteroatoms include amyl acetate, isoamyl acetate, 2-methylbutyl acetate, 1-methylbutyl acetate, hexyl acetate, pentyl propionate, hexyl propionate, butyl propionate, isobutyl isobutyrate, heptyl propionate, and butyl butanoate, and isoamyl acetate is particularly preferably used.

In a case of using EUV and EB in the exposing step, the organic solvent included in the organic developer may use a mixed solvent of the ester-based solvent and the hydrocarbon-based solvent, or a mixed solvent of the ketone-based solvent and the hydrocarbon solvent, instead of the above-mentioned ester-based solvent having 7 or more carbon atoms and 2 or less heteroatoms. Also, this case is effective for suppression of the swelling of the resist film.

In a case of the ester-based solvent and the hydrocarbon-based solvent in combination, isoamyl acetate is preferably used as the ester-based solvent. Further, from the viewpoint of adjusting the solubility of the resist film, a saturated hydrocarbon solvent (for example, octane, nonane, decane, dodecane, undecane, and hexadecane) is preferably used as the hydrocarbon-based solvent.

In a case of the ketone-based solvent and the hydrocarbon-based solvent in combination, 2-heptanone is preferably used as the ketone-based solvent. Further, from the viewpoint of adjusting the solubility of the resist film, a saturated hydrocarbon solvent (for example, octane, nonane, decane, dodecane, undecane, and hexadecane) is preferably used as the hydrocarbon-based solvent.

In a case of using the above mixed solvent, the content of the hydrocarbon-based solvent depends on the solubility of the resist film in the solvent, and thus, it is not particularly limited and the required amount thereof may be determined by appropriate adjustment.

A plurality of the above organic solvents may be used in combination, or the solvent may be used in combination with a solvent other than the solvents described above or water. Here, in order to exhibit the effects of the present invention sufficiently, the moisture content of the entirety of the developer is preferably less than 10% by mass, and the developer more preferably substantially does not contain moisture. The concentration (content) of the organic solvent (a total content in a case where a plurality of solvents are mixed together) in the developer is preferably 50% by mass or more, more preferably 50% to 100% by mass, still preferably 85% to 100% by mass, even still more preferably 90% to 100% by mass, and particularly preferably 95% to 100% by mass. A case where the developer is formed of substantially only an organic solvent is the most preferable. Moreover, a case where the developer is formed of substantially only an organic solvent includes a case where trace amounts of a surfactant, an antioxidant, a stabilizer, an anti-foaming agent, and the like are included.

The developer preferably contains an antioxidant. Thus, generation of oxidizing agents over time can be suppressed, and the content of the oxidizing agent can further be reduced. As the antioxidant, known ones can be used, but in a case of being used in semiconductor applications, an amine-based antioxidant or a phenol-based antioxidant is preferably used.

The content of the antioxidant is not particularly limited, but is preferably 0.0001% to 1% by mass, more preferably 0.0001% to 0.1% by mass, and still more preferably 0.0001% to 0.01% by mass, with respect to the total mass of the developer. There is a tendency that with the content of 0.0001% by mass or more, superior antioxidant effects are obtained, and with the content of 1% by mass or less, developing residues can be suppressed.

The developer may contain a basic compound, and specific examples thereof include the same ones as the basic compound which may be contained in the resist composition.

The developer may contain a surfactant. By incorporating the surfactant into the developer, the wettability for the resist film is improved, and thus, the development proceeds more effectively.

As the surfactant, the same ones as the surfactant which can be contained in the actinic ray-sensitive or radiation-sensitive resin composition can be used.

In a case where the developer contains a surfactant, the content of the surfactant is preferably 0.001% to 5% by mass, more preferably 0.005% to 2% by mass, and still more preferably 0.01% to 0.5% by mass, with respect to the total mass of the developer.

As the developing method, for example, a method in which a substrate is immersed in a tank filled with a developer for a certain period of time (a dip method), a method in which development is performed by heaping a developer up onto the surface of a substrate by surface tension, and then leave it to stand for a certain period of time (a puddle method), a method in which a developer is sprayed on the surface of a substrate (a spray method), a method in which a developer is continuously discharged onto a substrate spun at a constant rate while scanning a developer discharging nozzle at a constant rate (a dynamic dispense method), or the like can be applied.

Moreover, after the step of performing development, a step of stopping the development by replacing the solvent with another solvent may be carried out.

The development time is not particularly limited, but is usually 10 to 300 seconds, and preferably 20 to 120 seconds.

The temperature of the developer is preferably 0° C. to 50° C., and more preferably 15° C. to 35° C.

Both of development using a developer containing an organic solvent as the developer to be used in the developing step and development using an alkali developer may be performed (so-called double development). Thus, a finer pattern can be formed.

As the alkali developer in the double development, for example, aqueous alkali solutions of inorganic alkali such as sodium hydroxide, potassium hydroxide, sodium carbonate, sodium silicate, sodium metasilicate, and ammonia water, primary amines such as ethylamine and n-propylamine, secondary amines such as diethylamine and di-n-butylamine, tertiary amines such as triethylamine and methyldiethylamine, alcohol amines such as dimethyl ethanolamine and triethanolamine, quaternary ammonium salts such as tetraalkylammonium hydroxides such as tetramethylammonium hydroxide, tetraethylammonium hydroxide, tetrapropylammonium hydroxide, tetrabutylammonium hydroxide, tetrapentylammonium hydroxide, tetrahexylammonium hydroxide, tetraoctylammonium hydroxide, ethyltrimethylammonium hydroxide, butyltrimethylammonium hydroxide, methyltriamylammonium hydroxide, and dibutyldipentylammonium hydroxide, trimethylphenylammonium hydroxide, trimethylbenzylammonium hydroxide, triethylbenzylammonium hydroxide, and dimethyl bis(2-hydroxyethyl)ammonium hydroxide, cyclic amines such as pyrrole and piperidine, or the like can be used.

Furthermore, alcohols and a surfactant can also be added to the aqueous alkali solution in an appropriate amount before use.

The alkali concentration of the alkali developer is usually 0.1% to 20% by mass. The pH of the alkali developer is usually 10.0 to 15.0.

As the alkali developer, a 2.38%-by-mass aqueous solution of tetramethylammonium hydroxide is particularly preferable.

The alkali developer is not particularly limited, but examples thereof include the alkali developers described in paragraph <0460> of JP2014-048500A.

As the rinsing liquid in the rinsing treatment to be carried out after the alkali development, pure water is used, and can also be used after adding an appropriate amount of a surfactant thereto.

In the present invention, an area with a low exposure intensity is removed in the organic solvent developing step, and by further carrying out the alkali developing step, an area with a high exposure intensity is also removed. By virtue of a multiple-development process in which development is carried out in a plurality of times in such a manner, a pattern can be formed by keeping only a region with an intermediate exposure intensity from not being dissolved, so that a finer pattern than usual can be formed (the same mechanism as in <0077> of JP2008-292975A).

In the pattern forming method of the present invention, the order of the alkali developing step and the developing step using an organic developer is not particularly limited, but it is more preferable that the alkali development is carried out before the developing step using an organic developer.

[Rinsing Step]

It is preferable that a step of rinsing the developed film (hereinafter also referred to as a “rinsing step”) after the developing step using an organic developer is included. The rinsing step is a step of washing (rinsing) a wafer and a film on the wafer with a rinsing liquid after the development step.

A method for the washing treatment in the rinsing step is not particularly limited, and examples thereof include a method in which a rinsing liquid is continuously discharged on a substrate spun at a constant rate (a spin coating method), a method in which a substrate is immersed in a tank filled with a rinsing liquid for a certain period of time (a dip method), and a method in which a rinsing liquid is sprayed on a substrate surface (a spray method). Among these, a method in which a washing treatment is carried out using a spin coating method, and a substrate is rotated at a rotation speed of 2,000 rpm to 4,000 rpm after washing, thereby removing the rinsing liquid from the substrate, is preferable.

The rinsing time is not particularly limited, but is preferably 10 seconds to 300 seconds, more preferably 10 seconds to 180 seconds, and most preferably 20 seconds to 120 seconds.

The temperature of the rinsing liquid is preferably 0° C. to 50° C., and more preferably 15° C. to 35° C.

Moreover, after the development treatment or the rinsing treatment, a treatment of removing the developer or rinsing liquid attached to the pattern by a supercritical fluid may be performed.

Incidentally, after the development treatment, the rinsing treatment, or the treatment with a supercritical fluid, a heating step may be performed so as to remove the solvent remaining in the pattern. The heating temperature is not particularly limited as long as a good resist pattern is obtained, and is usually 40° C. to 160° C. The heating temperature is preferably 50° C. to 150° C., and most preferably 50° C. to 110° C. The heating time is not particularly limited as long as a good resist pattern is obtained, and is usually 15 to 300 seconds, and preferably 15 to 180 seconds.

(Rinsing Liquid)

As the rinsing liquid, a rinsing liquid including an organic solvent is preferably used, and as the organic solvent, at least one organic solvent selected from the group consisting of a hydrocarbon-based solvent, a ketone-based solvent, an ester-based solvent, an alcohol-based solvent, an amide-based solvent, and an ether-based solvent is preferable.

The organic solvent included in the rinsing liquid is preferably at least one selected from a hydrocarbon-based solvent, an ether-based solvent, and a ketone-based solvent, and more preferably at least one selected from a hydrocarbon-based solvent and an ether-based solvent.

As the organic solvent included in the rinsing liquid, the ether-based solvent can also be suitably used.

Specific examples of these organic solvents are the same as those described for the organic solvent contained in the developer as described above.

The vapor pressure of the rinsing liquid is preferably from 0.05 kPa to 5 kPa, more preferably from 0.1 kPa to 5 kPa, and most preferably from 0.12 kPa to 3 kPa, at 20° C. In a case where the rinsing liquid is a mixed solvent of a plurality of solvents, it is preferable that the total vapor pressure thereof is in the range. By setting the vapor pressure of the rinsing liquid to a range from 0.05 kPa to 5 kPa, the temperature uniformity in a wafer plane is improved, and further, the dimensional uniformity in a wafer plane is enhanced by suppression of swelling due to the permeation of the rinsing liquid.

The organic solvent included in the rinsing liquid may be of one kind or of two or more kinds. In a case where two or more kinds of the rinsing liquids are included, examples thereof include a mixed solvent of undecane and diisobutyl ketone.

The rinsing liquid may contain a surfactant. By incorporation of a surfactant into the rinsing liquid, there is tendency that the wetting properties to the resist film are improved, the rinsing properties are improved, and thus, generation of foreign matters is suppressed.

As the surfactant, the same one as the surfactant for use in the actinic ray-sensitive or radiation-sensitive resin composition which will be described later can be used.

In a case where the rinsing liquid contains a surfactant, the content of the surfactant is preferably 0.001% to 5% by mass, more preferably 0.005% to 2% by mass, and still more preferably 0.01% to 0.5% by mass, with respect to the total mass of the rinsing liquid.

The rinsing liquid may contain an antioxidant. The antioxidant that may be contained in the rinsing liquid is the same as the antioxidant that may be contained in the developer as described above.

In a case where the rinsing liquid contains an antioxidant, the content of the antioxidant is not particularly limited, but is preferably 0.0001% to 1% by mass, more preferably 0.0001% to 0.1% by mass, and still more preferably 0.0001% to 0.01% by mass, with respect to the total mass of the rinsing liquid.

A step of performing a washing step using a rinsing liquid may be included after the step of performing development using a developer including an organic solvent, but from the viewpoints of a throughput (productivity), an amount of a rinsing liquid to used, and the like, the step of performing washing using a rinsing liquid may not be included.

With regard to a treatment method not having a step of performing washing using a rinsing liquid, reference can be made to, for example, the descriptions in <0014> to <0086> of JP2015-216403A, the contents of which are incorporated herein by reference.

Moreover, it is also preferable that methyl isobutyl carbinol (MIBC) or the same liquid as the developer (particularly butyl acetate) is used as the rinsing liquid.

[Actinic Ray-Sensitive or Radiation-Sensitive Resin Composition]

The actinic ray-sensitive or radiation-sensitive resin composition used in the pattern forming method of the present invention is typically a resist composition, and preferably a chemically amplified resist composition.

The actinic ray-sensitive or radiation-sensitive resin composition is preferably an actinic ray-sensitive or radiation-sensitive resin composition for organic solvent development using a developer including an organic solvent. Here, the use for organic solvent development means at least an application for being provided for a step of performing development using a developer including an organic solvent.

The actinic ray-sensitive or radiation-sensitive resin composition is preferably a negative tone resist composition.

The actinic ray-sensitive or radiation-sensitive resin composition is preferably used for exposure with electron beams or extreme ultraviolet rays.

Hereinafter, the respective components contained in the actinic ray-sensitive or radiation-sensitive resin composition in the present invention will be described.

<Acid-Decomposable Resin (1)>

The actinic ray-sensitive or radiation-sensitive resin composition contains an acid-decomposable resin (1) (hereinafter also simply referred to as a “resin (1)”).

The acid-decomposable resin (1) has a repeating unit (a) having an aromatic ring and a repeating unit (b) represented by General Formula (AI). Hereinafter, the respective repeating units will be specifically described.

Repeating Unit (a) Having Aromatic Ring

Examples of the aromatic ring in the repeating unit having an aromatic ring include aromatic hydrocarbon rings (preferably having 6 to 18 carbon atoms) such as a benzene ring, a naphthalene ring, an anthracene ring, a fluorene ring, and a phenanthrene ring, and aromatic heterocycles including a heterocycle, such as a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, and a thiazole ring. Among these, from the viewpoint of resolution, the benzene ring or the naphthalene ring is preferable, and the benzene ring is the most preferable.

The aromatic ring may further have a substituent, and specific examples of the substituent include a hydroxyl group, and the respective groups mentioned as R₇ in General Formula (X) which will be described later.

As the repeating unit having an aromatic ring, a repeating unit represented by General Formula (A) is preferably.

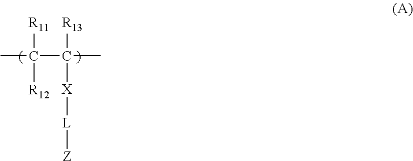

In General Formula (A),

R₁₁, R₁₂, and R₁₃ each independently represent a hydrogen atom, an alkyl group, a cycloalkyl group, a halogen atom, a cyano group, or an alkoxycarbonyl group. Here, R₁₂ may be bonded to L or Z to form a ring. In a case where R₁₂ is bonded to L or Z to form a ring, it represents a single bond or an alkylene group, and in a case where R₁₂ is not bonded to L or Z to form a ring, it represents a hydrogen atom, an alkyl group, a cycloalkyl group, a halogen atom, a cyano group, or an alkoxycarbonyl group.

X represents a single bond, —COO—, or —CONR₃₀—, and R₃₀ represents a hydrogen atom or an alkyl group.

In a case where L is not bonded to R₁₂, L represents a single bond or a divalent linking group. In a case where L is bonded to R₁₂, it represents a trivalent linking group. The trivalent linking group represents a group formed by removing any of hydrogen atoms from a divalent linking group.

Z represents an aromatic ring, and may be bonded to R₁₂ to form a ring.

Specific examples, preferred examples, and the like of R₁₁, R₁₂, R₁₃, X, and L in General Formula (A) are each the same as those of R₄₁, R₄₂, R₄₃, X₄, and L₄ in General Formula (I) which will be described later. Further, specific examples, preferred examples, and the like of Z are each the same as in the aromatic ring as described above.

Suitable examples of the repeating unit (a) having an aromatic ring include a repeating unit having a phenolic hydroxyl group.

In the present specification, the phenolic hydroxyl group is a group formed by substituting a hydrogen atom of an aromatic ring with a hydroxyl group.

Examples of the repeating unit having a phenolic hydroxyl group include a repeating unit represented by General Formula (I) or (I-1).

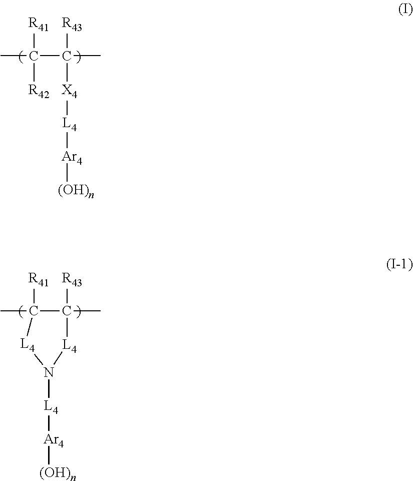

In the formulae,

R₄₁, R₄₂, and R₄₃ each independently represent a hydrogen atom, an alkyl group, a cycloalkyl group, a halogen atom, a cyano group, or an alkoxycarbonyl group, in which R₄₂ may be bonded to Ar₄ to form a ring. In a case where R₄₂ is bonded to Ar₄ to form a ring, it represents a single bond or an alkylene group. In a case where R₄₂ is not bonded to Ar₄ to form a ring, it represents a hydrogen atom, an alkyl group, a cycloalkyl group, a halogen atom, a cyano group, or an alkoxycarbonyl group.

X₄ represents a single bond, —COO—, or —CONR₆₄—, and R₆₄ represents a hydrogen atom or an alkyl group.

L₄'s each independently represent a single bond or a divalent linking group.

In a case where Ar₄ is not bonded to R₄₂, Ar₄ represents an (n+1)-valent aromatic ring group, and in a case where Ar₄ is bonded to R₄₂ to form a ring, it represents an (n+2)-valent aromatic ring group.

n represents an integer of 1 to 5.

For a purpose of increasing the polarity of the repeating unit of General Formula (I) or (I-1), it is also preferable that n is an integer of 2 or more, or X₄ is —COO— or —CONR₆₄—.

Examples of the alkyl group of R₄₁, R₄₂, or R₄₃ in General Formulae (I) and (I-1) preferably include an alkyl group having 20 or less carbon atoms, such as a methyl group, an ethyl group, a propyl group, an isopropyl group, an n-butyl group, a sec-butyl group, a hexyl group, a 2-ethylhexyl group, an octyl group, and a dodecyl group, more preferably include an alkyl group having 8 or less carbon atoms, and particularly preferably include an alkyl group having 3 or less carbon atoms, each of which may have a substituent.

The cycloalkyl group of R₄₁, R₄₂, or R₄₃ in General Formulae (I) and (I-1) may be either monocyclic or polycyclic. Preferred examples thereof include a monocyclic cycloalkyl group having 3 to 8 carbon atoms, such as a cyclopropyl group, a cyclopentyl group, and a cyclohexyl group, each of which may have a substituent.

Examples of the halogen atom of R₄₁, R₄₂, or R₄₃ in General Formulae (I) and (I-1) include a fluorine atom, a chlorine atom, a bromine atom, and an iodine atom, with the fluorine atom being particularly preferable.

The alkyl group included in the alkoxycarbonyl group of R₄₁, R₄₂, or R₄₃ in General Formulae (I) and (I-1) is preferably the same as the alkyl group in R₄₁, R₄₂, or R₄₃.

Preferred examples of the substituent in each of the groups include an alkyl group, a cycloalkyl group, an aryl group, an amino group, an amido group, a ureido group, a urethane group, a hydroxyl group, a carboxyl group, a halogen atom, an alkoxy group, a thioether group, an acyl group, an acyloxy group, an alkoxycarbonyl group, a cyano group, and a nitro group, and the substituent preferably has 8 or less carbon atoms.

Ar₄ represents an (n+1)-valent aromatic ring group. A divalent aromatic ring group in a case where n is 1 may have a substituent, and preferred examples thereof include an arylene group having 6 to 18 carbon atoms, such as a phenylene group, a tolylene group, a naphthylene group, and an anthracenylene group, or an aromatic ring group including a heterocycle, such as thiophene, furan, pyrrole, benzothiophene, benzofuran, benzopyrrole, triazine, imidazole, benzimidazole, triazole, thiadiazole, and thiazole.

Specific suitable examples of the (n+1)-valent aromatic ring group in a case where n is an integer of 2 or more include groups formed by obtaining removing arbitrary (n−1) hydrogen atoms from the specific examples of the divalent aromatic ring groups.

The (n+1)-valent aromatic ring group may further have a substituent.

Examples of the substituent which can be contained in the alkyl group, the cycloalkyl group, the alkoxycarbonyl group, and the (n+1)-valent aromatic ring group include the alkyl groups mentioned above for R₄₁, R₄₂, or R₄₃ in General Formula (I), and alkoxy groups such as a methoxy group, an ethoxy group, a hydroxyethoxy group, a propoxy group, a hydroxypropoxy group, and a butoxy group; and aryl groups such as a phenyl group.

Preferred examples of the alkyl group of R₆₄ in —CONR₆₄— represented by X₄ (R₆₄ represents a hydrogen atom or an alkyl group) include an alkyl group having 20 or less carbon atoms, such as a methyl group, an ethyl group, a propyl group, an isopropyl group, an n-butyl group, a sec-butyl group, a hexyl group, a 2-ethylhexyl group, an octyl group, and a dodecyl group, and more preferred examples of the alkyl group include an alkyl group having 8 or less carbon atoms, each of which may have a substituent.

X₄ is preferably a single bond, —COO—, or —CONH—, and more preferably a single bond or —COO—.

The divalent linking group as L₄ is preferably an alkylene group or an arylene group, and preferred examples of the alkylene group include an alkylene group having 1 to 8 carbon atoms, such as a methylene group, an ethylene group, a propylene group, a butylene group, a hexylene group, and an octylene group, and an arylene group having 6 to 12 carbon atoms, such as a phenylene group and a naphthylene group, each of which may have a substituent.

As Ar₄, an aromatic ring group having 6 to 18 carbon atoms, which may have a substituent, is more preferable, and a benzene ring group, a naphthalene ring group, or a biphenylene ring group is particularly preferable.

The repeating unit represented by General Formula (I) preferably includes a hydroxystyrene structure. That is, Ar₄ is preferably a benzene ring group.

In General Formula (I), X₄ is preferably a single bond or —COO—, Ar₄ is preferably an arylene group, L₄ is preferably a single bond, and n is preferably 1.

Preferred examples of the repeating unit having a phenolic hydroxyl group include a repeating unit represented by General Formula (p1).

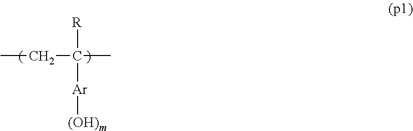

R in General Formula (p1) represents a hydrogen atom, a halogen atom, or a linear or branched alkyl group having 1 to 4 carbon atoms. A plurality of R's may be the same as or different from each other. R in General Formula (p1) is particularly preferably a hydrogen atom.

Ar in General Formula (p1) represents an aromatic ring, and examples thereof include the same one as those mentioned above.

m in General Formula (p1) represents an integer of 1 to 5, and is preferably 1.

Specific examples of the repeating unit having a phenolic hydroxyl group are shown below, but the present invention is not limited thereto. In the formula, a represents 1 or 2. Further, with regard to the specific examples of the repeating unit having a phenolic hydroxyl group, reference can be made to the specific examples described in <0177> and <0178> of JP2014-232309A, the contents of which are incorporated herein by reference.

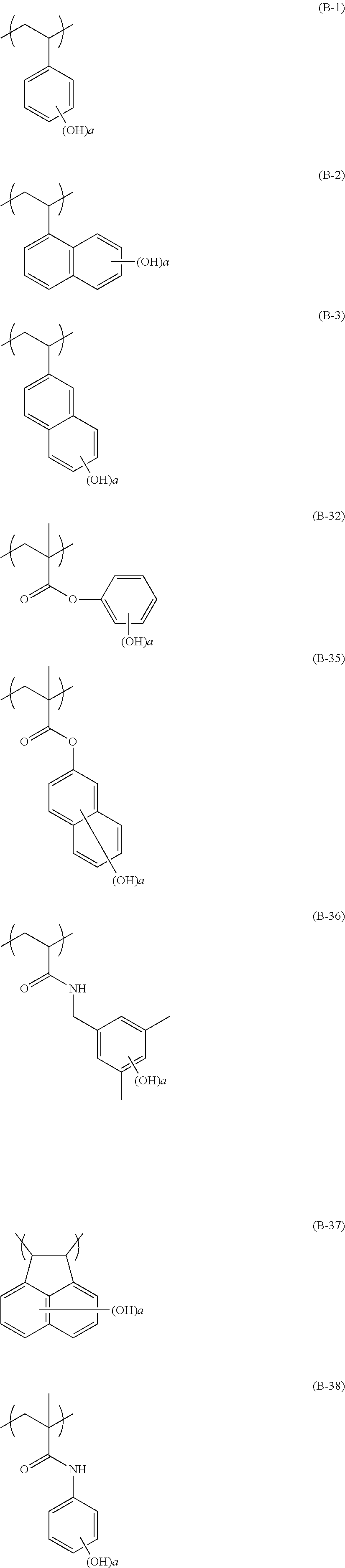

In a case where the resin (1) has a repeating unit having a phenolic hydroxyl group, it may have one kind or two or more kinds of the repeating unit having a phenolic hydroxyl group.

In a case where the resin (1) has a repeating unit having a phenolic hydroxyl group, the content of the repeating unit having a phenolic hydroxyl group is preferably 10% to 95% by mole, more preferably 20% to 90% by mole, and still more preferably 30% to 85% by mole, with respect to all the repeating units of the resin (1).

The repeating unit (a) having an aromatic ring may be a repeating unit represented by General Formula (X).

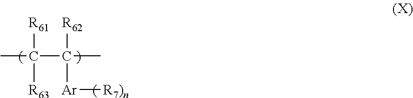

In General Formula (X),

R₆₁, R₆₂, and R₆₃ each independently represent a hydrogen atom, an alkyl group, a cycloalkyl group, a halogen atom, a cyano group, or an alkoxycarbonyl group, provided that R₆₃ may be bonded to Ar to form a ring, and R₆₃ in such a case represents a single bond or an alkylene group.

Ar represents an (n+1)-valent aromatic ring group, and in a case where Ar is bonded with R₆₃ to form a ring, it represents an (n+2)-valent aromatic ring group.

R₇'s each independently represent a linear, branched, or cyclic alkyl group, alkoxy group, or acyloxy group having 1 to 10 carbon atoms, a cyano group, a nitro group, an amino group, a halogen atom, an ester group (—OCOR or —COOR: R represents an alkyl group or a fluorinated alkyl group having 1 to 6 carbon atoms), or a carboxyl group.

n represents an integer of 0 or more.

General Formula (X) is also preferably a repeating unit represented by the following General Formula (V) or the following General Formula (VI).

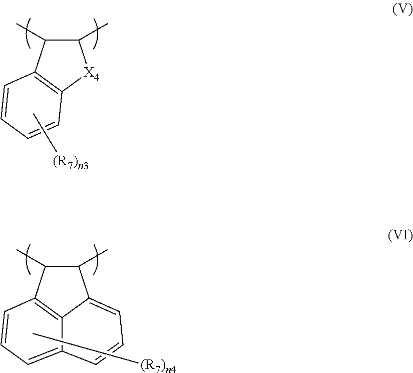

In the formula, n₃ represents an integer of 0 to 4. n₄ represents an integer of 0 to 6.

X₄ is a methylene group, an oxygen atom, or a sulfur atom.

R₇ has the same definition as R₇ in General Formula (X).

Specific examples of the repeating unit represented by General Formula (X) are shown below, but are not limited thereto.

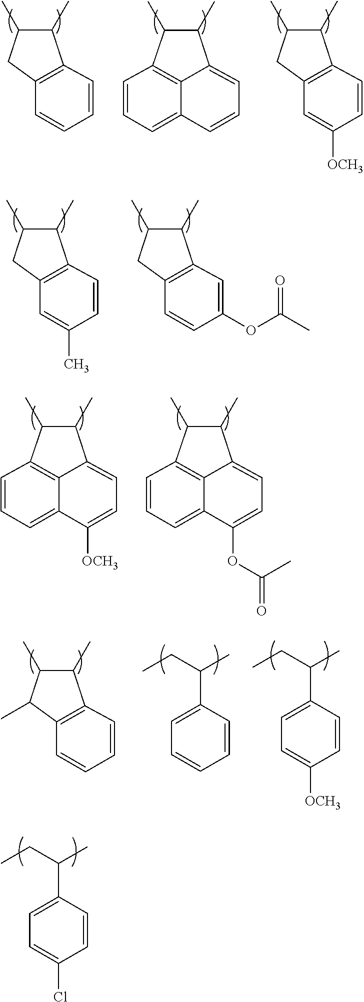

In a case where the resin (1) has the repeating unit represented by General Formula (X), it may have one kind or two or more kinds of the repeating unit represented by General Formula (X).

In a case where the resin (1) has the repeating unit represented by General Formula (X), the content of the repeating unit represented by General Formula (X) is preferably 5% to 50% by mole, more preferably 5% to 40% by mole, and still more preferably 5% to 30% by mole, with respect to all the repeating units of the resin (1).

Furthermore, the repeating unit (a) having an aromatic ring may be one having a repeating unit (b) represented by General Formula (AI), and in addition, a repeating unit having an aromatic ring in the repeating unit (c) having an acid-decomposable group, which will be described later.

Examples of the repeating unit (a) having an aromatic ring include the following repeating units.

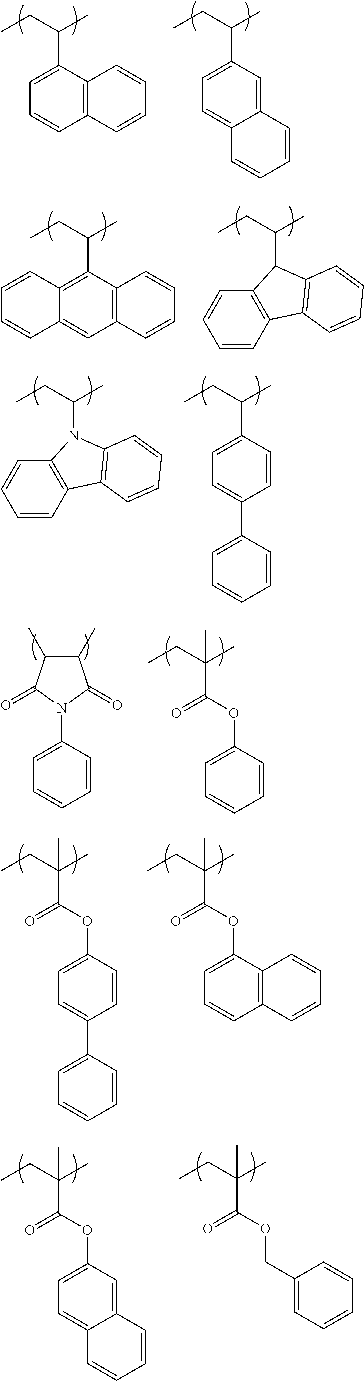

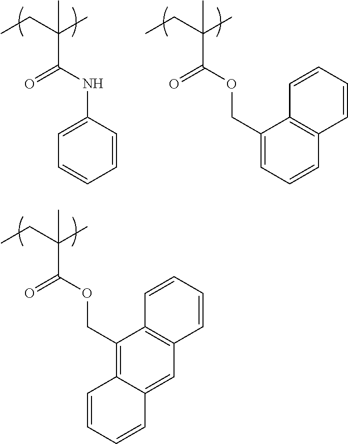

Examples of the repeating unit having an aromatic ring, in which the aromatic ring further has a substituent, include repeating units shown below.

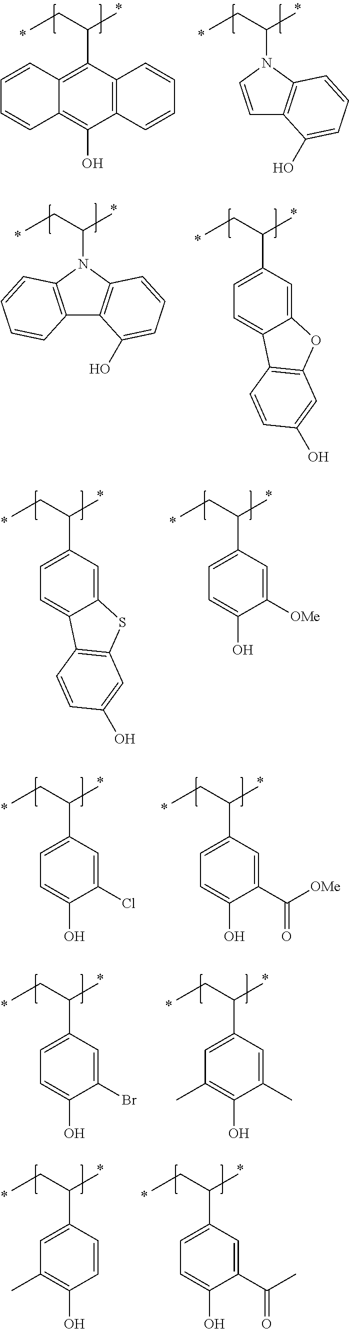

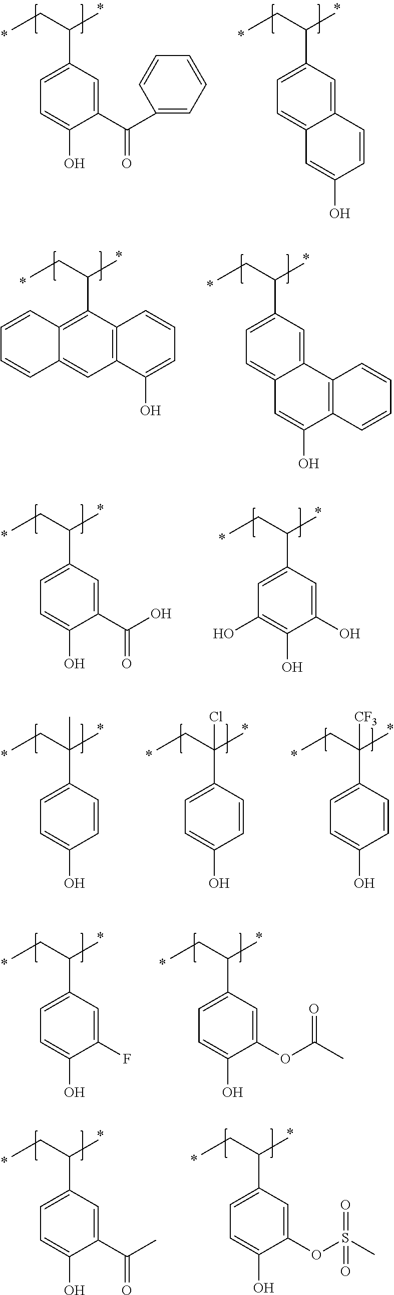

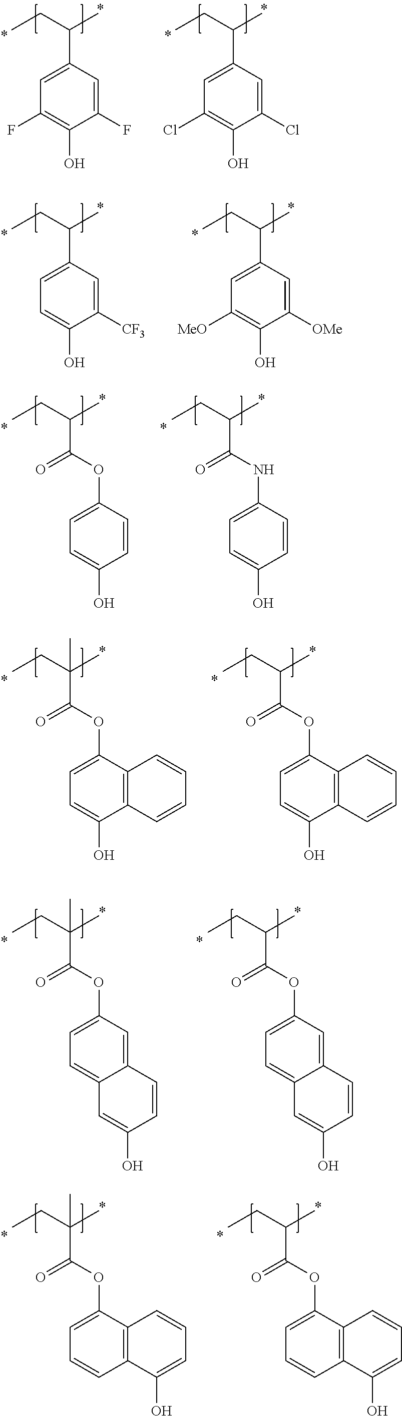

The resin (1) has a repeating unit (a) having an aromatic ring, and may have one kind or two or more kinds of the repeating unit (a) having an aromatic ring group.

The content of the repeating unit (a) having an aromatic ring included in the resin (1) is 55% by mole or more, preferably 60% to 100% by mole, more preferably 65% to 95% by mole, and still more preferably 70% to 90% by mole, with respect to all the repeating units of the resin (1).

Repeating Unit (b) Represented by General Formula (AI)

The resin (1) has a repeating unit represented by General Formula (AI).

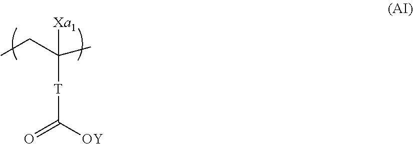

In General Formula (AI),

Xa₁ represents a hydrogen atom or an alkyl group.

T represents a single bond or a divalent linking group.

Y is a group that leaves by the action of an acid, and represents a group represented by General Formula (Y1).

—C(Rx1)(Rx2)(Rx3) General Formula (Y1):

In General Formula (Y1), Rx1 to Rx3 each independently represent an alkyl group or a cycloalkyl group, the total number of carbon atoms of Rx1 to Rx3 is 10 or less, and two of Rx1 to Rx3 are bonded to form a ring. The ring may include an ether bond or ester bond in the ring.

The alkyl group represented by Xa₁ may be alkyl group having a substituent, and examples thereof include a methyl group or a group represented by —CH₂—R₁₁. R₁₁ represents a halogen atom (a fluorine atom or the like), a hydroxyl group, or a monovalent organic group, and examples thereof include an alkyl group having 5 or less carbon atoms and an acyl group having 5 or less carbon atoms, preferably an alkyl group having 3 or less carbon atoms, and more preferably a methyl group. In one aspect, Xₐ₁ is preferably a hydrogen atom, a methyl group, a trifluoromethyl group, a hydroxymethyl group, or the like.

Examples of the divalent linking group of T include an alkylene group, an arylene group, a —COO-Rt- group, an —O-Rt- group, and a group formed by combination thereof. In the formulae, Rt represents an alkylene group, a cycloalkylene group, or an arylene group.

T is preferably a single bond, an arylene group, or a —COO-Rt- group. Rt is preferably an arylene group having 6 to 12 carbon atoms or an alkylene group having 1 to 5 carbon atoms, and more preferably a phenylene group, a naphthylene group, a —CH₂— group, a —(CH₂)₂— group, or a —(CH₂)₃— group.

Specific examples of T include the following linking groups.

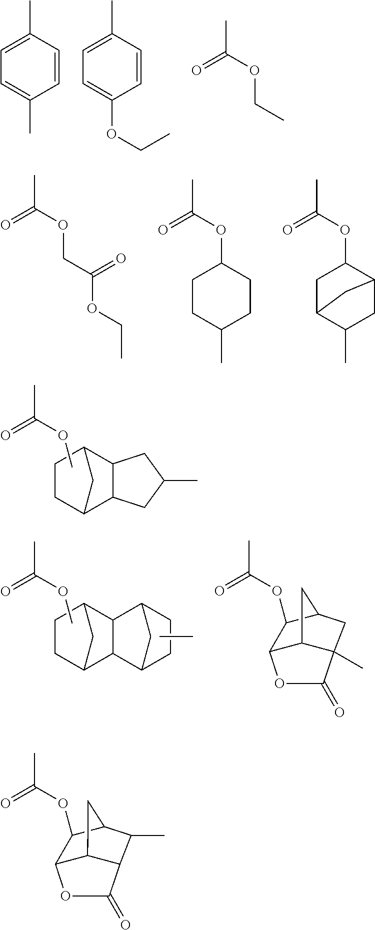

Furthermore, in a case where T of General Formula (AI) includes arylene, General Formula (AI) also corresponds to the repeating unit (a) having an aromatic ring.

Rx₁ to Rx₃ each independently represent an (linear or branched) alkyl group or a (monocyclic or polycyclic) cycloalkyl group.

Two of Rx1 to Rx3 are bonded to form a ring. The ring may include an ether bond or ester bond in the ring.

As the alkyl group of Rx₁ to Rx₃, an alkyl group having 1 to 4 carbon atoms, such as a methyl group, an ethyl group, an n-propyl group, an isopropyl group, an n-butyl group, an isobutyl group, and a t-butyl group is preferable.

As the cycloalkyl group of Rx₁ to Rx₃, a monocyclic cycloalkyl group such as a cyclopentyl group and a cyclohexyl group, or a polycyclic cycloalkyl group such as a norbornyl group, a tetracyclodecanyl group, a tetracyclododecanyl group, and an adamantyl group is preferable.

The total number of carbon atoms of Rx1 to Rx3 is 10 or less, preferably 8 or less, and still more preferably 7 or less. The total number of carbon atoms of Rx1 to Rx3 is usually 5 or more.

As the ring formed by the bonding of two of Rx₁ to Rx₃, a monocyclic alicycle such as a cyclopentane ring and a cyclohexane ring, or a polycyclic alicycle such as a norbornane ring, a tetracyclodecane ring, a tetracyclododecane ring, and an adamantane ring is preferable. The ring is preferably a 5- or 6-membered ring. Further, as the ring, a monocycle is preferable.

The ring may include an ether bond or ester bond in the ring.

Each of the groups may have a substituent, and examples of the substituent include an alkyl group (having 1 to 4 carbon atoms), a halogen atom, a hydroxyl group, an alkoxy group (having 1 to 4 carbon atoms), a carboxyl group, and an alkoxycarbonyl group (having 2 to 6 carbon atoms), with those having 8 or less carbon atoms being preferable.

The repeating unit (b) represented by General Formula (AI) is a repeating unit having a structure (acid-decomposable group) in which a polar group (carboxyl group) is protected with a leaving group that leaves by the decomposition by the action of an acid.

Here, in a case where the repeating unit having an acid-decomposable group is included in the resin, the solubility of the resin in an organic solvent decreases by the action of an acid, and thus, its solubility in an alkali developer increases.

Examples of the repeating unit (b) represented by General Formula (AI) are shown below. In the specific examples, Rx represents a hydrogen atom, CH₃, CF₃, or CH₂OH. Rxa and Rxb each represent an alkyl group having 1 to 4 carbon atoms. Z represents a substituent including a polar group, and in a case where Z's are present in plural numbers, they are each independent. p represents 0 or a positive integer. Examples of the substituent including a polar group, represented by Z, include a linear or branched alkyl group, and a cycloalkyl group, each having a hydroxyl group, a cyano group, an amino group, an alkylamido group, or a sulfonamido group, and preferably an alkyl group having a hydroxyl group. As the branched alkyl group, an isopropyl group is particularly preferable.

Here, for each of the groups corresponding to Rx1 to Rx3 in General Formula (Y1), Rxa, Z, and p are appropriately controlled such that the total number of carbon atoms of each of the groups is 10 or less.

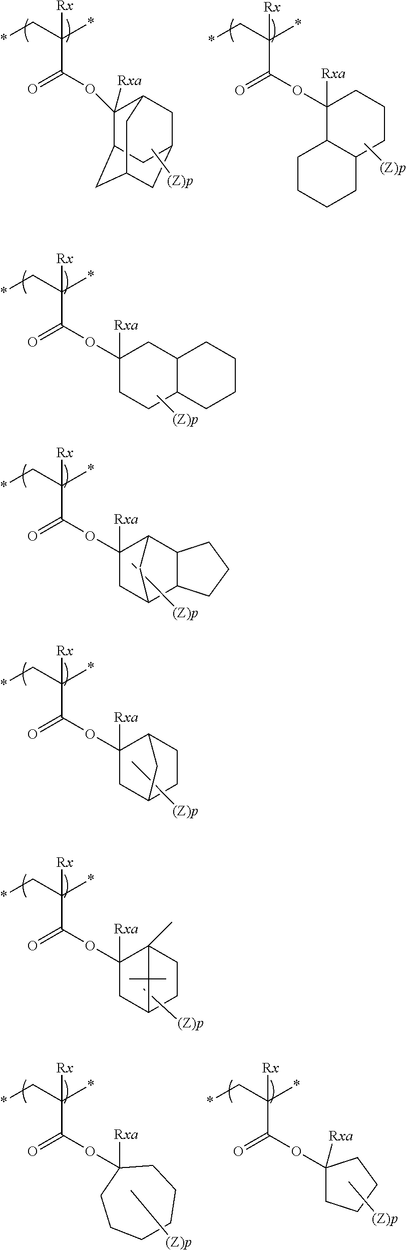

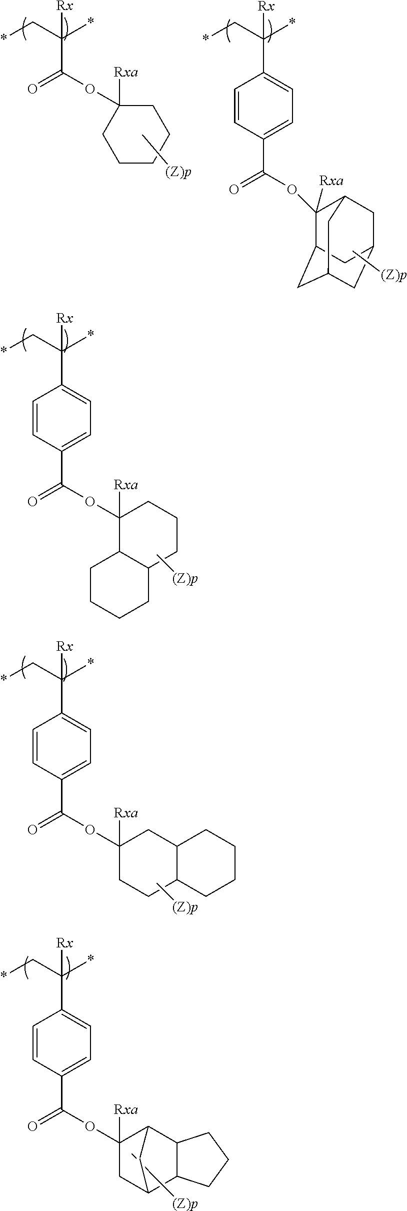

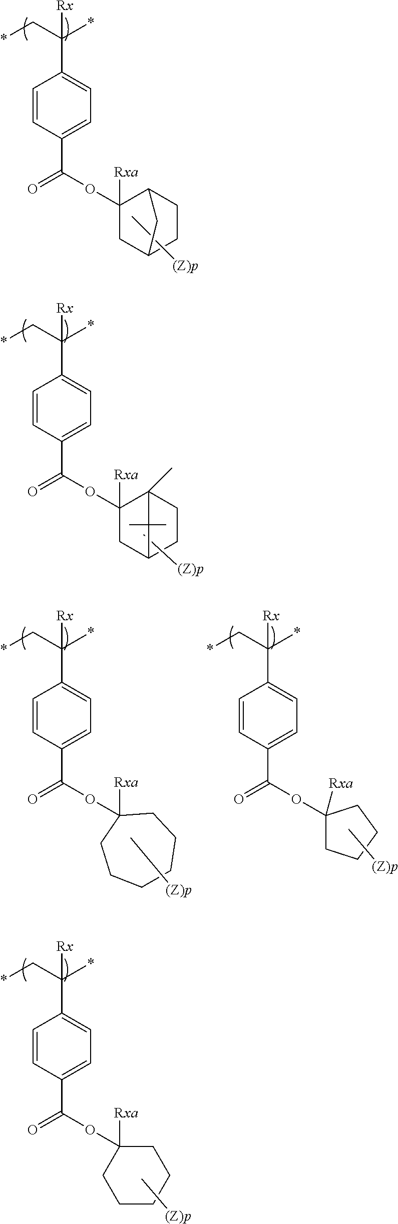

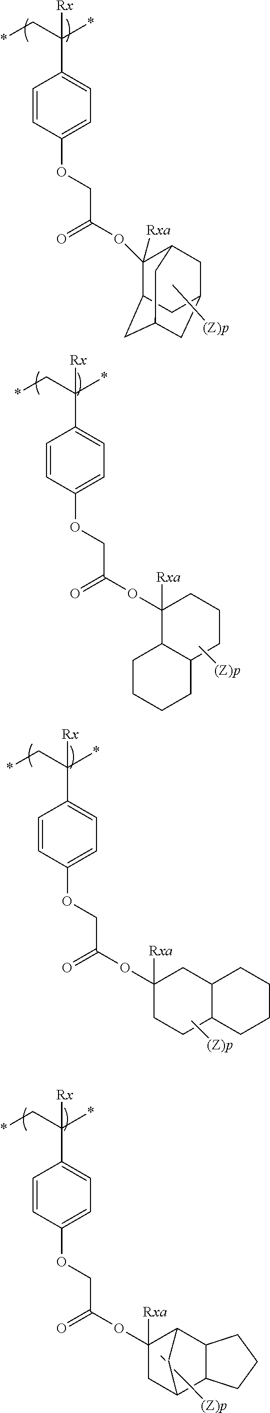

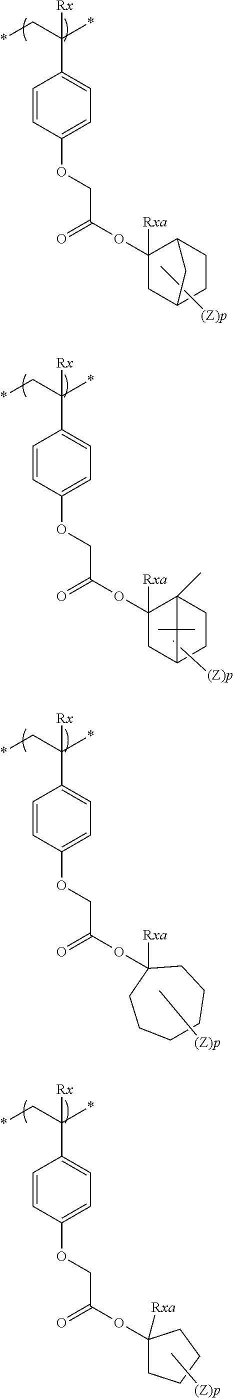

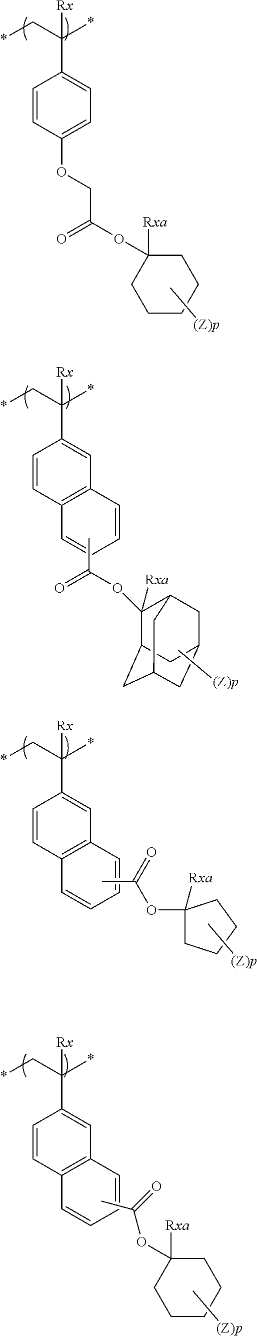

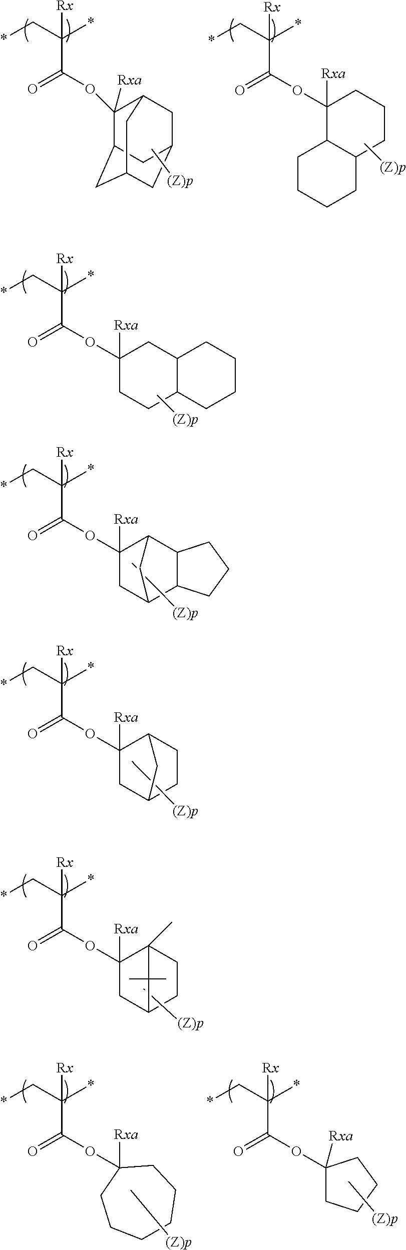

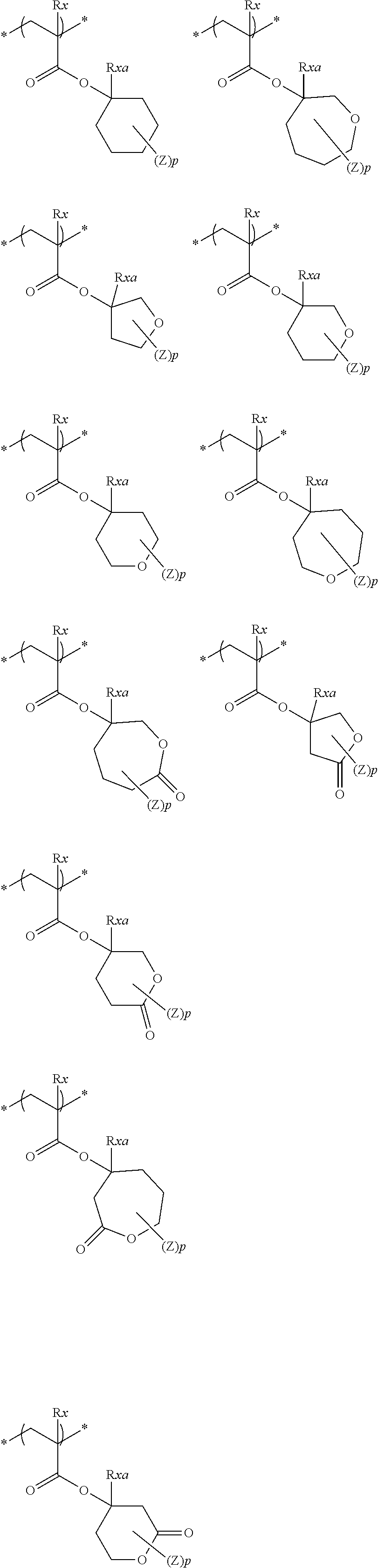

The resin (1) has the repeating unit (b) represented by General Formula (AI), and may have one kind or two or more kinds of the repeating unit (b) represented by General Formula (AI).

The content of the repeating unit (b) represented by General Formula (AI) included in the resin (1) is preferably 20% to 100% by mole, more preferably 40% to 95% by mole, and still more preferably 60% to 90% by mole, with respect to all the repeating units of the resin (1).

Other Repeating Unit (c) having Acid-Decomposable Group

The resin (1) may have a repeating unit having an acid-decomposable group (hereinafter also simply referred to as a “repeating unit (c)”) other than the repeating unit (c) represented by General Formula (AI), in addition to the repeating unit (b) represented by General Formula (AI).

The repeating unit (c) typically has a structure protected with a leaving group that leaves by the decomposition of a polar group by the action of an acid as an acid-decomposable group.

Examples of the polar group include a carboxyl group, an alcoholic hydroxyl group, and a phenolic hydroxyl group, and a sulfonic acid group. Among those, the polar group is preferably a carboxyl group, an alcoholic hydroxyl group, or a phenolic hydroxyl group, and more preferably a carboxyl group, or a phenolic hydroxyl group.

Examples of the leaving group that leaves through decomposition by the action of an acid include a group represented by any one of General Formulae (Y11) to (Y14).

—C(Rx₁₁)(Rx₁₂)(Rx₁₃) General Formula (Y11):

—C(═O)OC(Rx₁₁)(Rx₁₂)(Rx₁₂) General Formula (Y12):

—C(R₃₆)(R₃₇)(OR₃₈) General Formula (Y13):

—C(Rn)(H)(Ar) General Formula (Y14):

In General Formulae (Y11) and (Y12), Rx₁₁ to Rx₁₃ each independently represent an (linear or branched) alkyl group or a (monocyclic or polycyclic) cycloalkyl group, provided that in a case where all of Rx₁₁ to Rx₁₃ are (linear or branched) alkyl groups, it is preferable that at least two of Rx₁₁, . . . , or Rx₁₃ are methyl groups.

More preferably, Rx₁₁ to Rx₁₃ are each independently a repeating unit representing a linear or branched alkyl group, still more preferably, Rx₁₁ to Rx₁₃ are each independently a repeating unit representing a linear alkyl group.

Two of Rx₁₁ to Rx₁₃ may be bonded to each other to form a monocycle or a polycycle.

Examples of the alkyl group of Rx₁₁ to Rx₁₃ include the groups mentioned above as the alkyl group of Rx₁ to Rx₃.

Examples of the cycloalkyl group of Rx₁ to Rx₃ include the groups mentioned above as the alkyl group of Rx₁ to Rx₃.

As the cycloalkyl group formed by the bonding of two of Rx₁₁ to Rx₁₃, a monocyclic cycloalkyl group such as a cyclopentyl group and a cyclohexyl group, or a polycyclic cycloalkyl group such as a norbornyl group, a tetracyclodecanyl group, a tetracyclododecanyl group, and an adamantyl group is preferable, and a monocyclic cycloalkyl group having 5 or 6 carbon atoms is particularly preferable.

In the cycloalkyl group formed by the bonding of two of Rx₁₁ to Rx₁₃, for example, one of the ring-constituting methylene groups may be substituted with a heteroatom such as an oxygen atom or a group having a heteroatom, such as a carbonyl group.

In a preferred aspect of the group represented by General Formula (Y11) or (Y12), for example, Rx₁₁ is a methyl group or an ethyl group, and Rx₁₂ and Rx₁₃ are bonded to each other to form the above-mentioned cycloalkyl group.

In General Formula (Y13), R₃₆ to R₃₈ each independently represent a hydrogen atom or monovalent organic group. R₃₇ and R₃₈ may be bonded to each other to form a ring. Examples of the monovalent organic group include an alkyl group, a cycloalkyl group, an aryl group, an aralkyl group, and an alkenyl group. It is also preferable that R₃₆ is a hydrogen atom.

As General Formula (Y13), a structure represented by General Formula (Y3-1) is more preferable.

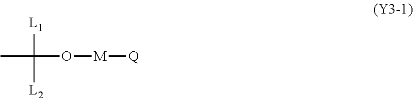

Here, L₁ and L₂ each independently represent a hydrogen atom, an alkyl group, a cycloalkyl group, an aryl group, or a group obtained by combining an alkylene group with an aryl group.

M represents a single bond or a divalent linking group.

Q represents an alkyl group, a cycloalkyl group which may include a heteroatom, an aryl group which may include a heteroatom, an amino group, an ammonium group, a mercapto group, a cyano group, or an aldehyde group.

It is preferable that at least one of L₁ or L₂ is a hydrogen atom, and at least one of L₁ or L₂ is an alkyl group, a cycloalkyl group, an aryl group, or a group obtained by combining an alkylene group with an aryl group.

At least two of Q, M, or L₁ may be bonded to each other to form a ring (preferably a 5- or 6-membered ring).

In order to improve the pattern collapse performance, L₂ is preferably a secondary or tertiary alkyl group, and more preferably a tertiary alkyl group. Examples of the secondary alkyl group include an isopropyl group, a cyclohexyl group, and a norbornyl group, and examples of the tertiary alkyl group include a tert-butyl group and adamantane. In these aspects, since Tg or activation energy is high, suppression of fogging can be achieved, in addition to secured film hardness.

In General Formula (Y14) Ar represents an aromatic ring group. Rn represents an alkyl group, a cycloalkyl group, or an aryl group. Rn and Ar may be bonded to each other to form a non-aromatic ring. Ar is more preferably an aryl group.

As the repeating unit having a group that generates a polar group through decomposition by the action of an acid, a repeating unit represented by General Formula (AIa) or (AII) is preferable.

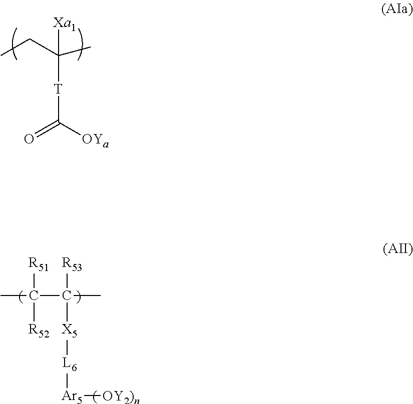

In General Formula (AIa),

Xa₁ represents a hydrogen atom or an alkyl group.

T represents a single bond or a divalent linking group.

Ya represents a group that leaves by the action of an acid. Ya is preferably a group represented by any one of General Formulae (Y11) to (Y14) as described above, provided that in a case where Ya is a group represented by General Formula (Y11), and two of Rx₁₁, Rx₁₂, and Rx₁₃ are bonded to form a ring, the total number of carbon atoms of Rx₁₁, Rx₁₂, and Rx₁₃ is 11 or more.

Examples of the alkyl group represented by Xa₁ include the same ones as Xa₁ of General Formula (AI), and a preferred range thereof is also the same.

Examples of the divalent linking group of T include the same ones as T of General Formula (AI), and a preferred range thereof is also the same.

In addition, in a case where T of General Formula (AIa) includes arylene, General Formula (AIa) corresponds to the repeating unit (a) having an aromatic ring.

In General Formula (AII),

R₆₁, R₆₂, and R₆₃ each independently represent a hydrogen atom, an alkyl group, a cycloalkyl group, a halogen atom, a cyano group, or an alkoxycarbonyl group, provided that R₆₂ may be bonded to Ar₆ to form a ring and in this case, R₆₂ represents a single bond or an alkylene group.

X₆ represents a single bond, —COO— or —CONR₆₄—, in which R64 represents a hydrogen atom or an alkyl group.

L₆ represents a single bond or an alkylene group.

Ar₆ represents an (n+1)-valent aromatic ring group and in a case where Ar₆ is bonded to R₆₂ to form a ring, it represents an (n+2)-valent aromatic ring group.

In a case of n≥2, Y₂'s each independently represent a hydrogen atom or a group that leaves by the action of an acid, provided that at least one of Y₂'s represents a group that leaves by the action of an acid. The group that leaves by the action of an acid as Y₂ is preferably a group of any one of General Formulae (Y11) to (Y14), provided that in a case where Y₂ is a group represented by General Formula (Y12), and two of Rx₁₁, Rx₁₂, and Rx₁₃ are bonded to each other to form a ring, the total number of carbon atoms of Rx₁₁, Rx₁₂, and Rx₁₃ is 11 or more.

n represents an integer of 1 to 4.

Each of the groups may have a substituent, and examples of the substituent include an alkyl group (having 1 to 4 carbon atoms), a halogen atom, a hydroxyl group, an alkoxy group (having 1 to 4 carbon atoms), a carboxyl group, and an alkoxycarbonyl group (having 2 to 6 carbon atoms), with those having 8 or less carbon atoms being preferable.

The repeating unit represented by General Formula (AIa) preferably represents an acid-decomposable (meth)acrylic acid tertiary alkyl ester-based repeating unit (a repeating unit in which Xa₁ represents a hydrogen atom or a methyl group, and T represents a single bond).

The repeating unit represented by General Formula (AII) is preferably a repeating unit represented by General Formula (AIII).

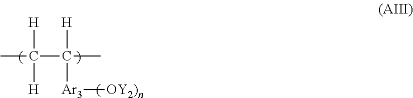

In General Formula (AIII),

Arₐ represents an aromatic ring group.

In a case of n≥2, Y₂'s each independently represent a hydrogen atom or a group that leaves by the action of an acid, provided that at least one of Y₂'s represents a group that leaves by the action of an acid. The group that leaves by the action of an acid as Y₂ is preferably a group of any one of General Formulae (Y11) to (Y14), provided that in a case where Y₂ is a group represented by General Formula (Y12), and two of Rx₁₁, Rx₁₂, and Rx₁₃ are bonded to each other to form a ring, the total number of carbon atoms of Rx₁₁, Rx₁₂, and Rx₁₃ is 11 or more. n represents an integer of 1 to 4.

The aromatic ring group represented by Ar₆ and Arₐ is preferably a benzene ring group or a naphthalene ring group, and more preferably a benzene ring group.

Specific examples of the repeating unit (c) are shown below, but the present invention is not limited thereto.

In the specific examples, Rx represents a hydrogen atom, CH₃, CF₃, or CH₂OH. Rxa and Rxb each represent an alkyl group having 1 to 4 carbon atoms. Z represents a substituent containing a polar group, and in a case where Z's are present in plural numbers, they are each independent. p represents 0 or a positive integer. Examples of the substituent including a polar group, represented by Z, include a linear or branched alkyl group, and a cycloalkyl group, each having a hydroxyl group, a cyano group, an amino group, an alkylamido group, or a sulfonamido group, with the alkyl group having a hydroxyl group being preferable. As the branched alkyl group, an isopropyl group is particularly preferable.

Each of the groups may have a substituent, and examples of the substituent include an alkyl group (having 1 to 4 carbon atoms), a halogen atom, a hydroxyl group, an alkoxy group (having 1 to 4 carbon atoms), a carboxyl group, and an alkoxycarbonyl group (having 2 to 6 carbon atoms), with those having 8 or less carbon atoms being preferable.

In addition, with reference to specific examples of the repeating unit (c), reference can be made to the examples not corresponding to the repeating unit (b) represented by General Formula (AI) among the specific examples described in <0227> to <0233>, and <0270> to <0272> of JP2014-232309A, and <0123> to <0131> of JP2012-208447A, the contents of which are incorporated herein by reference.

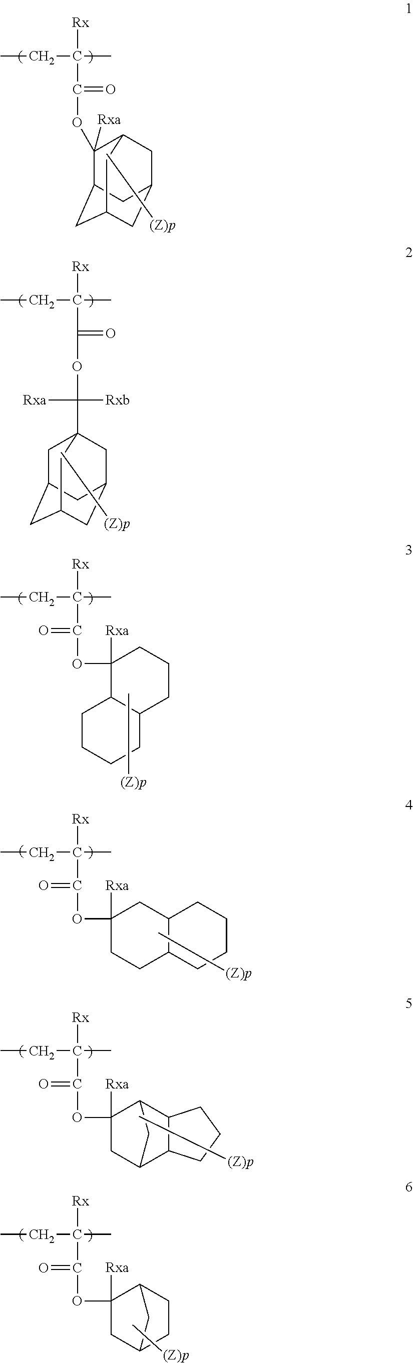

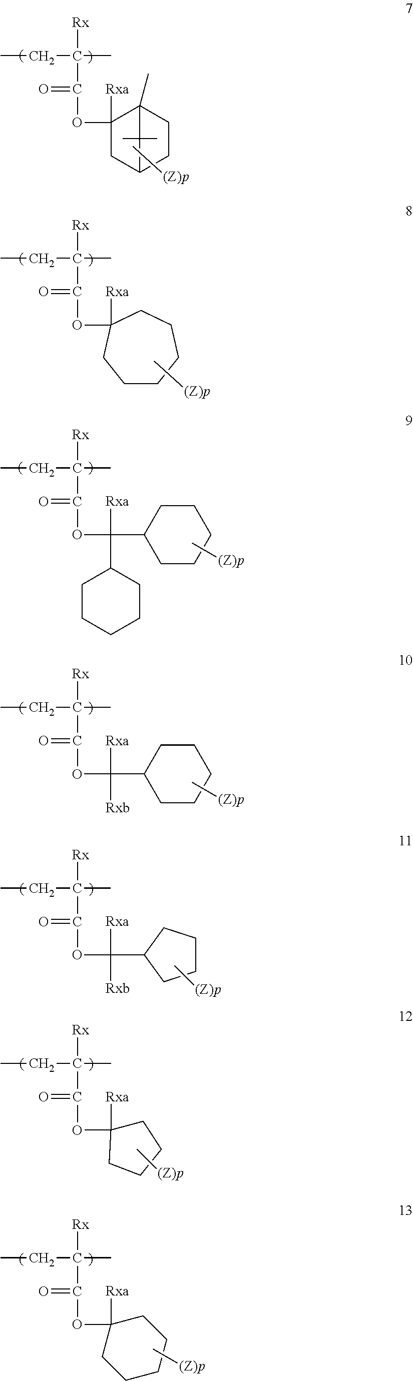

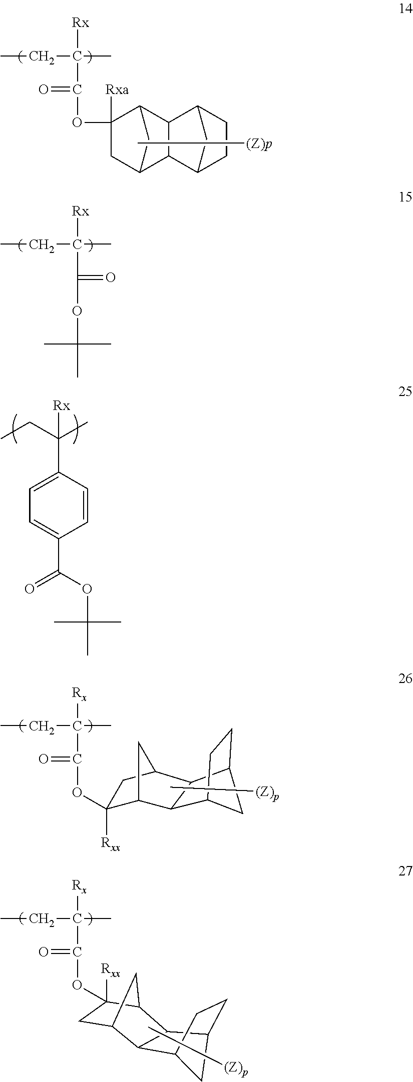

In a case where the resin (1) has a repeating unit (c) having an acid-decomposable group, the repeating unit (c) having an acid-decomposable group may be used singly or in combination of two or more kinds thereof.

In a case where the resin (1) has the repeating unit (c) having an acid-decomposable group, the content of the repeating unit (c) (a total content in a case where a plurality of kinds thereof are contained) having an acid-decomposable group in the resin (1) is preferably from 5% by mole to 80% by mole, more preferably from 5% by mole to 75% by mole, and still more preferably from 10% by mole to 65% by mole, the with respect to all the repeating units in the resin (1).

Moreover, in a case where the repeating unit (c) has an aromatic ring, the repeating unit corresponds to the repeating unit (a) having an aromatic ring.

(Repeating Unit Having Lactone Group or Sultone Group)

The resin (1) preferably contains a repeating unit having a group having a lactone group or a sultone (cyclic sulfonic acid ester) group. As the lactone group or sultone group, any group having a lactone structure or sultone structure can be used, and is preferably a group having a 5- to 7-membered ring lactone structure or sultone structure, with those having a 5- to 7-membered ring lactone structure or sultone structure to which another ring structure is fused so as to form a bicyclo structure or spiro structure being preferable.

The resin (1) still more preferably has a repeating unit having a lactone structure represented by any one of General Formulae (LC1-1) to (LC1-17), or a sultone structure represented by any one of General Formulae (SL1-1) to (SL1-3). Further, the group having a lactone structure or a sultone structure may be directly bonded to a main chain. A preferred lactone structure or sultone structure is a group represented by General Formula (LC1-1), (LC1-4), (LC1-5), (LC1-6), (LC1-13), or (LC1-14).

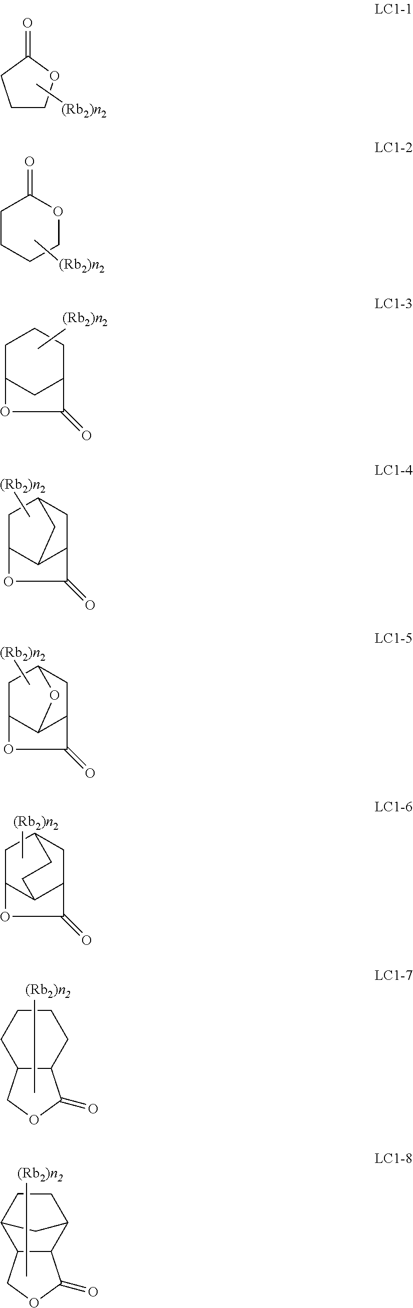

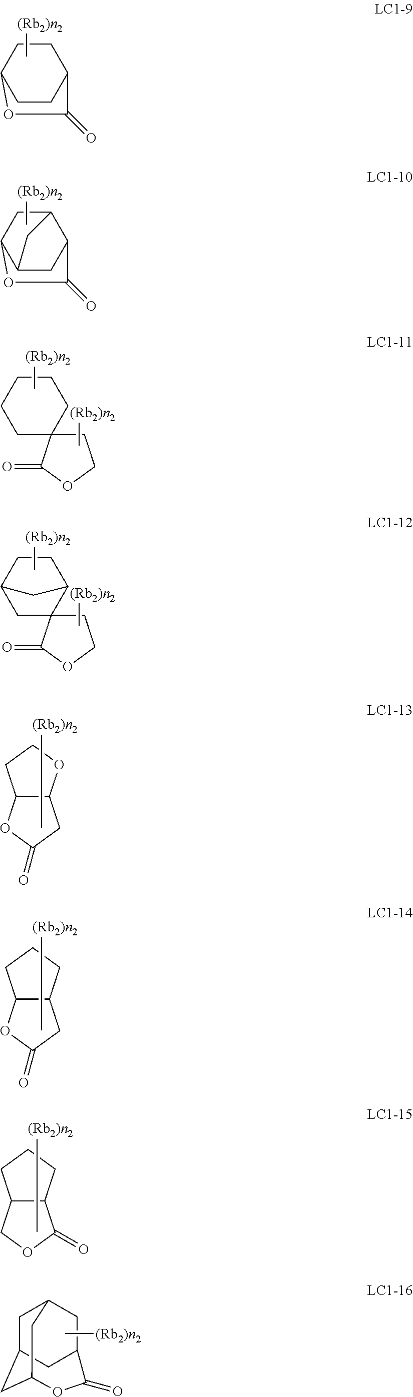

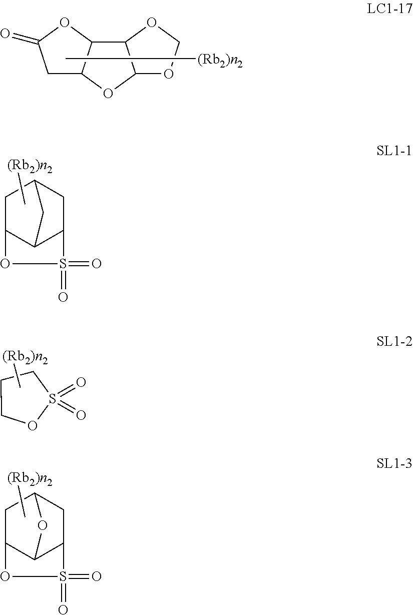

The lactone structure moiety or the sultone structure moiety may or may not have a substituent (Rb₂). Preferred examples of the substituent (Rb₂) include an alkyl group having 1 to 8 carbon atoms, a cycloalkyl group having 4 to 7 carbon atoms, an alkoxy group having 1 to 8 carbon atoms, an alkoxycarbonyl group having 1 to 8 carbon atoms, a carboxyl group, a halogen atom, a hydroxyl group, a cyano group, and an acid-decomposable group. n₂ represents an integer of 0 to 4. In a case where n₂ is 2 or more, Rb₂'s which are present in plural numbers may be the same as or different from each other, and further, Rb₂'s which are present in plural numbers may be bonded to each other to form a ring.

Examples of the repeating unit having a group having a lactone structure represented by any one of General Formulae (LC1-1) to (LC1-17) or a sultone structure represented by any one of General Formulae (SL1-1) to (SL1-3) include a repeating unit represented by General Formula (BI).

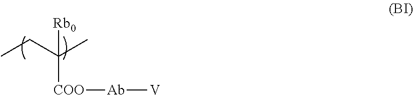

In General Formula (BI), Rb₀ represents a hydrogen atom, a halogen atom, or an alkyl group having 1 to 4 carbon atoms.

Preferred examples of the substituent which may be contained in the alkyl group of Rb₀ include a hydroxyl group and a halogen atom.

Examples of the halogen atom of Rb₀ include a fluorine atom, a chlorine atom, a bromine atom, and an iodine atom. Rb₀ is preferably a hydrogen atom or a methyl group.

Ab represents a single bond, an alkylene group, a divalent linking group having a monocyclic or polycyclic alicyclic hydrocarbon structure, an ether group, an ester group, a carbonyl group, a carboxyl group, or a divalent group formed by combination thereof. Ab is preferably a single bond or a linking group represented by -Ab₁-CO₂—. Ab₁ is a linear or branched alkylene group or a monocyclic or polycyclic cycloalkylene group, and preferably a methylene group, an ethylene group, a cyclohexylene group, an adamantylene group, or a norbornylene group.

V represents a group represented by any one of General Formulae (LC1-1) to (LC1-17) and (SL1-1) to (SL1-3).

As the repeating unit having a lactone group or a sultone group, an optical isomer thereof is usually present, and any optical isomer may be used. Further, one kind of optical isomer may be used singly or a plurality of optical isomers may be mixed and used. In a case of mainly using one kind of optical isomer, the optical purity (ee) thereof is preferably 90 or more, and more preferably 95 or more.

Specific examples of the repeating unit having a lactone group or a sultone group are shown below, but the present invention is not limited thereto.

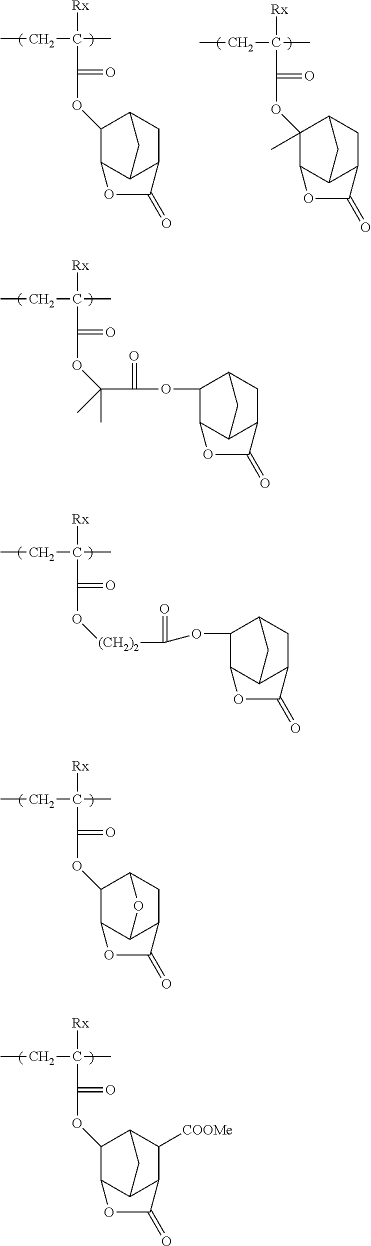

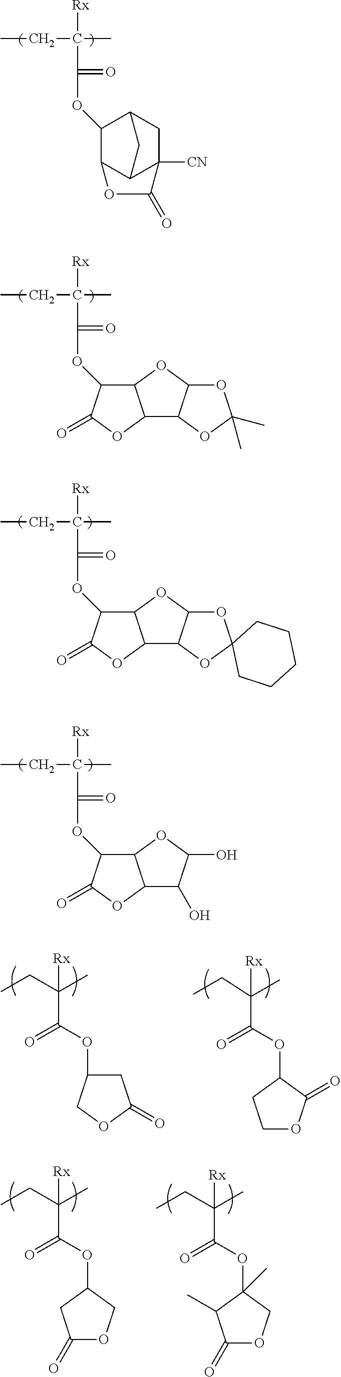

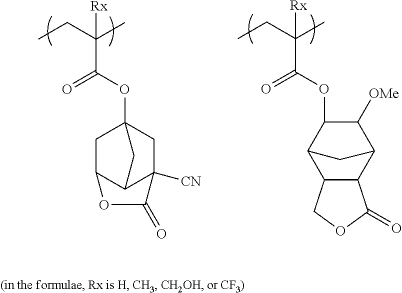

In a case where the resin (1) has a repeating unit having a lactone group or a sultone group, the content of the repeating unit having a lactone group or a sultone group is preferably 1% to 30% by mole, more preferably 5% to 25% by mole, and still more preferably 5% to 20% by mole, with respect to all the repeating units in the resin (1).

(Repeating Unit Having Silicon Atom in Side Chain)

The resin (1) may have a repeating unit having a silicon atom in a side chain.

The repeating unit having a silicon atom in a side chain is not particularly limited as long as it has a silicon atom in a side chain, but examples thereof include a (meth)acrylate-based repeating unit having a silicon atom and a vinyl-based repeating unit having a silicon atom.

The repeating unit having a silicon atom is preferably a repeating unit not having a structure in which a polar group is protected with a leaving group that leaves through decomposition by the action of an acid (acid-decomposable group).

The repeating unit having a silicon atom in a side chain is typically a repeating unit having a group having a silicon atom in a side chain, and examples of the group having a silicon atom include a trimethylsilyl group, a triethylsilyl group, a triphenylsilyl group, a tricyclohexylsilyl group, a tristrimethylsiloxysilyl group, a tristrimethylsilylsilyl group, a methylbi strimethylsilylsilyl group, a methylbi strimethylsiloxysilyl group, a dimethyltrimethylsilylsilyl group, a dimethyltrimethylsiloxysilyl group, or a cyclic or linear polysiloxane as described below, or a cage type, ladder type, or random type silsesquioxane structure. In the formula, R, and R¹ each independently represent a monovalent substituent. * represents a bonding arm.

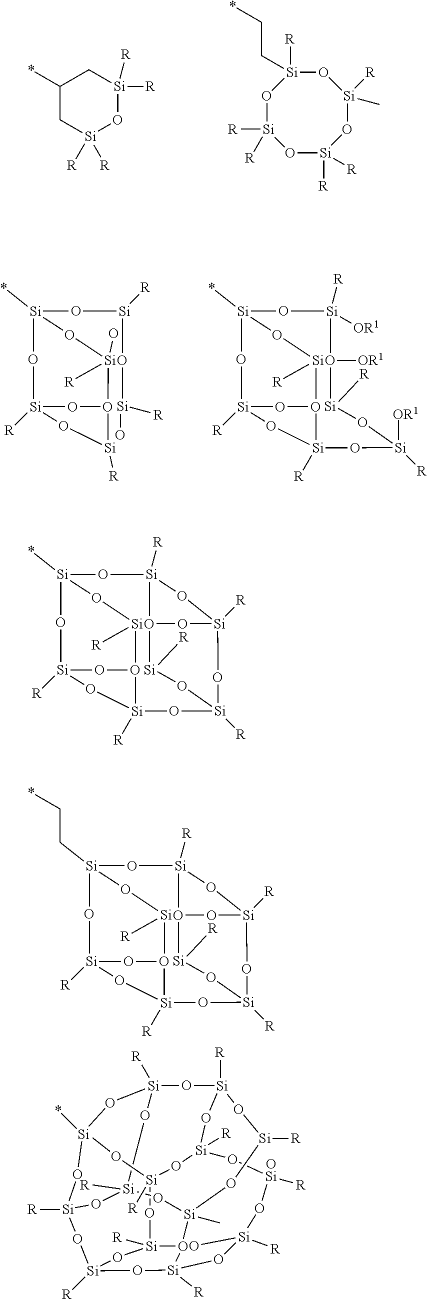

Suitable examples of the repeating unit having the above-mentioned group include a repeating unit derived from an acrylate or methacrylate compound having the above-mentioned group and a repeating unit derived from a compound having the above-mentioned group and a vinyl group.

The repeating unit having a silicon atom is preferably a repeating unit having a silsesquioxane structure, and with such a structure, the repeating unit can exhibit extremely excellent collapse performance in the formation of an ultrafine pattern (for example, a pattern with a line width of 50 nm or less), which has a cross-section having a high aspect ratio (for example, a ratio of film thickness/line width of 2 or more).

Examples of the silsesquioxane structure include a cage type silsesquioxane structure, a ladder type silsesquioxane structure, and a random type silsesquioxane structure. Among these, the cage type silsesquioxane structure is preferable.

Here, the cage type silsesquioxane structure is a silsesquioxane structure having a cage shape skeleton. The cage type silsesquioxane structure may be either a full cage type silsesquioxane structure or a partial cage type silsesquioxane structure, with the full cage type silsesquioxane structure being preferable.

Furthermore, the ladder type silsesquioxane structure is a silsesquioxane structure having a ladder shape skeleton.

In addition, the random type silsesquioxane structure is a silsesquioxane structure having a random skeleton.

The cage type silsesquioxane structure is preferably a siloxane structure represented by Formula (S).

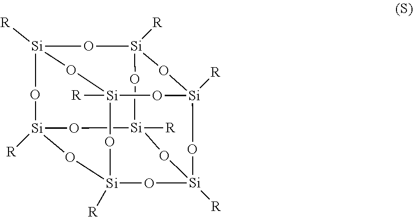

In Formula (S), R represents a monovalent substituent. R's which are present in plural numbers may be the same as or different from each other.

The monovalent substituent is not particularly limited, but specific examples thereof include a halogen atom, a hydroxyl group, a nitro group, a carboxyl group, an alkoxy group, an amino group, a mercapto group, a blocked mercapto group (for example, a mercapto group blocked (protected) with an acyl group), an acyl group, an imido group, a phosphino group, a phosphinyl group, a silyl group, a vinyl group, a hydrocarbon group which may have a heteroatom, a (meth)acryl group-containing group, and an epoxy group-containing group.

Examples of the halogen atom include a fluorine atom, a chlorine atom, a bromine atom, and an iodine atom.

Examples of the heteroatom of the hydrocarbon group which may have the heteroatom include an oxygen atom, a nitrogen atom, a sulfur atom, and a phosphorus atom.

Examples of the hydrocarbon group in the hydrocarbon group which may have the heteroatom include an aliphatic hydrocarbon group, an aromatic hydrocarbon group, and a group formed by combination thereof.

The aliphatic hydrocarbon group may be linear, branched, or cyclic. Specific examples of the aliphatic hydrocarbon group include a linear or branched alkyl group (in particular, having 1 to 30 carbon atoms), a linear or branched alkenyl group (in particular, having 2 to 30 carbon atoms), and a linear or branched alkynyl group (in particular, having 2 to 30 carbon atoms).

Examples of the aromatic hydrocarbon group include an aromatic hydrocarbon group having 6 to 18 carbon atoms, such as a phenyl group, a tolyl group, a xylyl group, and a naphthyl group.

The repeating unit having a silicon atom is preferably represented by Formula (I).

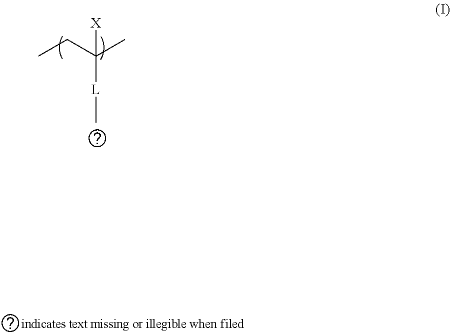

In Formula (I), L represents a single bond or a divalent linking group.

Examples of the divalent linking group include an alkylene group, a —COO-Rt- group, and an —O-Rt- group. In the formula, Rt represents an alkylene group or a cycloalkylene group.

L is preferably a single bond or a —COO-Rt- group. Rt is preferably an alkylene group having 1 to 5 carbon atoms, and more preferably a —CH₂— group, a —(CH₂)₂— group, or a —(CH₂)₃— group.

In Formula (I), X represents a hydrogen atom or an organic group.

Examples of the organic group include an alkyl group which may have a substituent such as a fluorine atom and a hydroxyl group, and the organic group is preferably a hydrogen atom, a methyl group, a trifluoromethyl group, or a hydroxymethyl group.

In Formula (I), A represents a silicon atom-containing group. Among those, a group represented by Formula (a) or (b) is preferable.

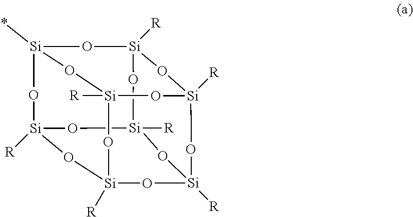

In Formula (a), R represents a monovalent substituent. R's which are present in plural numbers may be the same as or different from each other. Specific examples and suitable embodiments of R are the same as those of the above-mentioned Formula (S). In addition, in a case where A in Formula (I) is a group represented by Formula (a), Formula (I) is represented by Formula (I-a).

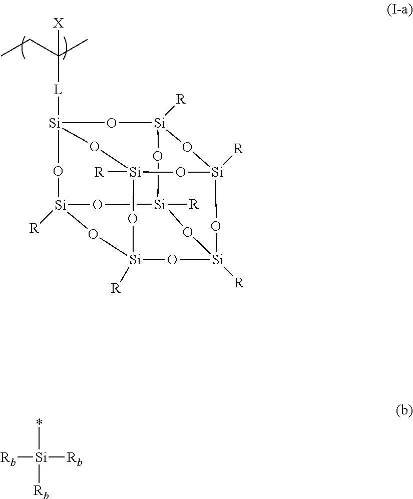

In Formula (b), R_{b} represents a hydrocarbon group which may have a heteroatom. Specific examples and suitable embodiments of the hydrocarbon group which may have a heteroatom are the same as those of R in Formula (S) as mentioned above.

In a case where the resin (1) has a repeating unit having a silicon atom, it may have one kind or two or more kinds of the repeating units having a silicon atom.

In a case where the resin (1) has a repeating unit having a silicon atom, the content of the repeating unit having a silicon atom is preferably 1% to 30% by mole, more preferably 1% to 20% by mole, and still more preferably 1% to 10% by mole, with respect to all the repeating units of the resin (1).

(Other Repeating Units)

The resin (1) may further have a repeating unit other than the above-mentioned repeating units. Examples of such other repeating unit may further have a repeating unit containing an organic group having a polar group, in particular, a repeating unit having an alicyclic hydrocarbon structure substituted with a polar group.

Thus, substrate adhesiveness and developer affinity are improved. As the alicyclic hydrocarbon structure substituted with a polar group, an adamantyl group, a diadamantyl group, or a norbornane group is preferable. As the polar group, a hydroxyl group or a cyano group is preferable. Specific examples of the repeating unit having a polar group are shown below, but the present invention is not limited thereto.

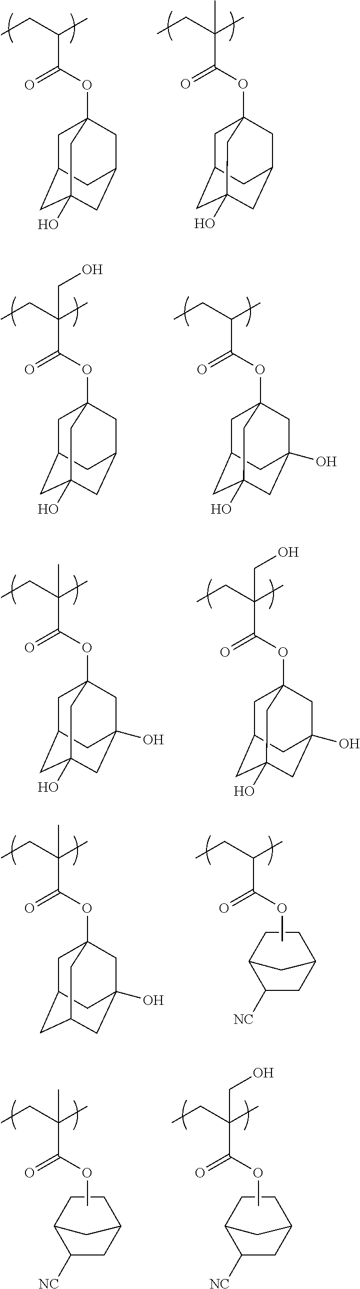

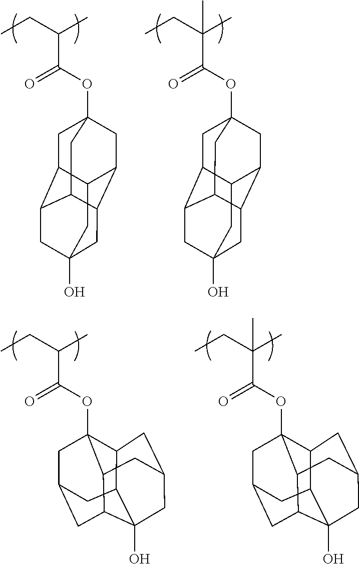

In a case where the resin (1) has a repeating unit containing an organic group having a polar group, the content of the repeating unit containing an organic group is preferably 1% to 30% by mole, more preferably 5% to 25% by mole, and still more preferably 5% to 20% by mole, with respect to all the repeating units in the resin (1).

Furthermore, the resin (1) may further include, as other repeating units, a repeating unit having a group capable of generating an acid upon irradiation with actinic rays or radiation (photoacid-generating group). In this case, it can be thought that the repeating unit having a photoacid-generating group corresponds to a compound (B) that generates an acid upon irradiation with actinic rays or radiation which will be described later.

Examples of such a repeating unit include a repeating unit represented by General Formula (4).

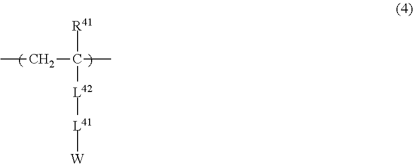

R⁴¹ represents a hydrogen atom or a methyl group. L⁴¹ represents a single bond or a divalent linking group. L⁴² represents a divalent linking group. W represents a structural site that generates an acid in a side chain through decomposition upon irradiation with actinic rays or radiation.

Other examples of the repeating unit represented by General Formula (4) include the repeating units described in paragraphs <0094> to <0105> of JP2014-041327A.

In a case where the resin (1) contains a repeating unit having a photoacid-generating group, the content of the repeating unit having a photoacid-generating group is preferably 1% to 40% by mole, more preferably 5% to 35% by mole, and still more preferably 5% to 30% by mole, with respect to all the repeating units in the resin (1).

Moreover, particularly in a case of performing EUV exposure, a repeating unit to which an atom for enhancing absorption of EUV has been introduced may be introduced into the resin (1) for the purpose of improving sensitivity. Examples of such an atom include a fluorine atom, an iodine atom, and a metal atom, and preferably repeating units corresponding to the following monomers.

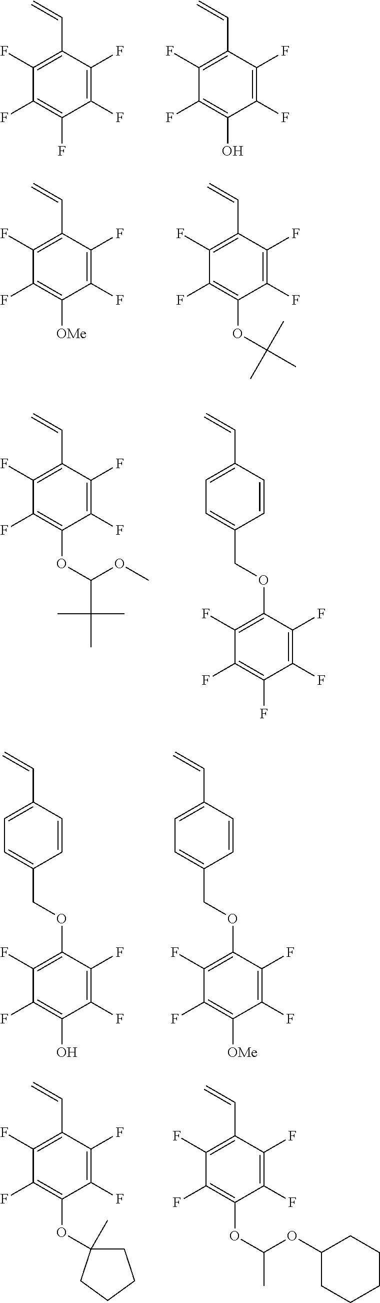

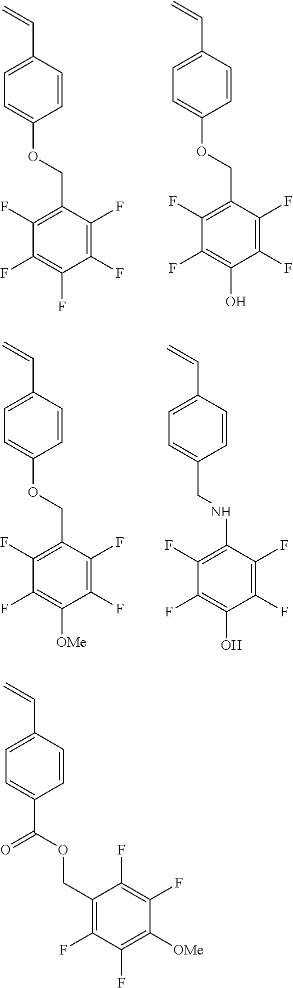

Furthermore, in the actinic ray-sensitive or radiation-sensitive resin composition, the resin (1) may be used singly or in combination of a plurality of kinds thereof.

The content of the resin (1) is preferably 50% to 99.9% by mass, and more preferably 60% to 99.0% by mass, in the total solid content of the actinic ray-sensitive or radiation-sensitive resin composition.

<(B) Compound that Generates Acid with Actinic Rays or Radiation>

The actinic ray-sensitive or radiation-sensitive resin composition preferably contains a compound that generates an acid with actinic rays or radiation (also referred to as a “photoacid generator <<PAG>>” or a “compound (B)”).

The photoacid generator may be in a form of a low molecular compound or in a form of being introduced into a part of a polymer. Further, a combination of the form of a low molecular compound and the form of being introduced into a part of a polymer may also be used.

In a case where the photoacid generator is in the form of a low molecular compound, the molecular weight thereof is preferably 3,000 or less, more preferably 2,000 or less, and still more preferably 1,000 or less.

In a case where the photoacid generator is in the form of being introduced into a part of a polymer, it may be introduced into a part of the resin (1) or into a resin other than the resin (1).

For the purpose of adjusting the cross-sectional shape of a pattern, the number of fluorine atoms contained in the acid generator is appropriately adjusted. By adjusting the number of fluorine atoms, it is possible to control the surface unevenness of the acid generator in the resist film. As the acid generator has more fluorine atoms, the surface unevenness is higher.

In the present invention, the photoacid generator is preferably in the form of a low molecular compound.

Although the photoacid generator is not particularly limited as long as it is a known photoacid generator, the photoacid generator is preferably a compound that generates an organic acid, for example, at least one of sulfonic acid, bis(alkylsulfonyl)imide, or tris(alkylsulfonyl)methide, upon irradiation with actinic rays or radiation, and preferably electron beams or extreme ultraviolet rays.

More preferred examples of the photoacid generator include compounds represented by General Formulae (ZI), (ZII), and (ZIII).

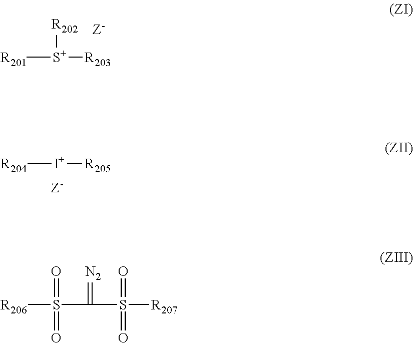

In General Formula (ZI),

R₂₀₁, R₂₀₂, and R₂₀₃ each independently represent an organic group.

The number of carbon atoms of the organic group as R₂₀₁, R₂₀₂, and R₂₀₃ is generally 1 to 30, and preferably 1 to 20.

Furthermore, two of R₂₀₁ to R₂₀₃ may be bonded to each other to form a ring structure, and the ring may include an oxygen atom, a sulfur atom, an ester bond, an amide bond, or a carbonyl group, and examples of the group formed by the bonding of two of R₂₀₁ to R₂₀₃ include an alkylene group (for example, a butylene group and a pentylene group).

Z⁻ represents a non-nucleophilic anion (anion having an extremely low ability of causing a nucleophilic reaction).

Examples of the non-nucleophilic anion include a sulfonate anion (such as an aliphatic sulfonate anion, an aromatic sulfonate anion, and a camphor sulfonate anion), a carboxylate anion (such as an aliphatic carboxylate anion, an aromatic carboxylate anion, and an aralkyl carboxylate anion), a sulfonylimide anion, a bis(alkylsulfonyl)imide anion, and a tris(alkylsulfonyl)methide anion.

The aliphatic moiety in the aliphatic sulfonate anion and the aliphatic carboxylate anion may be an alkyl group or a cycloalkyl group, and preferred examples thereof include a linear or branched alkyl group having 1 to 30 carbon atoms and a cycloalkyl group having 3 to 30 carbon atoms.

Preferred examples of the aromatic group in the aromatic sulfonate anion and aromatic carboxylate anion include an aryl group having 6 to 14 carbon atoms, such as a phenyl group, a tolyl group, and a naphthyl group.

The alkyl group, the cycloalkyl group, and the aryl group mentioned above may have a substituent. Specific examples of the substituent include a nitro group, a halogen atom such as fluorine atom, a carboxyl group, a hydroxyl group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an alkylthio group (preferably having 1 to 15 carbon atoms), an alkylsulfonyl group (preferably having 1 to 15 carbon atoms), an alkyliminosulfonyl group (preferably having 1 to 15 carbon atoms), an aryloxysulfonyl group (preferably having 6 to 20 carbon atoms), an alkylaryloxysulfonyl group (preferably having 7 to 20 carbon atoms), a cycloalkylaryloxysulfonyl group (preferably having 10 to 20 carbon atoms), an alkyloxyalkyloxy group (preferably having 5 to 20 carbon atoms), and a cycloalkylalkyloxyalkyloxy group (preferably having 8 to 20 carbon atoms). The aryl group or the ring structure which is contained in each group may further have an alkyl group (preferably having 1 to 15 carbon atoms) as a substituent.

Preferred examples of the aralkyl group in the aralkyl carboxylate anion include an aralkyl group having 7 to 12 carbon atoms, such as a benzyl group, a phenethyl group, a naphthylmethyl group, a naphthylethyl group, and a naphthylbutyl group.

Examples of the sulfonylimide anion include a saccharin anion.

The alkyl group in the bis(alkylsulfonyl)imide anion and the tris(alkylsulfonyl)methide anion is preferably an alkyl group having 1 to 5 carbon atoms. Examples of the substituent of this alkyl group include a halogen atom, a halogen atom-substituted alkyl group, an alkoxy group, an alkylthio group, an alkyloxysulfonyl group, an aryloxysulfonyl group, and a cycloalkylaryloxysulfonyl group, with the fluorine atom and the fluorine atom-substituted alkyl group being preferable.

In addition, the alkyl groups in the bis(alkylsulfonyl)imide anion may be bonded to each other to form a ring structure. Thus, the acid strength is increased.

Other examples of the non-nucleophilic anion include fluorinated phosphorus (for example, PF₆⁻), fluorinated boron (for example, BF₄⁻), and fluorinated antimony (for example, SbF₆⁻).

The non-nucleophilic anion is preferably an aliphatic sulfonate anion substituted with a fluorine atom at least at the α-position of the sulfonic acid, an aromatic sulfonate anion substituted with a fluorine atom or a fluorine atom-containing group, a bis(alkylsulfonyl)imide anion in which the alkyl group is substituted with a fluorine atom, or a tris(alkylsulfonyl)methide anion in which the alkyl group is substituted with a fluorine atom. The non-nucleophilic anion is more preferably a perfluoroaliphatic sulfonate anion (still more preferably having 4 to 8 carbon atoms) or a fluorine atom-containing benzenesulfonate anion, and still more preferably a nonafluorobutanesulfonate anion, a perfluorooctanesulfonate anion, a pentafluorobenzenesulfonate anion, or a 3,5-bis(trifluoromethyl)benzenesulfonate anion.

From the viewpoint of the acid strength, the pKa of the acid generated is preferably −1 or less so as to improve the sensitivity.

Moreover, an anion represented by General Formula (AN1) may also be mentioned as a preferred embodiment of the non-nucleophilic anion.

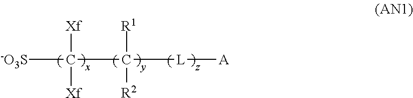

In the formula,

Xf's each independently represent a fluorine atom or an alkyl group substituted with at least one fluorine atom.

R1 and R2 each independently represent a hydrogen atom, a fluorine atom or an alkyl group, and R1's or R2's in a case where a plurality of R1's or R2's are present may be the same as or different from each other.

L represents a divalent linking group, and L's in a case where a plurality of L's are present may be the same as or different from each other.

A represents a cyclic organic group.

x represents an integer of 1 to 20, y represents an integer of 0 to 10, and z represents an integer of 0 to 10.

General Formula (AN1) will be described in more detail.

The alkyl group in the fluorine atom-substituted alkyl group of Xf is preferably an alkyl group having 1 to 10 carbon atoms, and more preferably an alkyl group having 1 to 4 carbon atoms. Further, the fluorine atom-substituted alkyl group of Xf is preferably a perfluoroalkyl group.

Xf is preferably a fluorine atom or a perfluoroalkyl group having 1 to 4 carbon atoms. Specific examples of Xf include a fluorine atom, CF₃, C₂F₅, C₃F₇, C₄F₉, CH₂CF₃, CH₂CH₂CF₃, CH₂C₂F₅, CH₂CH₂C₂F₅, CH₂C₃F₇, CH₂CH₂C₃F₇, CH₂C₄F₉, and CH₂CH₂C₄F₉, and among these, the fluorine atom and CF₃ are preferable. In particular, it is preferable that both Xf s are fluorine atoms.

The alkyl group of each of R¹ and R² may have a substituent (preferably a fluorine atom) and is preferably an alkyl group having 1 to 4 carbon atoms, and more preferably a perfluoroalkyl group having 1 to 4 carbon atoms. Specific examples of the alkyl group having a substituent of R¹ and R² include CF₃, C₂F₅, C₃F₇, C₄F₉, C₅F₁ᵢ, C₆F₁₃, C₇F₁ₛ, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉, and CH₂CH₂C₄F₉, and among these, CF₃ is preferable.

R¹ and R² are each preferably a fluorine atom or CF₃.

x is preferably 1 to 10, and more preferably 1 to 5.

y is preferably 0 to 4, and more preferably 0.

z is preferably 0 to 5, and more preferably 0 to 3.

The divalent linking group of L is not particularly limited and examples thereof include —COO—, —COO—, —CO—, —O—, —S—, —SO—, —SO₂—, an alkylene group, a cycloalkylene group, an alkenylene group, and a linking group formed by combining a plurality thereof. A linking group having a total number of carbon atoms of 12 or less is preferable. Among these, —COO—, —OCO—, —CO—, and —O— are preferable, and —COO— and —OCO— are more preferable.

The cyclic organic group of A is not particularly limited as long as it has a cyclic structure, and examples thereof include an alicyclic group, an aryl group, and a heterocyclic group (including not only those having aromaticity but also those having no aromaticity).

The alicyclic group may be monocyclic or polycyclic and is preferably a monocyclic cycloalkyl group such as a cyclopentyl group, a cyclohexyl group, and a cyclooctyl group, or a polycyclic cycloalkyl group such as a norbornyl group, a tricyclodecanyl group, a tetracyclodecanyl group, a tetracyclododecanyl group, and an adamantyl group. Among those, an alicyclic group having a bulky structure having 7 or more carbon atoms, such as a norbornyl group, a tricyclodecanyl group, a tetracyclodecanyl group, a tetracyclododecanyl group, and an adamantyl group, is preferable from the viewpoint that the diffusibility in the film in a heating step after exposure can be suppressed and mask error enhancement factor (MEEF) can be improved.

Examples of the aryl group include a benzene ring, a naphthalene ring, a phenanthrene ring, and an anthracene ring.

Examples of the heterocyclic group include those derived from a furan ring, a thiophene ring, a benzofuran ring, a benzothiophene ring, a dibenzofuran ring, a dibenzothiophene ring, and a pyridine ring. Among these, heterocyclic groups derived from a furan ring, a thiophene ring and a pyridine ring are preferable.

Moreover, other examples of the cyclic organic group include a lactone structure, and specific examples thereof include lactone structures represented by General Formulae (LC1-1) to (LC1-17).

The cyclic organic group may have a substituent, and examples of the substituent include an alkyl group (may be in any one of linear, branched, and cyclic forms; preferably having 1 to 12 carbon atoms), a cycloalkyl group (may be in any one of monocyclic, polycyclic, and spirocyclic forms; preferably having 3 to 20 carbon atoms), an aryl group (preferably having 6 to 14 carbon atoms), a hydroxyl group, an alkoxy group, an ester group, an amido group, a urethane group, a ureido group, a thioether group, a sulfonamido group, and a sulfonic acid ester group. Incidentally, the carbon constituting the cyclic organic group (the carbon contributing to ring formation) may be a carbonyl carbon.

Examples of the organic group of R₂₀₁, R₂₀₂, and R₂₀₃ include an aryl group, an alkyl group, and a cycloalkyl group.

It is preferable that at least one of three members R₂₀₁, R₂₀₂, or R₂₀₃ is an aryl group, and it is more preferable that all of these three members are an aryl group. The aryl group may be a heteroaryl group such as indole residue and pyrrole residue, other than a phenyl group, a naphthyl group and the like. The alkyl group and the cycloalkyl group of R₂₀₁ to R₂₀₃ may be preferably a linear or branched alkyl group having 1 to 10 carbon atoms and a cycloalkyl group having 3 to 10 carbon atoms. More preferred examples of the alkyl group include a methyl group, an ethyl group, an n-propyl group, an i-propyl group, and an n-butyl group. More preferred examples of the cycloalkyl group include a cyclopropyl group, a cyclobutyl group, a cyclopentyl group, a cyclohexyl group, and a cycloheptyl group. These groups may further have a substituent, and examples of the substituent include, but are not limited to, a nitro group, a halogen atom such as fluorine atom, a carboxyl group, a hydroxyl group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), and an alkoxycarbonyloxy group (preferably having 2 to 7 carbon atoms).

Preferred examples of the anion represented by General Formula (AN1) include the following structures. In the following examples, A represents a cyclic organic group.

SO₃—CF₂—CH₂—OCO-A, SO₃—CF₂—CHF—CH₂—OCO-A, SO₃—CF₂—COO-A, SO₃—CF₂—CF₂—CH₂-A, SO₃—CF₂—CH(CF₃)—OCO-A

In General Formulae (ZII) and (ZIII),

R₂₀₄ to R₂₀₇ each independently represent an aryl group, an alkyl group, or a cycloalkyl group.

The aryl group, the alkyl group, and the cycloalkyl group of R₂₀₄ to R₂₀₇ are each the same as the aryl groups mentioned as the aryl group, the alkyl group, and the cycloalkyl group of R₂₀₁ to R₂₀₃ in the compound (ZI).

The aryl group, the alkyl group, and the cycloalkyl group of R₂₀₄ to R₂₀₇ may have a substituent. Examples of the substituent include the substituents which may be included in the aryl group, the alkyl group, or the cycloalkyl group of R₂₀₁ to R₂₀₃ in the compound (ZI).

T represents a non-nucleophilic anion, and examples thereof include the same non-nucleophilic anions as those of Z⁻ in General Formula (ZI).

In the present invention, from the viewpoint of preventing an acid generated by exposure from diffusing to the unexposed area and thus improving the resolution, the photoacid generator is preferably a compound that generates an acid in a size with a volume of 130 Å³ or more (more preferably a sulfonic acid), more preferably a compound that generates an acid in a size with a volume of 190 Å³ or more (more preferably a sulfonic acid), still more preferably a compound that generates an acid in a size with a volume of 270 Å³ or more (more preferably sulfonic acid), and particularly preferably a compound that generates an acid in a size with a volume of 400 Å³ or more (more preferably sulfonic acid), upon irradiation with electron beams or extreme ultraviolet rays. However, from the viewpoint of the sensitivity or the solubility in the coating solvent, the volume is preferably 2,000 Å³ or less, and more preferably 1,500 Å³ or less. The value of the volume was determined using “WinMOPAC” produced by Fujitsu Limited. That is, first, the chemical structure of the acid in each compound is input, next, using this structure as an initial structure, the most stable steric conformation of each acid is determined by molecular force field calculation according to an MM3 method, and then, molecular orbital calculation using a PM3 method is performed with respect to the most stable steric conformation, whereby the “accessible volume” of each acid can be calculated.

1 Å is 1×10⁻¹⁰ m.

With regard to the photoacid generator, reference can be made to paragraphs <0368> to <0377> of JP2014-41328A, and paragraphs <0240> to <0262> of JP2013-228681A (<0339> of the corresponding US2015/004533A), the contents of which are incorporated herein. Further, specific preferred examples thereof include the following compounds, but are not limited thereto.

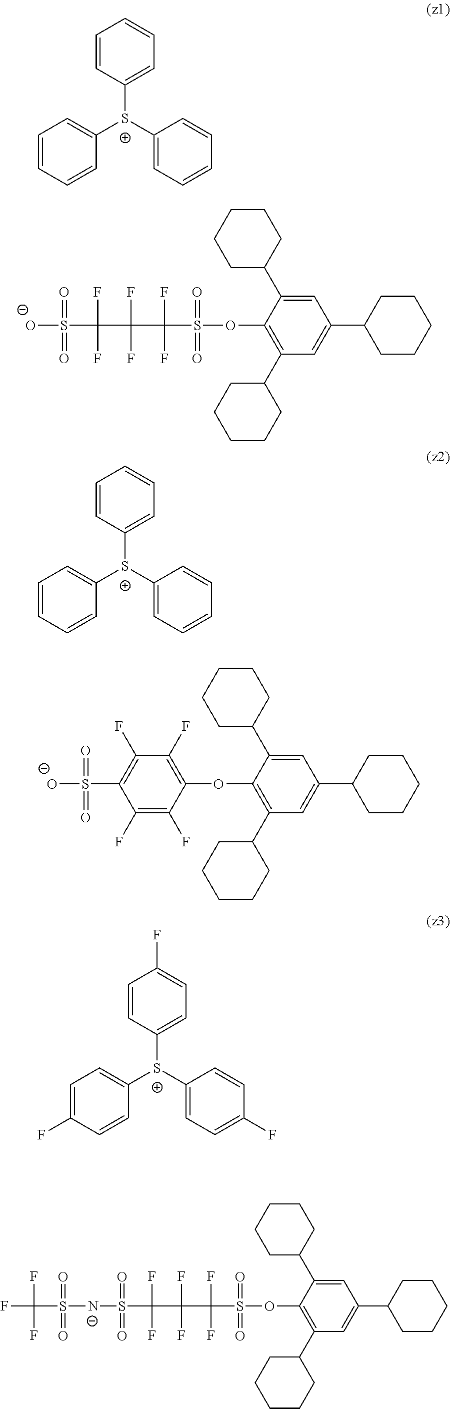 [SMILES: c1ccc([S+](c2ccccc2)c2ccccc2)cc1 ; O=S(=O)([O-])C(F)(F)C(F)(F)C(F)(F)S(=O)(=O)Oc1c(C2CCCCC2)cc(C2CCCCC2)cc1C1CCCCC1 ; c1ccc([S+](c2ccccc2)c2ccccc2)cc1 ; O=S(=O)([O-])c1c(F)c(F)c(Oc2c(C3CCCCC3)cc(C3CCCCC3)cc2C2CCCCC2)c(F)c1F ; Fc1ccc([S+](c2ccc(F)cc2)c2ccc(F)cc2)cc1 ; O=S(=O)([N-]S(=O)(=O)C(F)(F)C(F)(F)C(F)(F)S(=O)(=O)Oc1c(C2CCCCC2)cc(C2CCCCC2)cc1C1CCCCC1)C(F)(F)F]

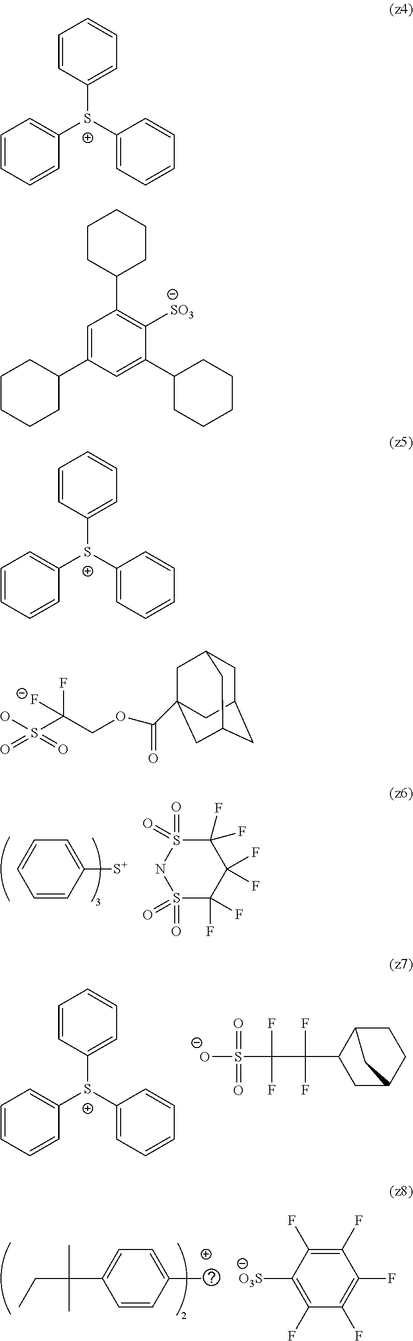

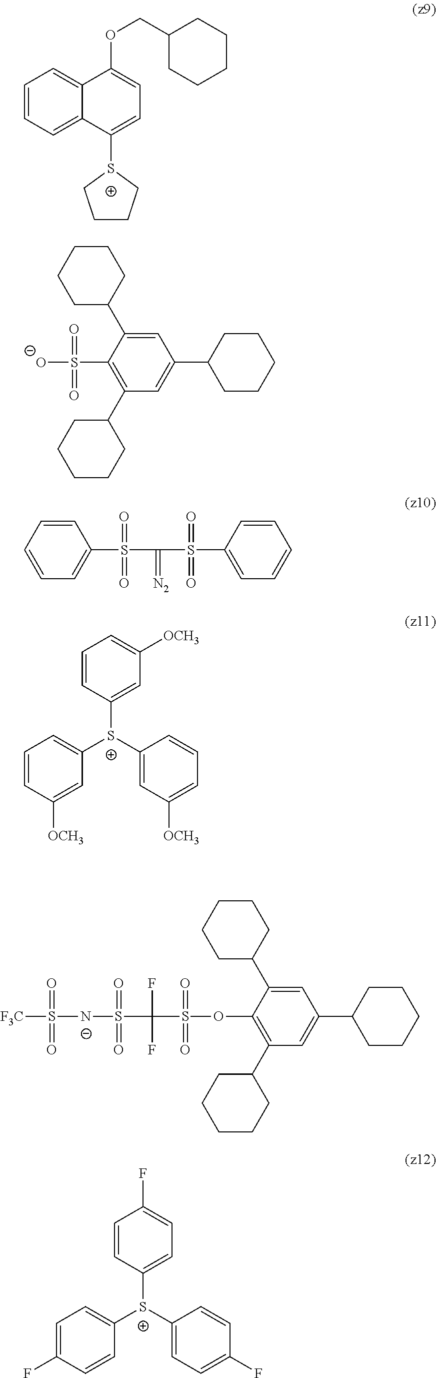

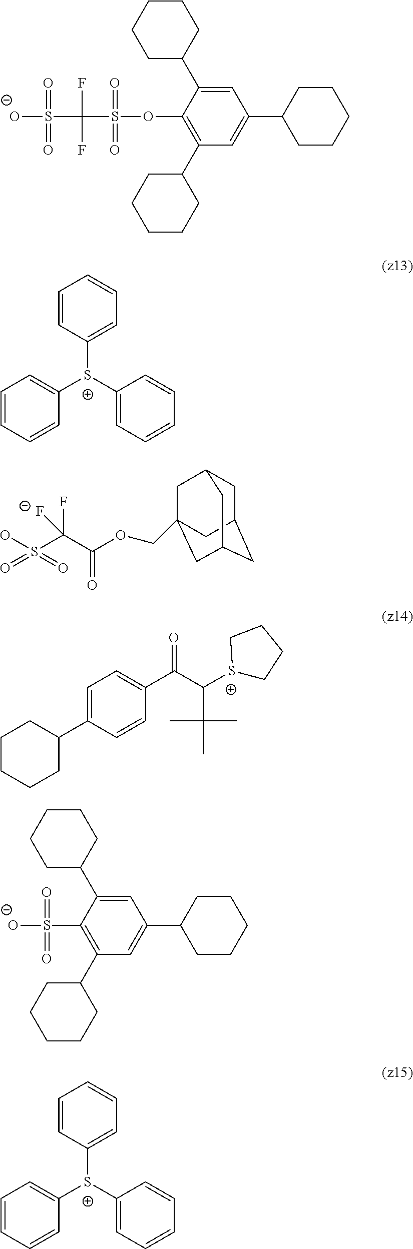

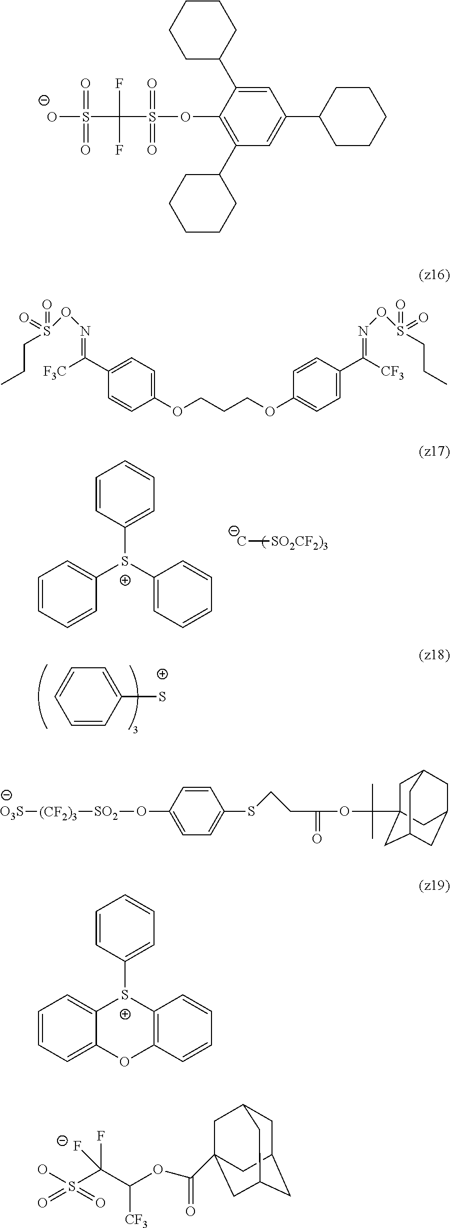

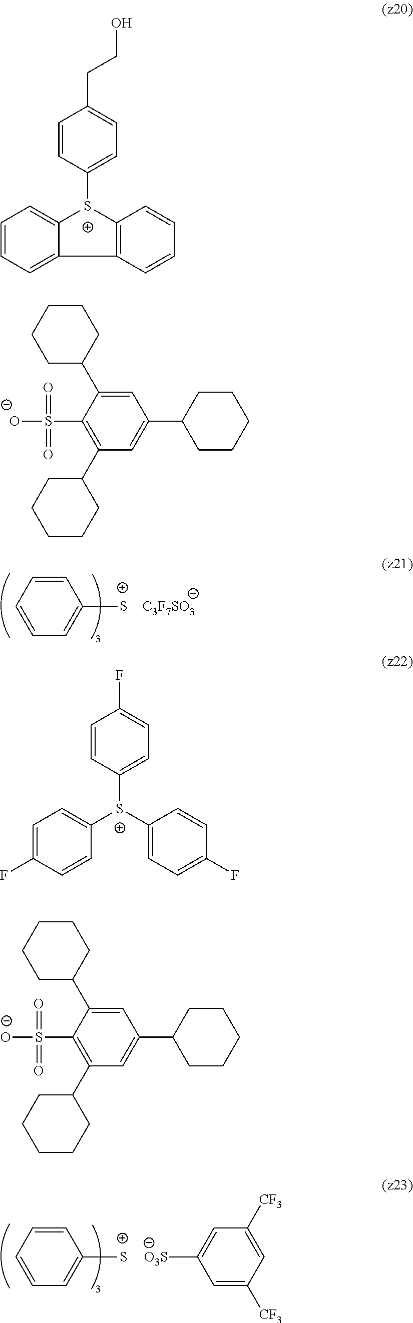

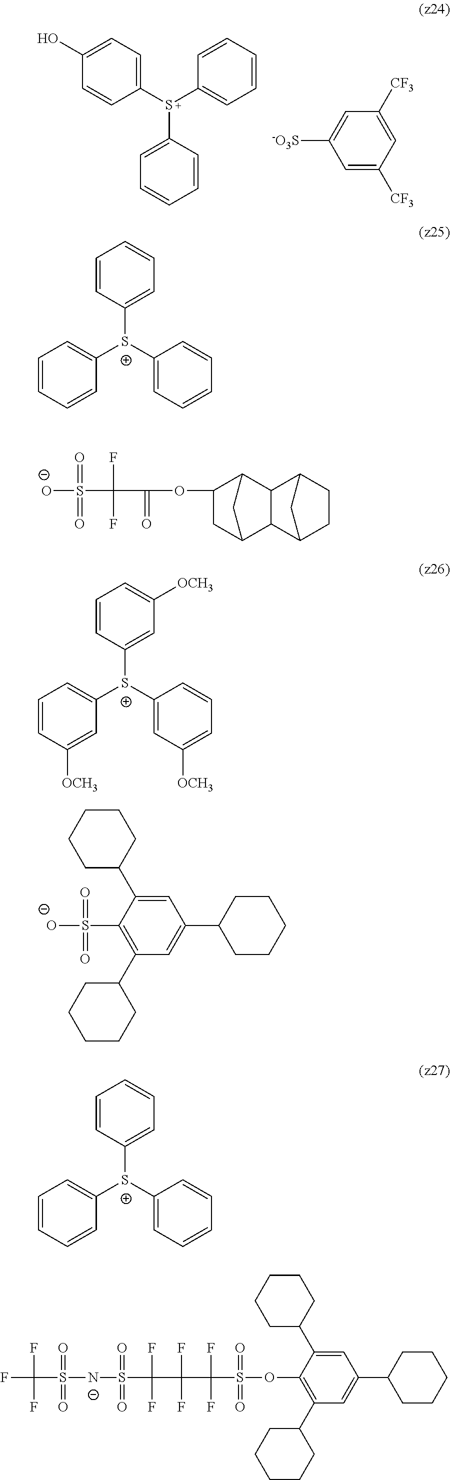

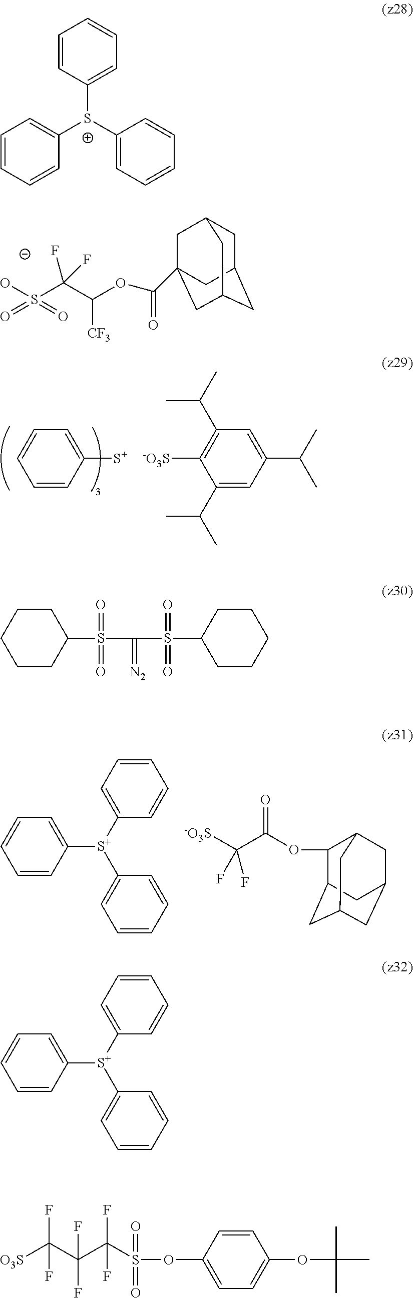

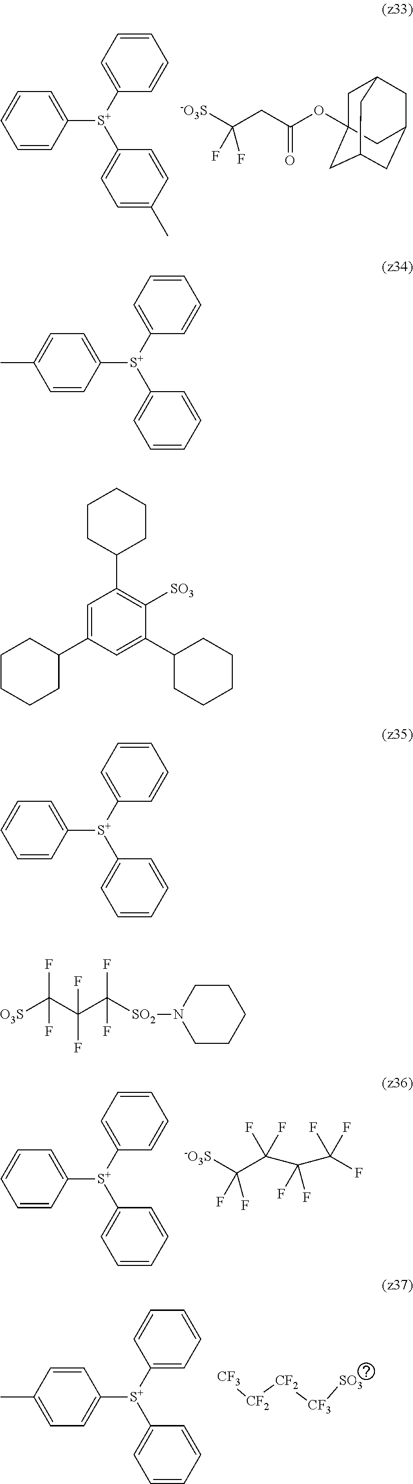

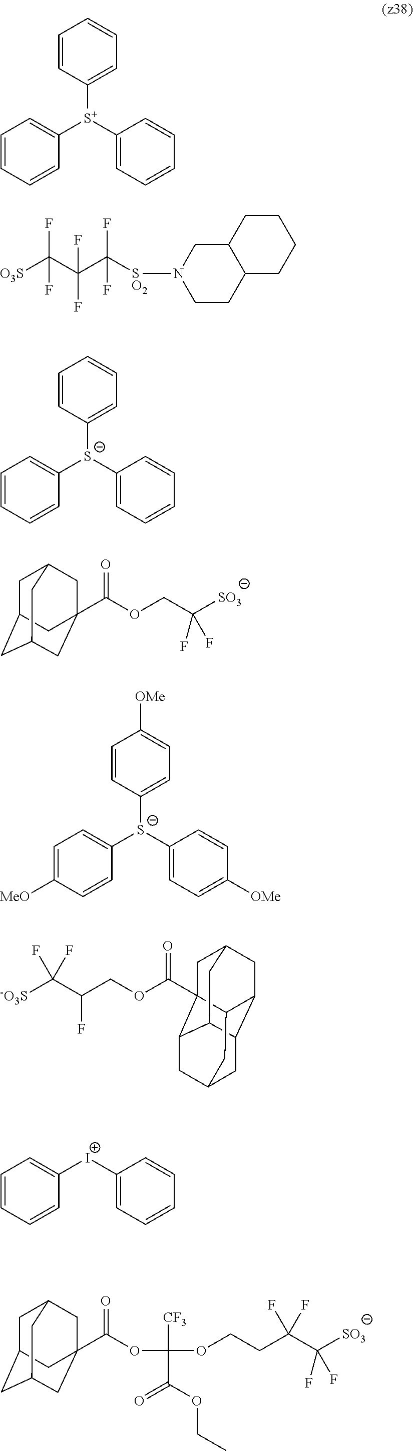

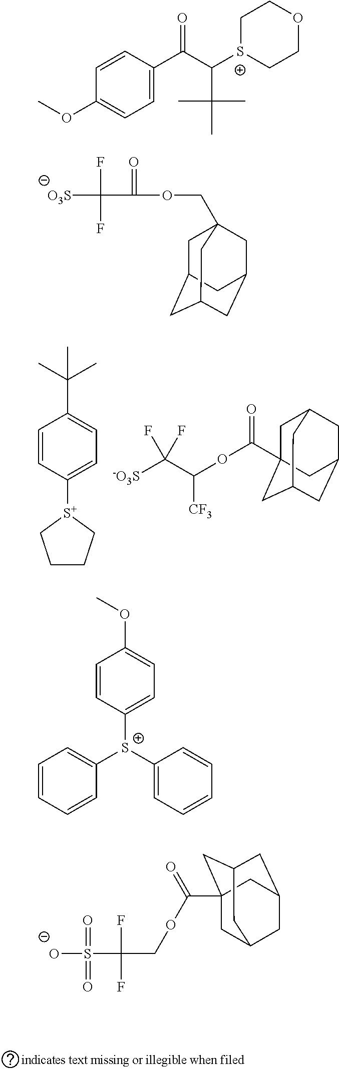

The photoacid generators may be used singly or in combination of two or more kinds thereof.

The content of the photoacid generator in the actinic ray-sensitive or radiation-sensitive resin composition is preferably 0.1% to 50% by mass, more preferably 5% to 50% by mass, and still more preferably 8% to 40% by mass, with respect to the total solid content of the composition. In particular, in order to satisfy both high sensitivity and high resolution upon exposure using electron beams or extreme ultraviolet rays, the content of the photoacid generator is preferably high, more preferably 10% to 40% by mass, and most preferably 10% to 35% by mass.

(C) Solvent

The actinic ray-sensitive or radiation-sensitive resin composition for use in the present invention preferably includes a solvent (also referred to as a “resist solvent”). Isomers (having the same atom numbers and different structures) may be included in the solvent. Further, one kind or a plurality of kinds of the isomers may be included. The solvent preferably includes at least one of propylene glycol monoalkyl ether carboxylate (M1), and at least one selected from the group consisting of propylene glycol monoalkyl ether, lactic acid ester, acetic acid ester, alkoxypropionic acid ester, chain ketone, cyclic ketone, lactone, and alkylene carbonate (M2). Further, this solvent may further include components other than the component (M1) and the component (M2).

As the component (M1), at least one selected from the group consisting of propylene glycol monomethyl ether acetate, propylene glycol monomethyl ether propionate, and propylene glycol monoethyl ether acetate is preferable, and propylene glycol monomethyl ether acetate is particularly preferable.

The component (M2) is preferably the following one.

The propylene glycol monoalkyl ether is preferably propylene glycol monomethyl ether or propylene glycol monoethyl ether.

The lactic acid ester is preferably ethyl lactate, butyl lactate, or propyl lactate.

The acetic acid ester is preferably methyl acetate, ethyl acetate, butyl acetate, isobutyl acetate, propyl acetate, isoamyl acetate, methyl formate, ethyl formate, butyl formate, propyl formate, or 3-methoxybutyl acetate.

Butyl butyrate is also preferable.

The alkoxypropionic acid ester is preferably methyl 3-methoxypropionate (MMP) or ethyl 3-ethoxypropionate (EEP).

The chain ketone is preferably 1-octanone, 2-octanone, 1-nonanone, 2-nonanone, acetone, 4-heptanone, 1-hexanone, 2-hexanone, diisobutyl ketone, phenyl acetone, methyl ethyl ketone, methyl isobutyl ketone, acetyl acetone, acetonyl acetone, ionone, diacetonyl alcohol, acetyl carbinol, acetophenone, methyl naphthyl ketone, or methylamyl ketone.

The cyclic ketone is preferably methyl cyclohexanone, isophorone, or cyclohexanone.

The lactone is preferably γ-butyrolactone.

The alkylene carbonate is preferably propylene carbonate.

The component (M2) is more preferably propylene glycol monomethyl ether, ethyl lactate, ethyl 3-ethoxypropionate, methylamyl ketone, cyclohexanone, butyl acetate, pentyl acetate, γ-butyrolactone, or propylene carbonate.

In addition to the components, it is preferable to use an ester-based solvent having 7 or more carbon atoms (preferably 7 to 14 carbon atoms, more preferably 7 to 12 carbon atoms, and still more preferably 7 to 10 carbon atoms), and having 2 or less heteroatoms.

Preferred examples of the ester-based solvent having 7 or more carbon atoms and 2 or less heteroatoms include amyl acetate, 2-methylbutyl acetate, 1-methylbutyl acetate, hexyl acetate, pentyl propionate, hexyl propionate, butyl propionate, isobutyl isobutyrate, heptyl propionate, and butyl butanoate, and isoamyl acetate is particularly preferably used.

As the component (M2), a component having a flash point (hereinafter also referred to as fp) of 37° C. or higher is preferably used. Such component (M2) is preferably propylene glycol monomethyl ether (fp: 47° C.), ethyl lactate (fp: 53° C.), ethyl 3-ethoxypropionate (fp: 49° C.), methylamyl ketone (fp: 42° C.), cyclohexanone (fp: 44° C.), pentyl acetate (fp: 45° C.), methyl 2-hydroxyisobutyrate (fp: 45° C.), γ-butyrolactone (fp: 101° C.), or propylene carbonate (fp: 132° C.). Among these, propylene glycol monoethyl ether, ethyl lactate, pentyl acetate, or cyclohexanone is more preferable, and propylene glycol monoethyl ether or ethyl lactate is particularly preferable. In addition, the “flash point” described here means a value described in the reagent catalog of Tokyo Chemical Industry Co., Ltd. or Sigma-Aldrich Co. LLC.

The solvent preferably includes the component (M1). It is more preferable that the solvent consists of substantially only the component (M1) or is a mixed solvent of the component (M1) and other components. In the latter case, the solvent still more preferably includes both the component (M1) and the component (M2).

The mass ratio of the component (M1) to the component (M2) is preferably within a range of 100:0 to 15:85, more preferably within a range of 100:0 to 40:60, and still more preferably within a range of 100:0 to 60:40. That is, it is preferable that the solvent consists of only the component (M1), or includes both the component (M1) and the component (M2) and the mass ratio thereof is as follows. That is, in the latter case, the mass ratio of the component (M1) to the component (M2) is preferably 15/85 or more, more preferably 40/60 or more, and still more preferably 60/40 or more. In a case where such a configuration is adopted, the number of development defects can further be reduced.

Moreover, in a case where the solvent includes both the component (M1) and the component (M2), the mass ratio of the component (M1) to the component (M2) is, for example, set to 99/1 or less.

As described above, the solvent may further include a component other than the component (M1) and the component (M2). In this case, the content of the component other than the component (M1) and the component (M2) is preferably within a range of 5% by mass to 30% by mass with respect to the total amount of the solvent.

The content of the solvent included in the actinic ray-sensitive or radiation-sensitive resin composition is preferably set such that the concentration of the solid contents of all the components reaches 0.5% to 30% by mass, and more preferably set such that the concentration of the solid contents of all the components reaches 1% to 20% by mass. By doing this, the coatability of the actinic ray-sensitive or radiation-sensitive resin composition can further be improved.

The concentration of the solid content of the actinic ray-sensitive or radiation-sensitive resin composition can be appropriately adjusted for the purpose of adjusting the thickness of the prepared resist film.

(E) Basic Compound

The actinic ray-sensitive or radiation-sensitive resin composition preferably contains a basic compound (E) in order to reduce a change in performance over time from exposure to heating.

Preferred examples of the basic compound include a compound having a structure represented by any one of Formulae (A) to (E).

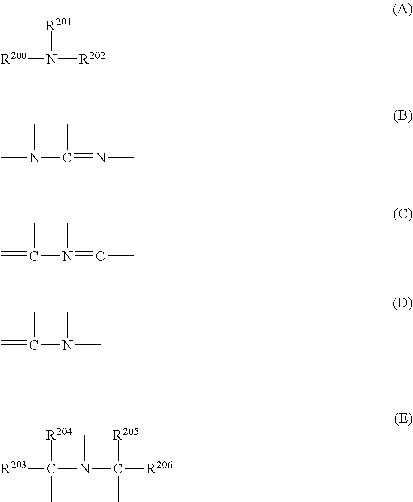

In General Formulae (A) to (E), R²⁰⁰, R²⁰¹, and R²⁰² may be the same as or different from each other, and each represent a hydrogen atom, an alkyl group (preferably having 1 to 20 carbon atoms), a cycloalkyl group (preferably having 3 to 20 carbon atoms), or an aryl group (preferably having 6 to 20 carbon atoms), in which R²⁰¹ and R²⁰² may be bonded to each other to form a ring.

With respect to the alkyl group, as the alkyl group having a substituent, an aminoalkyl group having 1 to 20 carbon atoms, a hydroxyalkyl group having 1 to 20 carbon atoms, or a cyanoalkyl group having 1 to 20 carbon atoms is preferable.

R²⁰³, R²⁰⁴, R²⁰⁵, and R²⁰⁶ may be the same as or different from each other, and each represent an alkyl group having 1 to 20 carbon atoms.

The alkyl group in General Formulae (A) to (E) is more preferably unsubstituted.

Preferred examples of the compound include guanidine, aminopyrrolidine, pyrazole, pyrazoline, piperazine, aminomorpholine, aminoalkylmorpholine and piperidine. More preferred examples of the compound include a compound having an imidazole structure, a diazabicyclo structure, an onium hydroxide structure, an onium carboxylate structure, a trialkylamine structure, an aniline structure or a pyridine structure; an alkylamine derivative having a hydroxyl group and/or an ether bond; and an aniline derivative having a hydroxyl group and/or an ether bond.

Examples of the compound having an imidazole structure include imidazole, 2,4,5-triphenylimidazole, and benzimidazole. Examples of the compound having a diazabicyclo structure include 1,4-diazabicyclo[2,2,2]octane, 1,5-diazabicyclo[4,3,0]non-5-ene, and 1,8-diazabicyclo[5,4,0]undec-7-ene. Examples of the compound having an onium hydroxide structure include triarylsulfonium hydroxide, phenacylsulfonium hydroxide, and sulfonium hydroxide having a 2-oxoalkyl group, specifically triphenylsulfonium hydroxide, tris(t-butylphenyl)sulfonium hydroxide, bis(t-butylphenyl)iodonium hydroxide, phenacylthiophenium hydroxide and 2-oxopropylthiophenium hydroxide. The compound having an onium carboxylate structure is formed by carboxylation of an anionic moiety of a compound having an onium hydroxide structure, and examples thereof include acetate, adamantane-1-carboxylate, and perfluoroalkyl carboxylate. Examples of the compound having a trialkylamine structure include tri(n-butyl)amine and tri(n-octyl)amine. Examples of the aniline compound include 2,6-diisopropylaniline, N,N-dimethylaniline, N,N-dibutylaniline, and N,N-dihexylaniline. Examples of the alkylamine derivative having a hydroxyl group and/or an ether bond include ethanolamine, diethanolamine, triethanolamine, and tris(methoxyethoxyethyl)amine. Examples of the aniline derivative having a hydroxyl group and/or an ether bond include N,N-bis(hydroxyethyl)aniline.

Preferred examples of the basic compound further include an amine compound having a phenoxy group and an ammonium salt compound having a phenoxy group.

As the amine compound, a primary, secondary, or tertiary amine compound can be used, and an amine compound in which at least one alkyl group is bonded to a nitrogen atom is preferable. The amine compound is more preferably a tertiary amine compound. In the amine compound, as long as at least one alkyl group (preferably having 1 to 20 carbon atoms) is bonded to a nitrogen atom, a cycloalkyl group (preferably having 3 to 20 carbon atoms) or an aryl group (preferably having 6 to 12 carbon atoms) may be bonded to the nitrogen atom, in addition to the alkyl group.

Incidentally, the amine compound preferably has an oxygen atom in the alkyl chain to form an oxyalkylene group. The number of the oxyalkylene groups within the molecule is 1 or more, preferably 3 to 9, and more preferably 4 to 6. Among the oxyalkylene groups, an oxyethylene group (—CH₂CH₂O—) or an oxypropylene group (—CH(CH₃)CH₂O— or —CH₂CH₂CH₂O—) is preferable, and an oxyethylene group is more preferable.

As the ammonium salt compound, primary, secondary, tertiary, or quaternary ammonium salt compounds can be used, and an ammonium salt compound having at least one alkyl group bonded to a nitrogen atom thereof is preferable. In the ammonium salt compounds, as long as at least one alkyl group (preferably having 1 to 20 carbon atoms) is bonded to a nitrogen atom thereof, a cycloalkyl group (preferably having 3 to 20 carbon atoms) or an aryl group (preferably having 6 to 12 carbon atoms) may be bonded to the nitrogen atom, in addition to the alkyl group.

The ammonium salt compound preferably has an oxygen atom in the alkyl chain to form an oxyalkylene group. The number of oxyalkylene groups in each molecule is 1 or more, preferably 3 to 9, and more preferably 4 to 6. Among the oxyalkylene groups, an oxyethylene group (—CH₂CH₂O—) or an oxypropylene group (—CH(CH₃)CH₂O— or —CH₂CH₂CH₂O—) is preferable, and an oxyethylene group is more preferable.

Examples of the anion of the ammonium salt compound include halogen atoms, sulfonate, borate, and phosphate, and among these, halogen atoms and sulfonate are preferable. As the halogen atom, chloride, bromide, or iodide is particularly preferable, and as the sulfonate, an organic sulfonate having 1 to 20 carbon atoms is particularly preferable. Examples of the organic sulfonate include aryl sulfonate and alkyl sulfonate having 1 to 20 carbon atoms. The alkyl group of the alkyl sulfonate may have a substituent. Examples of the substituent include fluorine, chlorine, bromine, an alkoxy group, an acyl group, and an aryl group. Specific examples of the alkyl sulfonates include methane sulfonate, ethane sulfonate, butane sulfonate, hexane sulfonate, octane sulfonate, benzyl sulfonate, trifluoromethane sulfonate, pentafluoroethane sulfonate, and nonafluorobutane sulfonate. Examples of the aryl group of the aryl sulfonate include a benzene ring, a naphthalene ring, and an anthracene ring. The benzene ring, the naphthalene ring, or the anthracene ring may have a substituent, and as the substituent, a linear or branched alkyl group having 1 to 6 carbon atoms or a cycloalkyl group having 3 to 6 carbon atoms is preferable. Specific examples of the linear or branched alkyl group and the cycloalkyl group include methyl, ethyl, n-propyl, isopropyl, n-butyl, i-butyl, t-butyl, n-hexyl, and cyclohexyl. Other examples of the substituent include an alkoxy group having 1 to 6 carbon atoms, a halogen atom, cyano, nitro, an acyl group, and an acyloxy group.

The amine compound having a phenoxy group and the ammonium salt compound having a phenoxy group are those having a phenoxy group at the terminal of the alkyl group of the amine compound or ammonium salt compound opposed to the nitrogen atom. The phenoxy group may have a substituent. Examples of the substituent of the phenoxy group include an alkyl group, an alkoxy group, a halogen atom, a cyano group, a nitro group, a carboxyl group, a carboxylic ester group, a sulfonic ester group, an aryl group, an aralkyl group, an acyloxy group, and an aryloxy group. The substitution position of the substituent may be any of 2- to 6-positions. The number of substituents is any value within the range of 1 to 5.

It is preferable that at least one oxyalkylene group exist between the phenoxy group and the nitrogen atom. The number of oxyalkylene groups in each molecule is 1 or more, preferably 3 to 9, and more preferably 4 to 6. Among the oxyalkylene groups, an oxyethylene group (—CH₂CH₂O—) or an oxypropylene group (—CH(CH₃)CH₂O— or —CH₂CH₂CH₂O—) is preferable, and an oxyethylene group is more preferable.

The amine compound having a phenoxy group can be obtained by heating a primary or secondary amine having a phenoxy group and a haloalkyl ether so as to effect a reaction therebetween, then adding an aqueous solution of a strong base such as sodium hydroxide, potassium hydroxide, and tetraalkylammonium, and thereafter carrying out an extraction with an organic solvent such as ethyl acetate and chloroform. Alternatively, the amine compound having a phenoxy group can be obtained by first heating a primary or secondary amine and a haloalkyl ether having a phenoxy group at its terminal so as to effect a reaction therebetween, subsequently adding an aqueous solution of a strong base such as sodium hydroxide, potassium hydroxide, and a tetraalkylammonium, and thereafter carrying out an extraction with an organic solvent such as ethyl acetate and chloroform.

(Compound (PA) That Has Proton-Accepting Functional Group and Generates Compound Whose Proton Acceptor Properties Are Reduced or Lost, or Which Is Changed from Having Proton Acceptor Properties to Being Acidic, by Decomposing upon Irradiation with Actinic Rays or Radiation)

The actinic ray-sensitive or radiation-sensitive resin composition may further include, as a basic compound, a compound [hereinafter also referred to as a compound (PA)] that has a proton-accepting functional group and generates a compound whose proton accepting properties are reduced or lost, or which is changed from having proton accepting properties to being acidic, through decomposition upon irradiation with actinic rays or radiation.

The proton-accepting functional group refers to a functional group having an electron or a group which is capable of electrostatically interacting with a proton, and for example, means a functional group with a macrocyclic structure, such as a cyclic polyether, or a functional group containing a nitrogen atom having an unshared electron pair not contributing to π-conjugation. The nitrogen atom having an unshared electron pair not contributing to π-conjugation is, for example, a nitrogen atom having a partial structure represented by the following general formula.

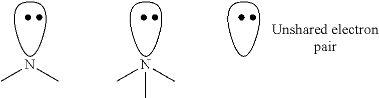

Preferred examples of the partial structure of the proton-accepting functional group include crown ether, azacrown ether, primary to tertiary amines, pyridine, imidazole, and pyrazine structures.

The compound (PA) decomposes upon irradiation with actinic rays or radiation to generate a compound whose proton accepting properties are reduced or lost, or which is changed from having proton accepting properties to being acidic. Here, the expression, a compound whose proton accepting properties are reduced or lost, or which is changed from having proton accepting properties to being acidic, means the compound having a change of proton accepting properties due to the proton being added to the proton-accepting functional group, and specifically a decrease in the equilibrium constant at chemical equilibrium in a case where a proton adduct is generated from the compound (PA) having the proton-accepting functional group and the proton.

Specific examples of the compound (PA) include the following compounds. Further, specific examples of the compound (PA) include those described in paragraphs 0421 to 0428 of JP2014-41328A, and paragraphs 0108 to 0116 of JP2014-134686A, the contents of which are incorporated herein.

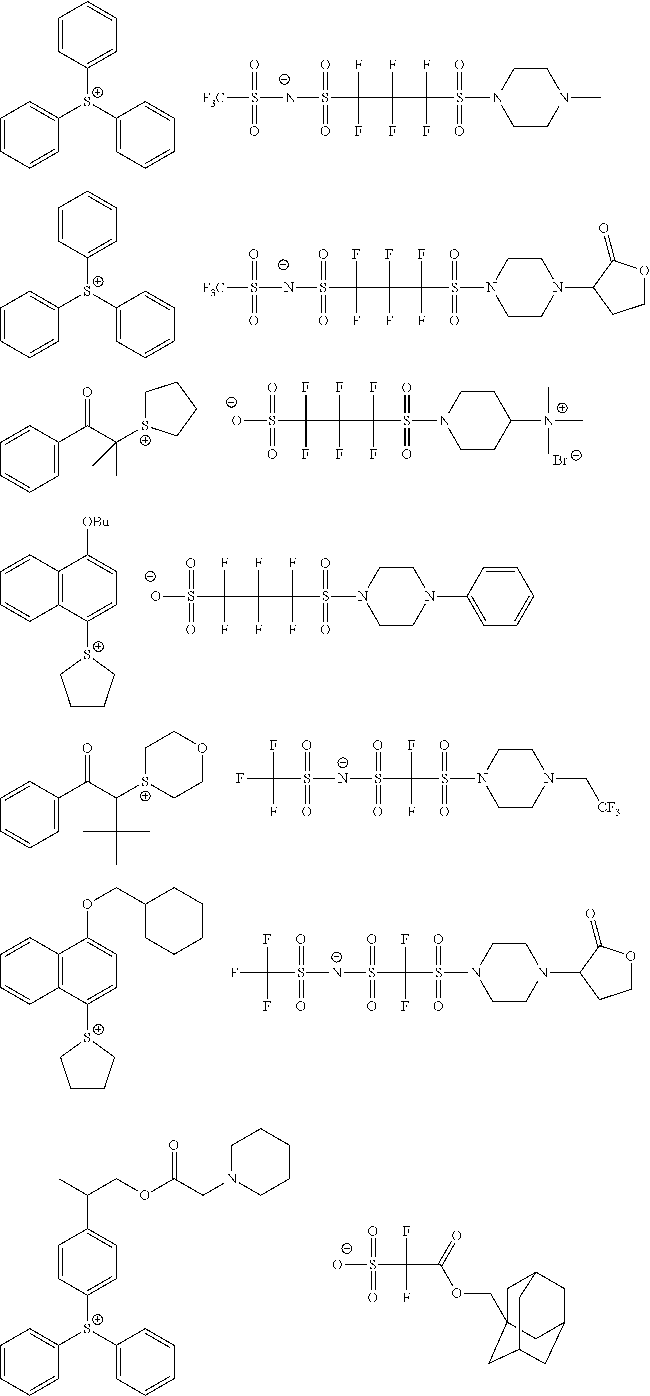

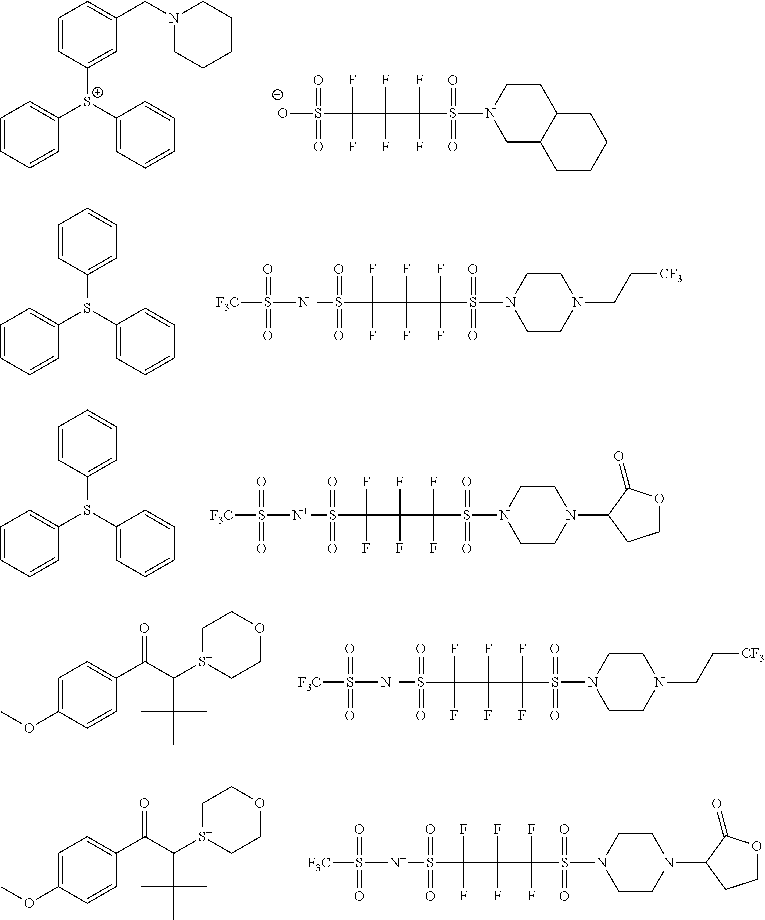

These basic compounds may be used singly or in combination of two or more kinds thereof.

The amount of the basic compound to be used is usually 0.001% to 10% by mass, and preferably 0.01% to 5% by mass, with respect to the solid content of the actinic ray-sensitive or radiation-sensitive resin composition.

The ratio between the acid generator to the basic compound to be used in the composition is preferably the acid generator/basic compound (molar ratio)=2.5 to 300. That is, the molar ratio is preferably 2.5 or more in view of sensitivity and resolution, and is preferably 300 or less in view of suppressing the reduction in resolution due to thickening of the resist pattern over time from exposure to the heat treatment. The acid generator/basic compound (molar ratio) is more preferably 5.0 to 200, and still more preferably 7.0 to 150.

As the basic compound, for example, the compounds (amine compounds, amido group-containing compounds, urea compounds, nitrogen-containing heterocyclic compounds, and the like) described in paragraphs 0140 to 0144 of JP2013-11833A can be used.

<Hydrophobic Resin>

The actinic ray-sensitive or radiation-sensitive resin composition may have a hydrophobic resin other than the resin (1), in addition to the resin (1).

Although the hydrophobic resin is preferably designed to be localized on a surface of the resist film, it does not necessarily have to have a hydrophilic group in its molecule unlike the surfactant, and does not need to contribute to uniform mixing of polar/nonpolar materials.

Examples of the effect of addition of the hydrophobic resin include control of the static/dynamic contact angle of the resist film surface with respect to water, and suppression of out gas.

The hydrophobic resin preferably has at least one of a “fluorine atom”, a “silicon atom”, or a “CH₃ partial structure which is contained in a side chain moiety of a resin” from the viewpoint of localization on the film surface layer, and more preferably has two or more kinds. Further, the hydrophobic resin preferably contains a hydrocarbon group having 5 or more carbon atoms. These groups may be contained in the main chain of the resin or may be substituted in a side chain.

In a case where hydrophobic resin includes a fluorine atom and/or a silicon atom, the fluorine atom and/or the silicon atom in the hydrophobic resin may be contained in the main chain or the side chain of the resin.

In a case where the hydrophobic resin includes a fluorine atom, it is preferably a resin having an alkyl group having a fluorine atom, a cycloalkyl group having a fluorine atom, or an aryl group having a fluorine atom, as a partial structure having a fluorine atom.

The alkyl group having a fluorine atom (preferably having 1 to 10 carbon atoms, and more preferably having 1 to 4 carbon atoms) is a linear or branched alkyl group in which at least one hydrogen atom is substituted with a fluorine atom, and may further have a substituent other than a fluorine atom.

The cycloalkyl group having a fluorine atom is a monocyclic or polycyclic cycloalkyl group in which at least one hydrogen atom is substituted with a fluorine atom, and may further have a substituent other than a fluorine atom.

The aryl group having a fluorine atom is an aryl group in which at least one hydrogen atom is substituted with a fluorine atom, such as a phenyl group and a naphthyl group, and may further have a substituent other than a fluorine atom.

Examples of the repeating unit having a fluorine atom or a silicon atom include those exemplified in paragraph 0519 of US2012/0251948A1.

Moreover, it is also preferable that the hydrophobic resin includes a CH₃ partial structure in the side chain moiety as described above.

Here, the CH₃ partial structure contained in the side chain moiety in the hydrophobic resin includes a CH₃ partial structure contained in an ethyl group, a propyl group, and the like.

On the other hand, a methyl group bonded directly to the main chain of the hydrophobic resin (for example, an α-methyl group in the repeating unit having a methacrylic acid structure) makes a small contribution to localization on the surface of the hydrophobic resin due to the effect of the main chain, and it is therefore not included in the CH₃ partial structure in the present invention.

With regard to the hydrophobic resin, reference can be made to the descriptions in paragraphs 0348> to <0415> of JP2014-010245A, the content of which is incorporated herein by reference.

In addition, as the hydrophobic resin, resins described in JP2011-248019A, JP2010-175859A, and JP2012-032544A can also be preferably used.

In a case where the actinic ray-sensitive or radiation-sensitive resin composition contains a hydrophobic resin, the content of the hydrophobic resin is preferably 0.01% to 20% by mass, more preferably 0.01% to 10% by mass, still more preferably 0.05% to 8% by mass, and particularly preferably 0.5% to 5% by mass, with respect to the total solid content of the actinic ray-sensitive or radiation-sensitive resin composition.

In the pattern forming method of the present invention, the resist film can be formed on a substrate, using the actinic ray-sensitive or radiation-sensitive resin composition, and a topcoat can also be formed on the resist film, using the composition for forming a topcoat layer. The film thickness of the resist film is preferably 10 to 100 nm, and the film thickness of the topcoat layer is preferably 10 to 200 nm, more preferably 20 to 100 nm, and still more preferably 40 to 80 nm.

As a method for coating the actinic ray-sensitive or radiation-sensitive resin composition onto the substrate, spin coating is preferable, and its rotation speed is preferably 1,000 to 3,000 rpm.

For example, the actinic ray-sensitive or radiation-sensitive resin composition is coated onto a substrate (for example, silicone/silicone dioxide coating) used to manufacture a precision integrated circuit element by a proper coating method such as a spinner or a coater, and then is dried, thus forming a resist film. Further, it is possible to previously form a known antireflection film. Furthermore, the resist film is preferably dried before the topcoat layer is formed.

Subsequently, the composition for forming a topcoat can be applied and dried on the obtained resist film by means that are the same as the method of forming the resist film, thereby forming the topcoat layer.

The resist film having on an upper layer thereof the topcoat layer is usually irradiated with electron beams (EB), X-rays, or EUV the through a mask, and preferably baked (heated) to perform development. Thus, it is possible to obtain a good pattern.

Surfactant (F)

The actinic ray-sensitive or radiation-sensitive resin composition may further include a surfactant (F). By the incorporation of the surfactant, it becomes possible to form a resist pattern which has less defects in adhesiveness and development with good sensitivity and resolution at the time of using an exposure light source at a wavelength of 250 nm or less, and particularly 220 nm or less.

Fluorine-based and/or silicon-based surfactants are particularly preferably used as the surfactant.

Examples of the fluorine- and/or silicon-based surfactants include the surfactants described in <0276> in US2008/0248425A. Further, EFTOP EF301 or EF303 (manufactured by Shin-Akita Kasei K. K.); FLORAD FC430, 431, or 4430 (manufactured by Sumitomo 3M Inc.); MEGAFACE F171, F173, F176, F189, F113, F110, F177, F120, or R08 (manufactured by DIC Corp.); SURFLON S-382, SC101, 102, 103, 104, 105, or 106 (manufactured by Asahi Glass Co., Ltd.); TROYSOL S-366 (manufactured by Troy Chemical Corp.); GF-300 or GF-150 (manufactured by Toagosei Chemical Industry Co., Ltd.); SURFLON S-393 (manufactured by Seimi Chemical Co., Ltd.); EFTOP EF121, EF122A, EF122B, RF122C, EF125M, EF135M, EF351, EF352, EF801, EF802, or EF601 (manufactured by JEMCO Inc.); PF636, PF656, PF6320, or PF6520 (manufactured by OMNOVA Solutions Inc.); or FTX-204G, 208G, 218G, 230G, 204D, 208D, 212D, 218D, or 222D (manufactured by NEOS COMPANY LIMITED) may be used. In addition, POLYSILOXANE POLYMER KP-341 (manufactured by Shin-Etsu Chemical Co., Ltd.) can also be used as the silicon-based surfactant.

Furthermore, in addition to those known surfactants as described above, a surfactant may be synthesized using a fluoroaliphatic compound which is produced by a telomerization method (also referred to as a telomer method) or an oligomerization method (also referred to as an oligomer method). Specifically, a polymer including a fluoroaliphatic group derived from the fluoroaliphatic compound may be used as the surfactant. The fluoroaliphatic compound can be synthesized in accordance with, for example, the method described in JP2002-90991A.

In addition, surfactants other than the fluorine-based and/or silicon-based surfactants described in <0280> of US2008/0248425A may be used.

These surfactants may be used singly or in combination of two or more kinds thereof.

In a case where the actinic ray-sensitive or radiation-sensitive resin composition includes a surfactant, the content of the surfactant is preferably 0% to 2% by mass, more preferably 0.0001% to 2% by mass, and still more preferably 0.0005% to 1% by mass, with respect to the total solid content of the composition.

Other Additives (G)

The actinic ray-sensitive or radiation-sensitive resin composition may further include a dissolution inhibiting compound, a dye, a plasticizer, a photosensitizer, a light absorber, and/or a compound promoting a solubility in a developer (for example, a phenol compound having a molecular weight of 1,000 or less, or an alicyclic or aliphatic compound including a carboxyl group).

The actinic ray-sensitive or radiation-sensitive resin composition may further include a dissolution inhibiting compound. Here, the “dissolution inhibiting compound” is a compound having a molecular weight of 3,000 or less, which decreases its solubility in an organic developer through decomposition by the action of an acid.

It is preferable that various materials (for example, a resist solvent, a developer, a rinsing liquid, a composition for forming an antireflection film, and a composition for forming a topcoat) used in the actinic ray-sensitive or radiation-sensitive resin composition of the present invention and the pattern forming method of the present invention include no impurities such as metals, metal salts including halogen, acids, alkalis, and the like. The content of the impurities included in these materials is preferably 1 ppm or less, more preferably 1 ppb or less, still more preferably 100 ppt or less, and particularly preferably 10 ppt or less, and most preferably, the impurities are not substantially included (no higher than a detection limit of a measurement device).

Examples of a method for removing impurities such as metals from the various materials include filtration using a filter and a purification step by distillation (in particular, thin-film distillation and molecular distillation). As for the purification step by distillation, for example, “<Factory Operation Series> Augmentation/Distillation, issued on Jul. 31, 1992, Chemical Industry Co., Ltd.”, “Chemical Engineering Handbook, published on Sep. 30, 2004”, Asakura Shoten, pages 95 to 102″, and the like may be mentioned. As for the filter pore diameter, the pore size is preferably 10 nm or less, more preferably 5 nm or less, and still more preferably 3 nm or less. As for the materials of a filter, a polytetrafluoroethylene-made filter, a polyethylene-made filter, and a nylon-made filter are preferable. The filter may be formed of a composite material formed by combining this material with an ion exchange medium. As the filter, a filter which had been washed with an organic solvent in advance may be used. In the step of filtration using a filter, plural kinds of filters may be connected in series or in parallel, and used. In a case of using plural kinds of filters, a combination of filters having different pore diameters and/or materials may be used. In addition, various materials may be filtered plural times, and a step of filtering plural times may be a circulatory filtration step.

Moreover, examples of the method for reducing the impurities such as metals included in the various materials include a method involving selecting raw materials having a small content of metals as raw materials constituting various materials, a method involving subjecting raw materials constituting various materials to filtration using a filter, and a method involving performing distillation under the condition with contamination being suppressed as much as possible by, for example, lining the inside of a device with TEFLON (registered trademark). The preferred conditions for filtration using a filter, which is carried out for raw materials constituting various materials, are the same as described above.

In addition to filtration using a filter, removal of impurities by an adsorbing material may be carried out, or a combination of filtration using a filter and an adsorbing material may be used. As the adsorbing material, known adsorbing materials may be used, and for example, inorganic adsorbing materials such as silica gel and zeolite, and organic adsorbing materials such as activated carbon can be used.

<Housing Container>

As the organic solvent (hereinafter also referred to as an “organic treatment liquid”) which can be used in the developer and the rinsing liquid, an organic solvent preserved in a housing container of an organic treatment liquid for the patterning of a resist film which is chemically amplified or not chemically amplified, having a housing section is preferably used. The housing container is preferably, for example, a housing container of an organic treatment liquid for the patterning of a resist film, in which the inner wall in contact with an organic treatment liquid of the housing section is formed from a resin different from any of the polyethylene resin, the polypropylene resin, and the polyethylene-polypropylene resin, or a metal which has been subjected to a rust-preventing/metal elution-preventing treatment. An organic solvent that is supposed to be used as an organic treatment liquid for the patterning of a resist film can be contained in the housing section of the housing container, and then discharged from the housing section upon the patterning of the resist film.

In a case where the housing container further has a sealing section for sealing the housing section, the sealing section is preferably formed of a resin different from one or more kinds of resins selected from the group consisting of the polyethylene resin, the polypropylene resin, and the polyethylene-polypropylene resin, or a metal which has been subjected to rust-preventing/metal elution-preventing treatments.

Here, the sealing section means a member capable of shielding the housing section from an outside air, and suitable examples thereof include a packing and an O-ring.

The resin different from one or more kinds of resins selected from the group consisting of a polyethylene resin, a polypropylene resin, and a polyethylene-polypropylene resin is preferably a perfluoro resin.

Examples of the perfluoro resin include a polytetrafluoroethylene resin (PTFE), a tetrafluoroethylene-perfluoroalkylvinyl ether copolymer (PFA), a tetrafluoroethylene-hexafluoropropylene copolymer resin (FEP), a tetrafluoroethylene-ethylene copolymer resin (ETFE), a chlorotrifluoroethylene-ethylene copolymer resin (ECTFE), a polyvinylidene fluoride resin (PVDF), a polychlorotrifluoroethylene copolymer resin (PCTFE), and a polyvinyl fluoride resin (PVF).

Particularly preferred examples of the perfluoro resin include a tetrafluoroethylene resin, a tetrafluoroethylene-perfluoroalkylvinyl ether copolymer, and a tetrafluoroethylene-hexafluoropropylene copolymer resin.

Examples of the metal in the metal which has been subjected to the rust-preventing/metal elution-preventing treatments include carbon steel, alloy steel, nickel-chrome steel, nickel chrome molybdenum steel, chrome steel, chrome molybdenum steel, and manganese steel.

As the rust-preventing/metal elution-preventing treatment, a coating film technique is preferably applied.

The coating technique is largely divided into three kinds of coatings such as metal coating (various platings), inorganic coating (various chemical conversion treatments, glass, concrete, ceramics, and the like) and organic coating (rust preventive oil, paint, rubber, and plastics).

Preferred examples of the coating technique include a surface treatment using a rust-preventing oil, a rust inhibitor, a corrosion inhibitor, a chelate compound, a peelable plastic, or a lining agent.

Among those, various corrosion inhibitors such as chromate, nitrite, silicate, phosphate, carboxylic acids such as oleic acid, dimer acid, and naphthalenic acid, a carboxylic acid metallic soap, sulfonate, an amine salt, esters (a glycerin ester or a phosphate ester of a higher fatty acid), chelate compounds such as ethylenediaminetetraacetic acid, gluconic acid, nitrilotriacetic acid, hydroxy ethyl ethylenediaminetriacetic acid, and diethylenetriaminepentaacetic acid, and a fluorine resin lining are preferable. The phosphate treatment and the fluorine resin lining are particularly preferable.

Furthermore, a “pre-treatment” which is at a pre-stage for the rust-preventing treatment is also preferably employed as a treatment method which leads to extension of an anti-rust period through a coating treatment although not directly preventing rust, as compared with a direct coating treatment.

Specific suitable examples of such a pre-treatment include a treatment for removing various corrosive factors, such as chloride and sulfate, present on a metal surface through washing or polishing.

Specific examples of the housing container are exemplified as follows.
FluoroPurePFA complex drum manufactured by Entegris Inc. (liquid contact inner surface; PFA resin lining)
Steel-made drum can be manufactured by JFE (liquid contact inner surface; zinc phosphate film)

Moreover, examples of the housing container which can be used in the present invention include the containers described in <0013> to <0030> of JP1999-021393A (JP-H11-021393A), and <0012> to <0024> of JP1998-45961A (JP-H10-45961A).

An electrically conductive compound may be added to the organic treatment liquid in the present invention in order to prevent the failure of chemical liquid pipes or various parts (filters, O-rings, tubes, and the like) associated with electrostatic charge and subsequently occurring electrostatic discharge. The electrically conductive compound is not particularly limited, but examples thereof include methanol. The addition amount thereof is not particularly limited, but is preferably 10% by mass or less, and more preferably 5% by mass or less, from the viewpoint of maintaining preferred development characteristics. For the members of the chemical liquid pipes, various pipes coated with stainless steel (SUS), or with polyethylene, polypropylene, or fluorine resins (polytetrafluoroethylene, a perfluoroalkoxy resin, and the like) which has been subjected to an antistatic treatment can be used. Similarly, with respect to the filters and the O-rings, polyethylene, polypropylene, or fluorine resins (polytetrafluoroethylene, a perfluoroalkoxy resin, and the like) which has been subjected to an antistatic treatment can be used.

Furthermore, generally, the developer and the rinsing liquid after use are stored in a waste liquid tank through a pipe. Here, in a case where a hydrocarbon-based solvent is used as the rinsing liquid, there is a method in which in order to prevent a resist dissolved in a developer from being precipitated and adhered onto the back surface of a wafer, the side surface of a pipe, or the like, a solvent in which a resist is dissolved is again passed through the pipe. Examples of a method for passing the solvent through the pipe include a method in which after washing with a rinsing liquid, the back surface or side surface of a substrate, or the like is washed with a solvent in which a resist is dissolved and the solvent is allowed to flow out, and a method in which a solvent in which a resist is dissolved is allowed to flow out by passing through a pipe while being not brought into contact with the resist.

The solvent which passes through the pipe is not particularly limited as long as it is capable of dissolving a resist, examples thereof include the above-mentioned organic solvents, and thus, propylene glycol monomethyl ether acetate (PGMEA), propylene glycol monoethyl ether acetate, propylene glycol monopropyl ether acetate, propylene glycol monobutyl ether acetate, propylene glycol monomethyl ether propionate, propylene glycol monoethyl ether propionate, ethylene glycol monomethyl ether acetate, ethylene glycol monoethyl ether acetate, propylene glycol monomethyl ether (PGME), propylene glycol monoethyl ether, propylene glycol monopropyl ether, propylene glycol monobutyl ether, ethylene glycol monomethyl ether, ethylene glycol monoethyl ether, 2-heptanone, ethyl lactate, 1-propanol, acetone, or the like can be used. Among those, PGMEA, PGME, or cyclohexanone can be preferably used.

By using a pattern obtained by the pattern forming method of the present invention as a mask, and appropriately carrying out an etching treatment, ion injection, or the like, a semiconductor fine circuit, a mold structure for imprints, a photomask, or the like can be produced.

The pattern formed by the method can also be used for a guide pattern formation in a directed self-assembly (DSA) (see, for example, ACS Nano Vol. 4 No. 8 Pages 4815-4823). In addition, a pattern formed by the method can be used as, for example, a core material (core) of the spacer process disclosed in JP1991-270227A (JP-H03-270227A) and JP2013-164509A.

In addition, a process of a case where a mold for imprints is manufactured using the pattern forming method of the present invention is described in, for example, JP4109085B, JP2008-162101A, and “Fundamentals of Nanoimprint and Technical Development/Application Deployment-Substrate Technique of Nanoimprint and Latest Application Deployment”, edited by Yoshihiko Hirai (Frontier Publishing).

A photomask produced using the pattern forming method of the present invention may be a light transmissive type mask used in ArF excimer laser or a light reflective type mask used in reflection system lithography using EUV as a light source.

Furthermore, the present invention also relates to a method for manufacturing an electronic device, including the pattern forming method of the present invention as described above.

An electronic device manufactured by the method for manufacturing an electronic device of the present invention is suitably mounted on electric or electronic equipment (home electronics, office appliance (OA)-related or media-related equipment, optical equipment, telecommunication equipment, and the like).

### EXAMPLES

Hereinbelow, the present invention will be described in more detail with reference to Examples, but the present invention is not limited thereto.

[Preparation of Resist Composition]

As the resin (1) in the resist composition, the following resins were used.

[Synthesis of Resin (A-3)]

First, a monomer (a1) was synthesized, and a resin (A-3) was synthesized using the synthesized monomer (a1). Details thereof will be described below.

<Synthesis of Monomer (a1)>

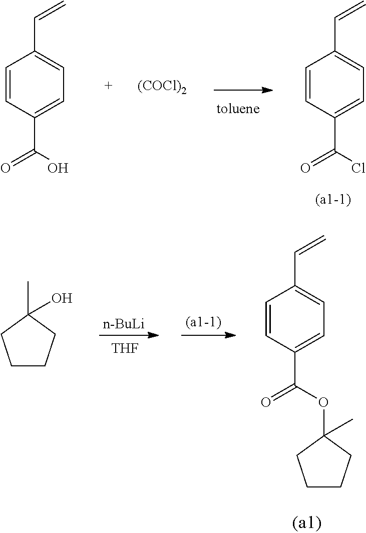

(Synthesis of Intermediate (a1-1))

30 g of 4-vinyl benzoic acid was suspended in 220 mL of toluene, 1 mL of N,N-dimethylformamide was added thereto, and then 38.7 g of oxalyl dichloride was added dropwise to the mixture under nitrogen stream. The mixture was stirred at room temperature for 2 hours and then stirred at 50° C. for 2 hours. After being left to be cooled to room temperature, 15 mg of 2,6-di-tert-butyl-p-cresol was added to the reaction solution, the solvent and excess oxalyl dichloride were distilled off by heating at 50° C. under reduced pressure to obtain 37 g of a pale yellow liquid. From ¹H-NMR, it was found that an intermediate (a1-1) accounted for 90.7%, and 9.3% of the rest accounted for toluene. This intermediate (a1-1) was used for the next reaction while not being further purified.

¹H-NMR (Acetone-d6: ppm) δ: 8.11 (d, 2H), 7.73 (d, 2H), 6.90 (dd, 1H), 6.10 (d, 1H), 5.53 (d, 1H)

(Synthesis of Monomer (a1))

7.6 g of 1-methylcyclopentanol and 130 mL of tetrahydrofuran were mixed, and the mixture was cooled to −78° C. in a nitrogen atmosphere. 46 mL of n-butyllithium (1.6 M hexane solution) was added dropwise thereto, and the mixture was stirred at −78° C. for 1 hour and then further stirred at −10° C. for 1 hour. A solution obtained by mixing 13.8 g of an intermediate al-1 (purity of 90.7%) and 30 mL of tetrahydrofuran was carefully added dropwise to the reaction solution cooled to −10° C. such that heat was not generated excessively. After stirring the mixture at room temperature for 2 hours, 300 mL of n-hexane and 300 mL of distilled water were added thereto, and then the mixture was subjected to a liquid separation operation. The organic layer was washed with a saturated aqueous sodium hydrogen carbonate solution and distilled water, dried over magnesium sulfate, and then separated by filtration, and the solvent of the organic layer was distilled off under reduced pressure. The residue was purified by silica gel column chromatography (eluent: ethyl acetate/n-hexane=3/97) to obtain 13 g of a monomer (al).

¹H-NMR (Acetone-d6: ppm) δ: 7.94 (d, 2H), 7.57 (d, 2H), 6.84 (dd, 1H), 5.95 (d, 1H), 5.38 (d, 1H), 2.28 (m, 2H), 1.85-1.68 (m, 6H), 1.67 (s, 3H)

In substantially the same manner as above in the synthesis of the monomer (al) except that 1-methylcyclopentanol was changed, each of monomers (acid-decomposable monomers) were synthesized.

<Synthesis of resin (A-3)>

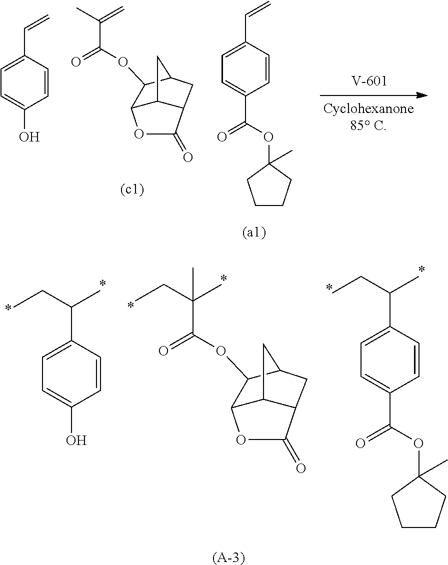

12.7 g of the monomer (al), 6.7 g of the monomer (c1), 1.8 g of p-hydroxystyrene, and 0.46 g of a polymerization initiator V-601 (manufactured by Wako Pure Chemical Industries, Ltd.) were dissolved in 77.9 g of cyclohexanone. 42.0 g of cyclohexanone was put into a reaction container, and added dropwise to a system at 85° C. for 4 hours in a nitrogen gas atmosphere. The reaction solution was heated and stirred over 2 hours and then left to be cooled to room temperature. The reaction solution was added dropwise to 978 g of a mixed solution of n-heptane and ethyl acetate (n-heptane/ethyl acetate=9/1 (mass ratio)) to precipitate polymers, which were filtered. The filtered solid was washed with 293 g of a mixed solution of n-heptane and ethyl acetate (n-heptane/ethyl acetate=9/1 (mass ratio)). Thereafter, the solid after washing was subjected to drying under reduced pressure to obtain 20.2 g of a resin (A-3). The weight-average molecular weight by means of GPC was 7,800, and the molecular weight dispersity (Mw/Mn) was 1.51.

¹H-NMR (DMSO-d6: ppm) δ: 9.38-8.84, 8.16-7.35, 7.33-6.04, 2.58-1.02 (peaks were all broad)

[Synthesis of Resins (A-1), (A-2), (A-4) to (A-19), and (R-1) to (R-5)]

In substantially the same manner as above except that the monomers to be used were changed, resins (A-1), (A-2), (A-4) to (A-19), and (R-1) to (R-5) having the structures shown in Tables 1 to 5 were synthesized.

In Tables 1 to 5, the compositional ratios (molar ratios) of the resins were calculated by ¹H-NMR (nuclear magnetic resonance) or ¹³C-NMR measurement. The weight-average molecular weight (Mw: in terms of polystyrene) and the dispersity (Mw/Mn) of the resin were calculated by GPC (solvent: THF) measurement.

TABLE 1

| | | Compositional ratio | Weight- | |
|---|---|---|---|---|
| | | (molar ratio) in the | average | |
| | | order from the left | molecular | |
| No | Structure | side | weight | Dispersity |
| A-1 | 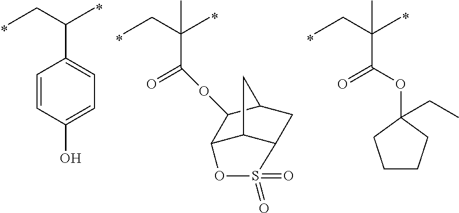 | 60/5/35 | 12400 | 1.47 |
| A-2 | 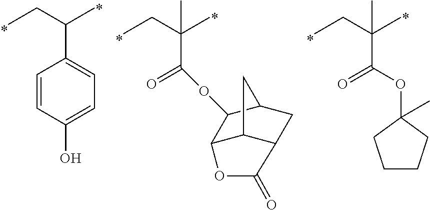 | 60/5/35 | 13000 | 1.49 |
| A-3 | 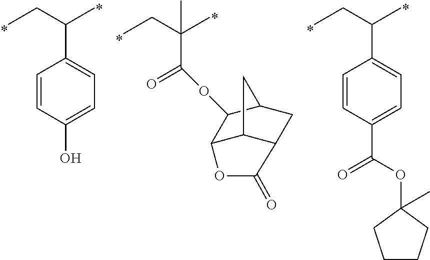 | 20/30/50 | 7800 | 1.51 |
| A-4 | 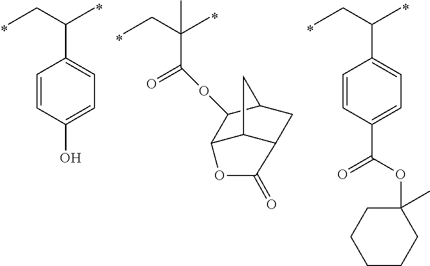 | 30/15/55 | 12100 | 1.47 |
| A-5 | 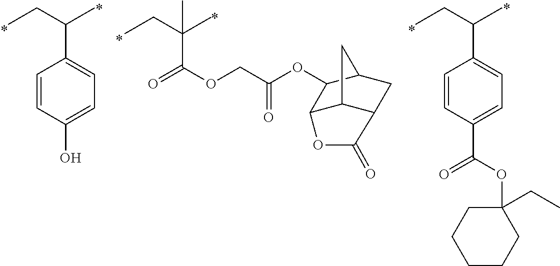 | 30/20/50 | 8800 | 1.49 |

TABLE 2

| | | Compositional ratio | Weight- | |
|---|---|---|---|---|
| | | (molar ratio) in the | average | |
| | | order from the left | molecular | |
| No | Structure | side | weight | Dispersity |
| A-6 | 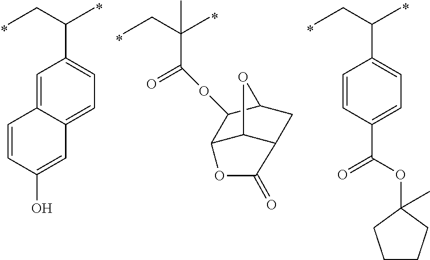 | 30/10/60 | 7800 | 1.51 |
| A-7 | 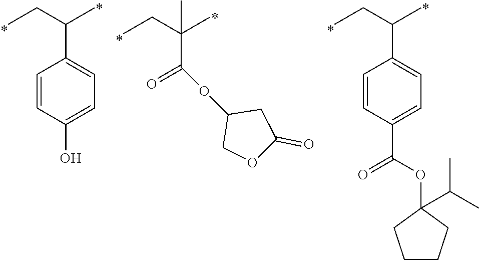 | 25/25/50 | 5500 | 1.48 |
| A-8 | 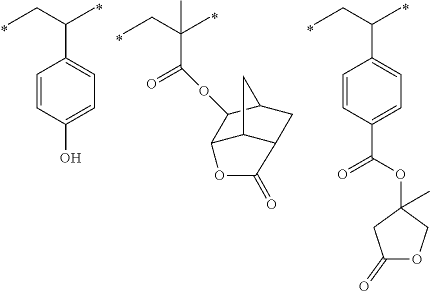 | 30/10/60 | 12000 | 1.48 |
| A-9 | 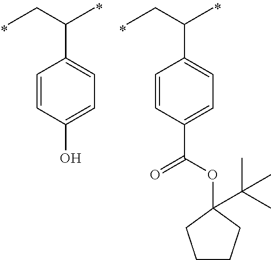 | 50/50 | 11700 | 1.48 |
| A-10 | 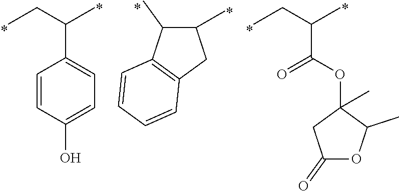 | 30/25/45 | 13200 | 1.49 |

TABLE 3

| | | Compositional | Weight | |
|---|---|---|---|---|
| | | ratio (molar | average | |
| | | ratio) in the order | molecular | |
| No | Structure | from the left side | weight | Dispersity |
| A-11 | 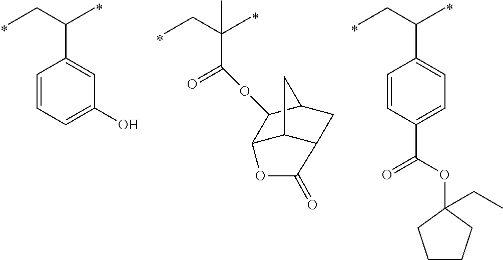 [SMILES: CCC(C)c1cccc(O)c1 ; CCC(C)(C)C(=O)OC1C2CC3C(=O)OC1C3C2 ; CCC(C)c1ccc(C(=O)OC2(CC)CCCC2)cc1] | 30/15/55 | 9700 | 1.47 |
| A-12 | 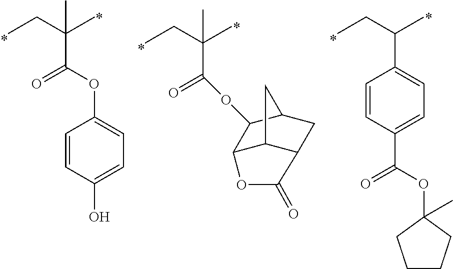 [SMILES: CCC(C)(C)C(=O)Oc1ccc(O)cc1 ; CCC(C)(C)C(=O)OC1C2CC3C(=O)OC1C3C2 ; CCC(C)c1ccc(C(=O)OC2(C)CCCC2)cc1] | 30/20/50 | 12900 | 1.53 |
| A-13 | 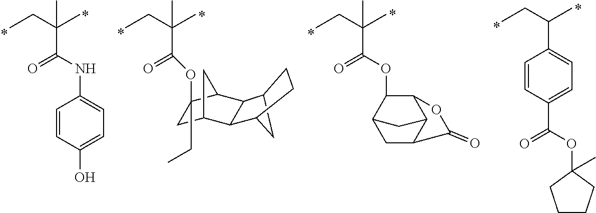 [SMILES: CCC(C)(C)C(=O)Nc1ccc(O)cc1 ; CCC(C)(C)C(=O)OC1(CC)CC2CC1C1(CC3CCC1C3)C2 ; CCC(C)(C)C(=O)OC1C2CC3C(=O)OC1C3C2 ; CCC(C)c1ccc(C(=O)OC2(C)CCCC2)cc1] | 30/30/10/30 | 15500 | 1.55 |
| A-14 | 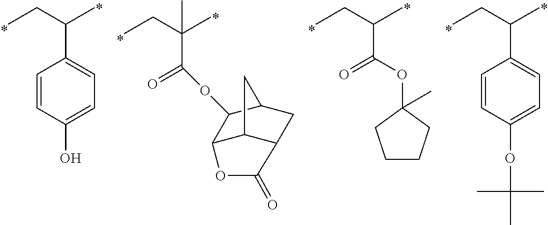 | 30/20/25/25 | 13000 | 1.52 |
| A-15 | 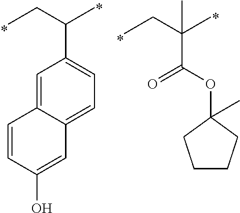 | 65/35 | 9500 | 1.20 |

TABLE 4

| | | Compositional | Weight- | |
|---|---|---|---|---|
| | | ratio (molar | average | |
| | | ratio) in the order | molecular | |
| No | Structure | from the lef tside | weight | Dispersity |
| A-16 | 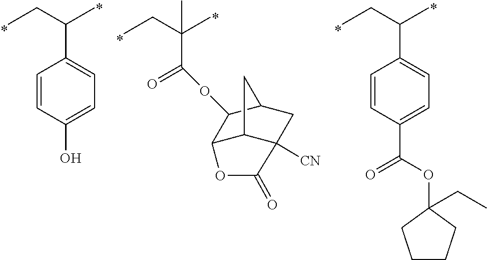 | 30/15/50 | 13300 | 1.51 |
| A-17 | 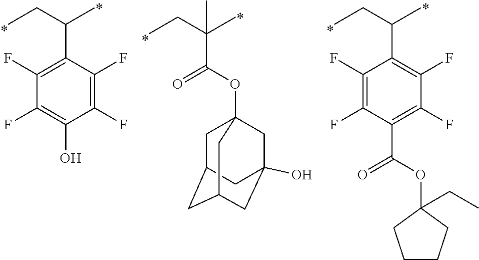 | 30/20/50 | 12700 | 1.48 |
| A-18 | 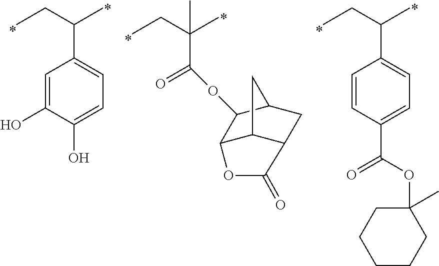 | 30/20/50 | 7800 | 1.51 |
| A-19 | 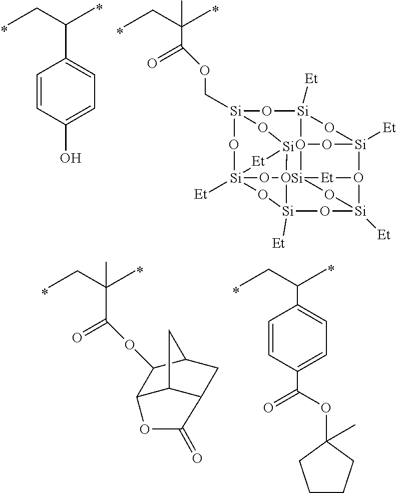 | 30/10/10/50 | 13800 | 1.54 |

TABLE 5

| | | Compositional ratio | Weight- | |
|---|---|---|---|---|
| | | (molar ratio) in the | average | |
| | | order from the left | molecular | |
| No | Structure | side | weight | Dispersity |
| R-1 | 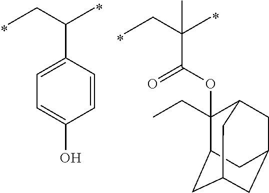 | 65/35 | 12300 | 1.54 |
| R-2 | 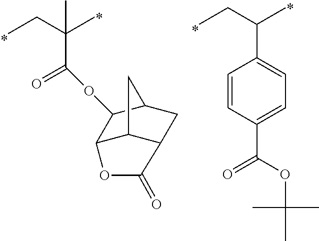 [SMILES: CCC(C)(C)C(=O)OC1C2CC3C(=O)OC1C3C2 ; CCC(C)c1ccc(C(=O)OC(C)(C)C)cc1] | 30/70 | 13200 | 1.49 |
| R-3 | 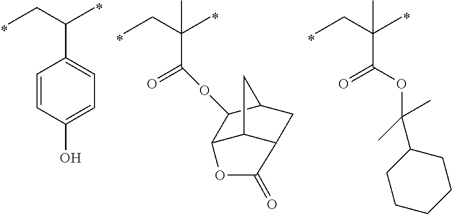 | 30/5/65 | 15000 | 1.51 |
| R-4 | 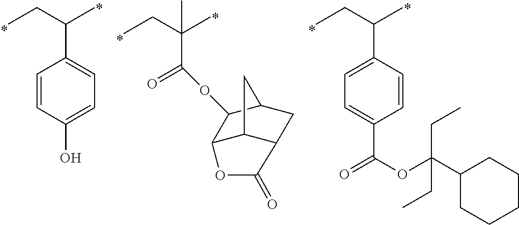 | 30/10/60 | 8000 | 1.46 |
| R-5 | 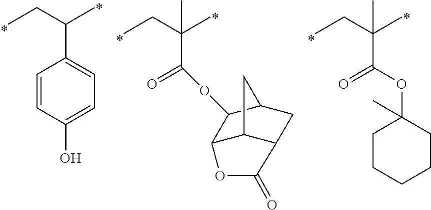 | 50/10/40 | 9000 | 1.52 |

[Hydrophobic Resin]

As the hydrophobic resin, the following resins (1b) to (5b) were used.

TABLE 6

| | Compositional ratio | | | | | |
|---|---|---|---|---|---|---|
| | (molar ratio) | | | | Mw | Mw/Mn |
| Resin (1b) | 50 | 45 | 5 | — | 7,000 | 1.30 |
| Resin (2b) | 40 | 40 | 20 | — | 18,600 | 1.57 |
| Resin (3b) | 50 | 50 | — | — | 25,400 | 1.63 |
| Resin (4b) | 30 | 65 | 5 | — | 28,000 | 1.70 |
| Resin (5b) | 10 | 10 | 30 | 50 | 12,500 | 1.65 |

Hereinafter, the specific structural formulae of the resins (1b) to (5b) described in Table 6 are shown below.

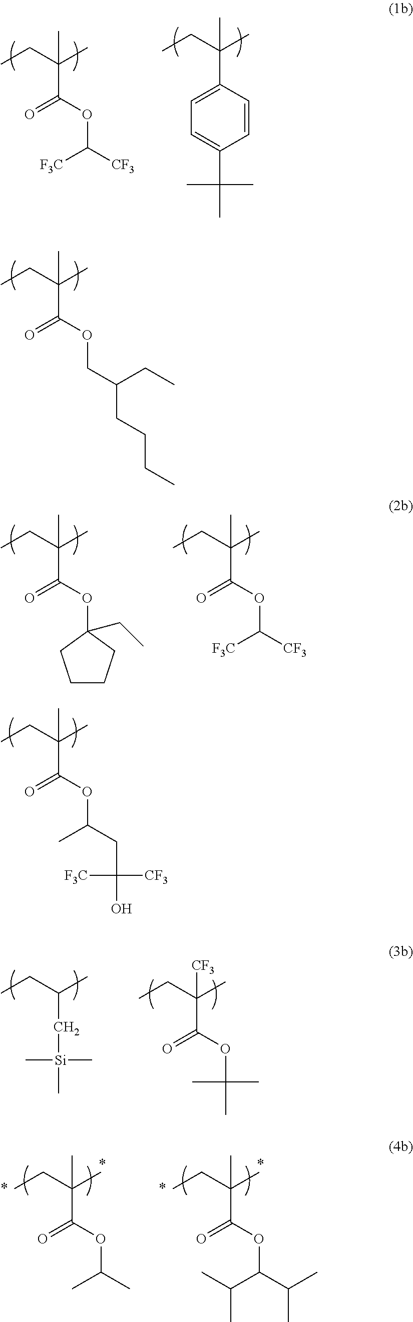

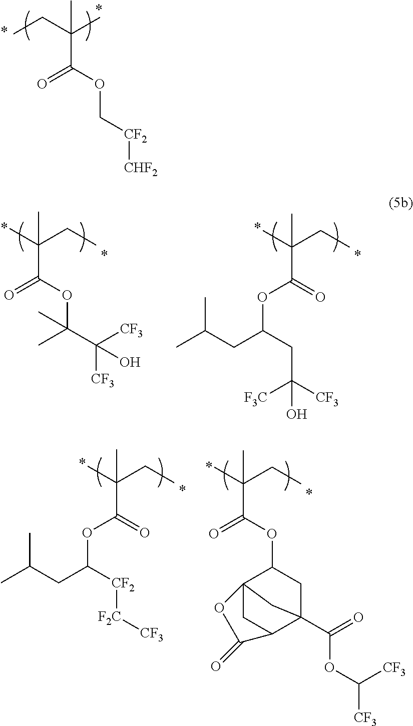

[Photoacid Generator (B)]

As the photoacid generator, the following compounds were used.

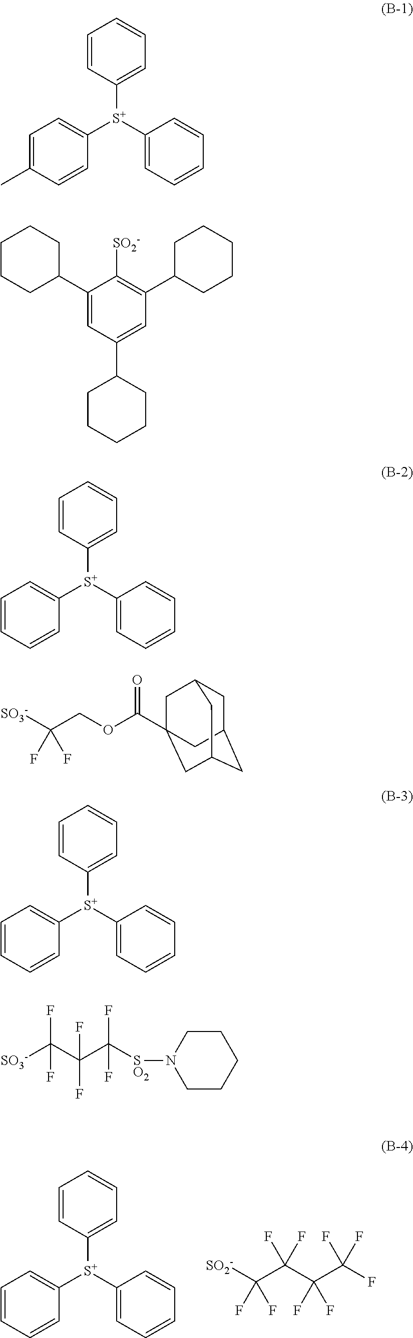

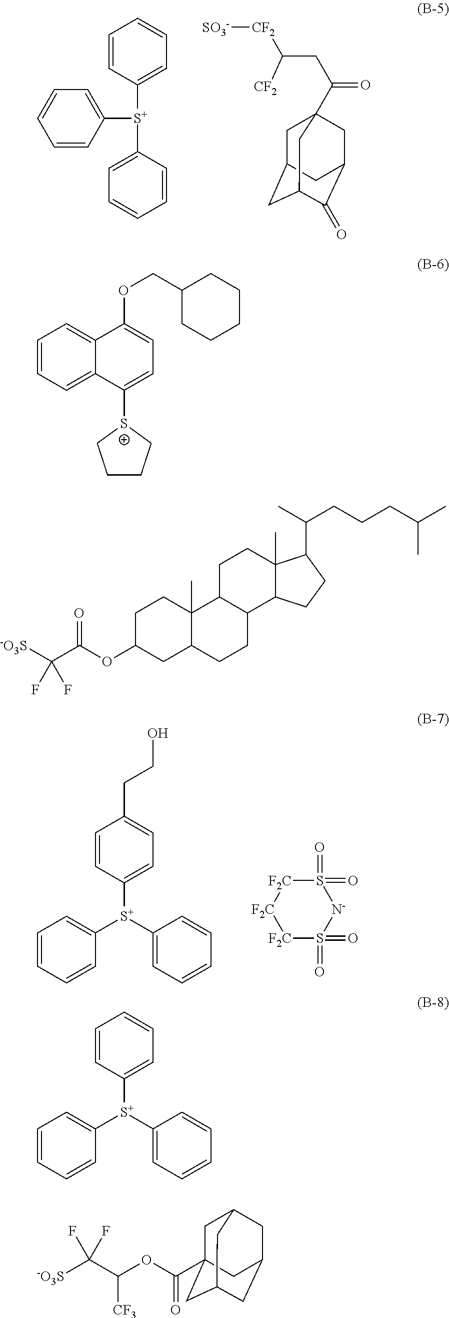

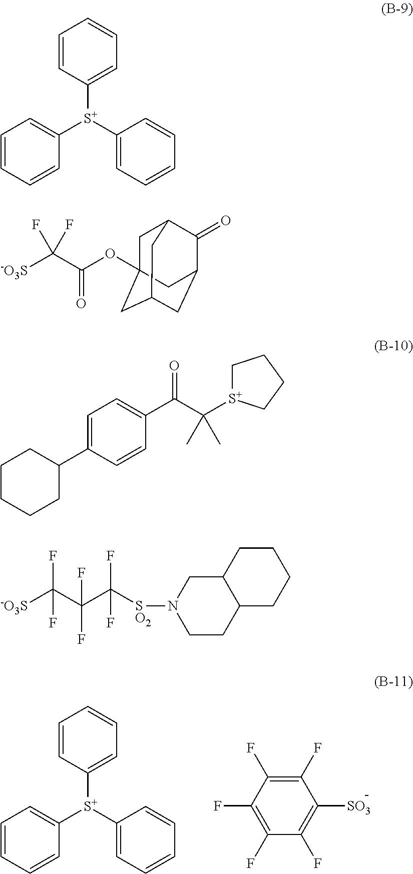

[Basic Compound (E)]

As the basic compound, the following compounds were used.

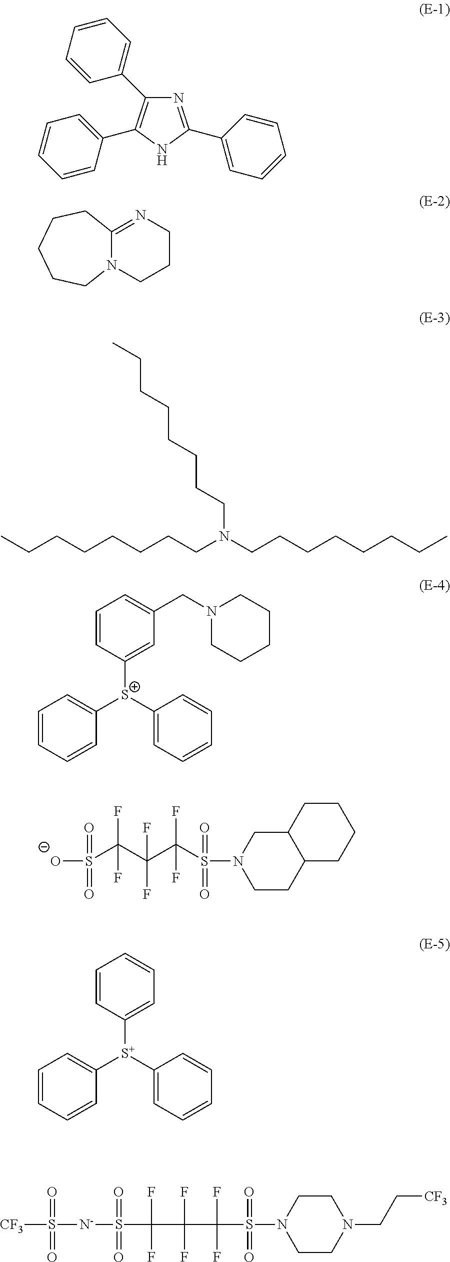

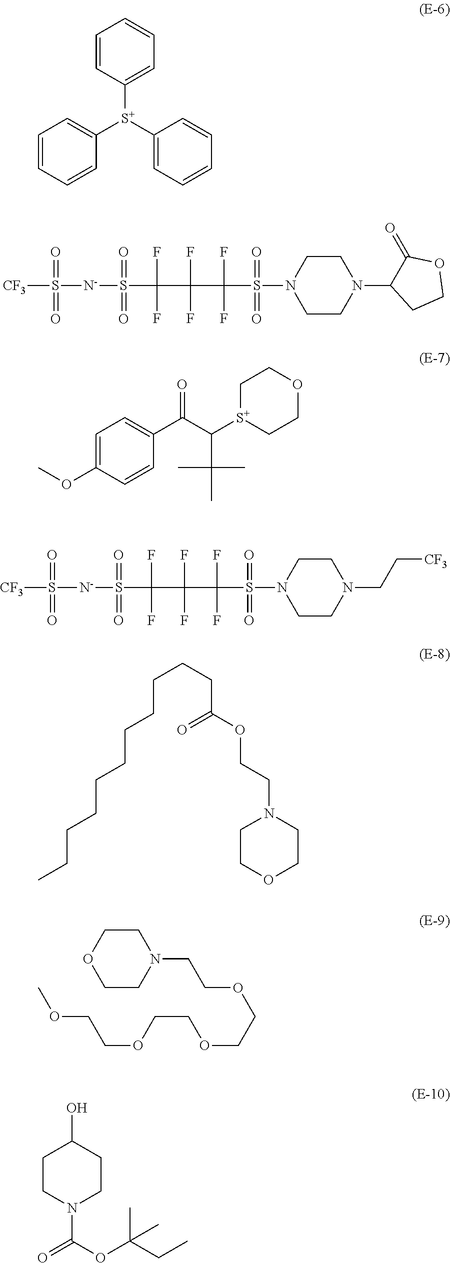

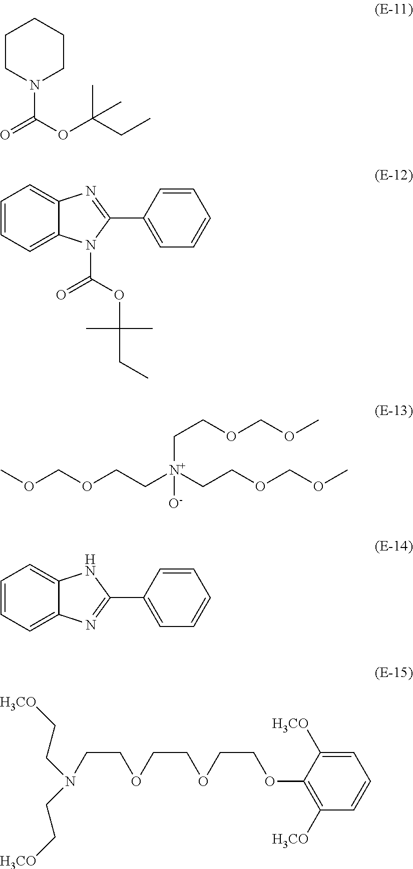

[Solvent (C)]

As the resist solvent, the following solvents were used.

C1: Propylene glycol monomethyl ether acetate

C2: Propylene glycol monomethyl ether

C3: Ethyl lactate

C4: Cyclohexanone

C5: Anisole

[Resist Composition]

The respective components shown in Table 7 were dissolved in the respective solvents shown in the same table. These were filtered using a polyethylene filter having a pore size of 0.03 μm to obtain a resist composition.

TABLE 7

| | | | | Hydro- | |
|---|---|---|---|---|---|
| Compo- | Polymer | Photoacid | Basic | phobic | |
| sition | compound | generator | compound | resin | Solvent |
| N1 | A-1 | B-2 | E-1 | None | C1/C3 |
| | 0.77 g | 0.3 g | 0.03 g | | 60 g/15 g |
| N2 | A-2 | B-2 | E-1 | None | C1/C3 |
| | 0.77 g | 0.2 g | 0.03 g | | 60 g/15 g |
| N3 | A-3 | B-2 | E-1 | None | C1/C3 |
| | 0.77 g | 0.2 g | 0.03 g | | 60 g/15 g |
| N4 | A-4 | B-2 | E-1 | None | C1/C3 |
| | 0.77 g | 0.2 g | 0.03 g | | 60 g/15 g |
| N5 | A-5 | B-2 | E-1 | None | C1/C3 |
| | 0.77 g | 0.2 g | 0.03 g | | 60 g/15 g |
| N6 | A-6 | B-2 | E-1 | None | C1/C3 |
| | 0.77 g | 0.2 g | 0.03 g | | 60 g/15 g |
| N7 | A-7 | B-2 | E-1 | None | C1/C3 |
| | 0.77 g | 0.2 g | 0.03 g | | 60 g/15 g |
| N8 | A-8 | B-2 | E-1 | None | C1/C3 |
| | 0.77 g | 0.2 g | 0.03 g | | 60 g/15 g |
| N9 | A-9 | B-2 | E-1 | None | C1/C3 |
| | 0.77 g | 0.2 g | 0.03 g | | 60 g/15 g |
| N10 | A-10 | B-2 | E-1 | None | C1/C3 |
| | 0.77 g | 0.2 g | 0.03 g | | 60 g/15 g |
| N11 | A-11 | B-2 | E-1 | None | C1/C3 |
| | 0.77 g | 0.2 g | 0.03 g | | 60 g/15 g |
| N12 | A-12 | B-2 | E-1 | None | C1/C3 |
| | 0.77 g | 0.2 g | 0.03 g | | 60 g/15 g |
| N13 | A-13 | B-2 | E-1 | None | C1/C3 |
| | 0.77 g | 0.2 g | 0.03 g | | 60 g/15 g |
| N14 | A-14 | B-2 | E-1 | None | C1/C3 |
| | 0.77 g | 0.2 g | 0.03 g | | 60 g/15 g |
| N15 | A-15 | B-2 | E-1 | None | C1/C3 |
| | 0.77 g | 0.2 g | 0.03 g | | 60 g/15 g |
| N16 | A-16 | B-2 | E-1 | None | C1/C3 |
| | 0.77 g | 0.2 g | 0.03 g | | 60 g/15 g |
| N17 | A-17 | B-2 | E-1/E-3 | None | C1/C3 |
| | 0.77 g | 0.2 g | 0.02 g/0.01 g | | 60 g/15 g |
| N18 | A-18 | B-2 | E-1 | None | C1/C3 |
| | 0.77 g | 0.2 g | 0.03 g | | 60 g/15 g |
| N19 | A-19 | B-2 | E-1 | None | C1/C3 |
| | 0.77 g | 0.2 g | 0.03 g | | 60 g/15 g |
| N20 | A-16 | B-1 | E-15 | 2b | C1/C3 |
| | 0.76 g | 0.2 g | 0.03 g | 0.01 g | 60 g/15 g |
| N21 | A-16 | B-3 | E-14 | None | C1/C2 |
| | 0.77 g | 0.2 g | 0.03 g | | 45 g/30 g |
| N22 | A-1 | B-4 | E-13 | 3b | C1/C3 |
| | 0.76 g | 0.2 g | 0.03 g | 0.01 g | 60 g/15 g |
| N23 | A-16 | B-5/B-6 | E-6 | 4b | C1/C4 |
| | 0.76 g | 0.1 g/0.1 g | 0.03 g | 0.01 g | 67.5 g/7.5 g |
| N24 | A-1 | B-7 | E-11/E-12 | 5b | C1/C3 |
| | 0.76 g | 0.2 g | 0.02 g/0.01 g | 0.01 g | 60 g/15 g |
| N25 | A-1 | B-11 | E-10 | None | C1/C3 |
| | 0.77 g | 0.2 g | 0.03 g | | 60 g/15 g |
| N26 | A-16 | B-9/B-10 | E-4 | None | C1/C3 |
| | 0.77g | 0.1 g/0.1 g | 0.03g | | 60 g/15 g |
| N27 | A-16 | B-9/B-8 | E-8 | None | C1/C3 |
| | 0.77g | 0.1 g/0.1 g | 0.03g | | 60 g/15 g |
| N28 | A-2/A-16 | B-2 | E-7 | None | C1/C3 |
| | 0.4 g/0.37 g | 0.2 g | 0.03 g | | 60 g/15 g |
| N29 | A-16 | B-2 | E-5 | 1b | C1/C2 |
| | 0.76 g | 0.2 g | 0.03 g | 0.01 g | 45 g/30 g |
| N30 | A-16 | B-2 | E-2/E-9 | None | Cl/C5 |
| | 0.77 g | 0.2 g | 0.02 g/0.01 g | | 67.5 g/7.5 g |
| NR1 | R-1 | B-2 | E-1 | None | C1/C3 |
| | 0.77 g | 0.2 g | 0.03 g | | 60 g/15 g |
| NR2 | R-2 | B-2 | E-1 | None | C1/C3 |
| | 0.77 g | 0.2 g | 0.03 g | | 60 g/15 g |
| NR3 | R-3 | B-2 | E-1 | None | C1/C3 |
| | 0.77 g | 0.2 g | 0.03 g | | 60 g/15 g |
| NR4 | R-4 | B-2 | E-1 | None | C1/C3 |
| | 0.77 g | 0.2 g | 0.03 g | | 60 g/15 g |
| NR5 | R-5 | B-2 | E-1 | None | C1/C3 |
| | 0.77 g | 0.2 g | 0.03 g | | 60 g/15 g |

[Composition for Forming Topcoat]

The respective components shown in Table 8 were dissolved in the respective solvents shown in the same table. These were filtered using a polyethylene filter having a pore size of 0.03 μm to obtain a composition for forming a topcoat. Further, in the following table, “MIBC” represents methyl isobutyl carbinol.

TABLE 8

| Composition | | | | |
|---|---|---|---|---|
| for forming | | | | Solvent |
| upper layer | | Photoacid | | (mixing ratio |
| film | Resin | generator | Additive | (mass ratio)) |
| T-1 | V-1 | — | — | MIBC/decane |
| | 1.0 g | — | — | 30/70 |
| T-2 | V-1 | B-2 | — | MIBC/decane |
| | 1.0 g | 0.02 g | — | 50/50 |
| T-3 | V-1 | — | E-11 | MIBC/decane |
| | 1.0 g | — | 0.02 g | 30/70 |
| T-4 | V-1 | — | X1 | MIBC/decane |
| | 1.0 g | — | 0.02 g | 30/70 |
| T-5 | V-1 | B-2 | X1 | MIBC/decane |
| | 1.0 g | 0.2 g | 0.02 g | 30/70 |
| T-6 | V-2 | — | — | MIBC/decane |
| | 1.0 g | — | — | 30/70 |
| T-7 | V-3 | — | — | MIBC/decane |
| | 1.0 g | — | — | 30/70 |
| T-8 | V-4 | — | — | MIBC/decane |
| | 1.0 g | — | — | 30/70 |
| T-9 | V-1:1b | — | — | MIBC/undecane |
| | 0.9 g:0.1 g | — | — | 20/80 |

The resins V-1 to V-4, and 1b, and the additive X1 which were used to obtain the composition for forming a topcoat are shown below. The other additives are the same as those mentioned above.

The compositional ratios, the weight-average molecular weights, and the dispersities of the resins V-1 to V-4, and 1b are shown in Table 9.

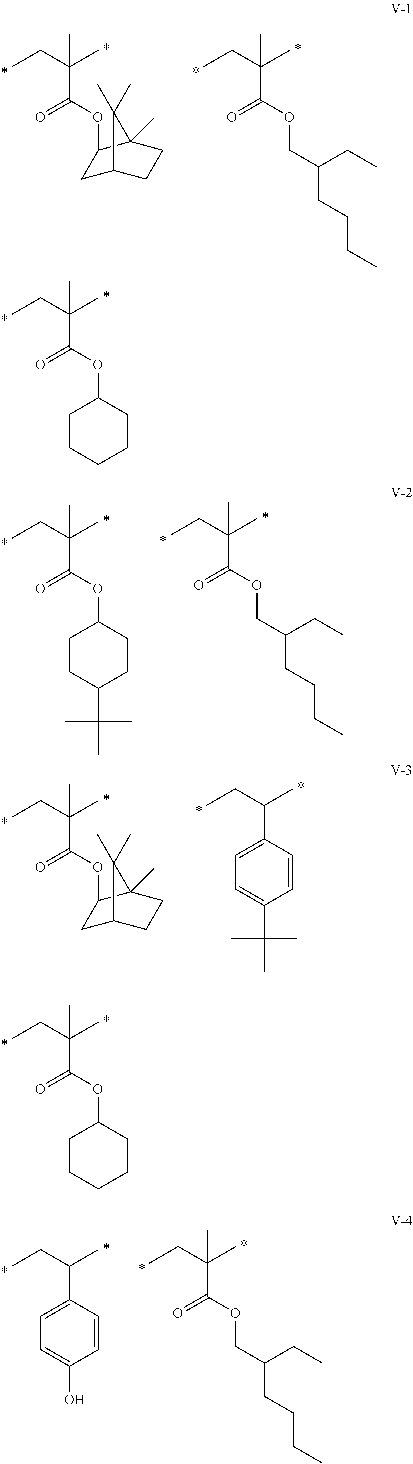

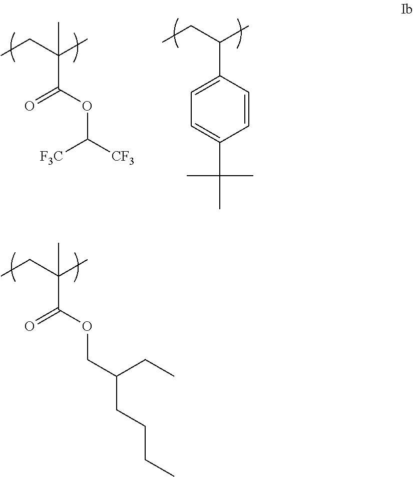

TABLE 9

| Resin for | | | |
|---|---|---|---|
| forming | Compositional | Weight-average | |
| upper | ratio | molecular | |
| layer film | (molar ratio) | weight | Dispersity |
| V-1 | 40/40/20 | 11,000 | 1.45 |
| V-2 | 60/40 | 9,500 | 1.59 |
| V-3 | 40/40/20 | 9,300 | 1.67 |
| V-4 | 30/70 | 12,000 | 1.33 |
| 1b | 40/50/10 | 11,000 | 1.45 |

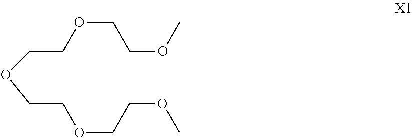

[EUV Exposure Evaluation]

Using the resist compositions described in Table 7, resist patterns were formed by the following procedure.

[Application of Resist Composition and Baking (PB) after Application]

A composition forming an organic film, DUV44 (manufactured by Brewer Science Inc.), was applied onto a 12-inch silicon wafer and baked at 200° C. for 60 seconds to form an organic film with a film thickness of 60 nm. Each of the resist compositions was applied onto the formed organic film and baked under the condition of 120° C. for 60 seconds to form a resist film with a film thickness of 40 nm. Here, 1 inch equals to 0.0254 m.

[Application and Baking (PB) after Application of Composition for Forming Topcoat]

With regard to samples 21E, and 25E to 30E, the composition for forming a topcoat represented in Table 8 was applied on the resist film after baking, and then baked at the PB temperature (unit: ° C.) described in Table 12 for 60 seconds to form an upper layer film (topcoat) with a film thickness of 40 nm.

[Exposure]

<Evaluation of Isolated Pattern>

The wafer prepared above was subjected to EUV exposure with a numerical aperture (NA) of 0.25 and dipole illumination (Dipole 60×, outer sigma of 0.81, and inner sigma of 0.43). Specifically, in order to form an isolated line pattern with a line width of 20 nm, using an exposure mask (line width/space width=1/5), the exposure dose was changed to perform EUV exposure.

[Post-Exposure Bake (PEB)]

After irradiation, the wafer was taken out of the EUV exposing apparatus and immediately baked (PEB) at the temperature described in Table 12 for 60 seconds.

[Development]

Thereafter, development was performed by spray-discharging a developer (23° C.) for 30 seconds at a flow rate of 200 mL/min while rotating the wafer at 50 revolutions (rpm), using a shower-type development device (ADE3000S, manufactured by ACTES). Further, the developer described in Table 10 was used as the developer. The developers used in the respective Examples are shown together in Table 12.

TABLE 10

| | | Compositional |
|---|---|---|
| | | ratio |
| Developer | Name of solvent | (% by mass) |
| SG1 | Butyl acetate | 100 |
| SG2 | Isoamyl acetate | 100 |
| SG3 | Isobutyl isobutanoate | 100 |
| SG4 | Diisobutyl ketone | 100 |
| SG5 | Diisobutyl ketone/undecane | 90/10 |
| SG6 | Diisobutyl ketone/decane | 90/10 |

[Rinsing]

Thereafter, a rinsing treatment was performed by spray-discharging a rinsing liquid (23° C.) for 15 seconds at a flow rate of 200 mL/min while rotating the wafer at 50 revolutions (rpm).

Lastly, the wafer was dried by rotating it at a high speed for 60 seconds at 2,500 revolutions (rpm). Further, the rinsing liquid described in Table 11 was used as the rinsing liquid. The rinsing liquids used in the respective Examples are shown together in Table 12.

TABLE 11

| | | Compositional |
|---|---|---|
| Rinsing | | ratio |
| liquid | Name of solvent | (% by mass) |
| SR1 | Undecane | 100 |
| SR2 | Decane | 100 |
| SR3 | Diisobutyl ketone | 100 |
| SR4 | Diisobutyl ketone/undecane | 90/10 |
| SR5 | Diisobutyl ketone/undecane | 80/20 |
| SR6 | Diisobutyl ketone/undecane | 70/30 |
| SR7 | Diisobutyl ketone/decane | 90/10 |
| SR8 | Diisobutyl ketone/decane | 80/20 |
| SR9 | Diisobutyl ketone/decane | 70/30 |

[Evaluation Test]

The following items were evaluated. Details of the results are shown in Table 12.

<Resolving Power (Pattern Collapse Performance)>

The resolution states of the line pattern exposed at different exposure doses were observed using a scanning electron microscope (S-938011 manufactured by Hitachi Seisakusho, Japan) at a magnification of 200 k, and a minimum line width (unit: nm) with which pattern collapse did not occur within one field of view was determined and used as an indicator of pattern collapse. A smaller numerical value thereof indicates that the pattern collapse performance is better (that is, occurrence of pattern collapse is suppressed).

<Etching Resistance>

An initial film thickness (FT1 (unit: Å)) of the resist film prepared by substantially the same method as above was measured. Then, using a dry etcher (U-621 manufactured by Hitachi High-Technologies Corporation), etching was performed for 20 seconds while supplying a CF₄ gas. Thereafter, the film thickness (FT2 (unit: Å)) of the resist film obtained after etching was measured. Then, a dry etching rate (DE (Unit: Å/sec)) as defined by the following equation was calculated.

[DE(Å/sec)]=(FT1−FT2)/20

The relative merits of DE were evaluated in accordance with the following standard. A smaller value of DE indicates that there is a smaller change in the film thickness due to etching (that is, the etching resistance is excellent). In a practical use, “A” or “B” is preferable.

“A” . . . The dry etching speed is less than 20 Å/sec.

“B” The dry etching speed is 20 Å/sec or more and less than 25 Å/sec.

“C” The dry etching speed is 25 Å/sec or more.

<Outgassing Performance>

The volatile outgassing amount under vacuum exposure was quantified as a thickness reduction rate.

More specifically, exposure was performed at an irradiation dose 2.0 times the irradiation dose during preparation of the pattern as described above, and the film thickness after exposure and before PEB was measured using a light interference type film thickness meter (VM-8200 manufactured by Dainippon Screen Mfg. Co., Ltd.), and a variation rate relative to the film thickness during non-exposure was determined using the following equation. A smaller value of the variation rate indicates a smaller amount of outgas, from which the performance can be considered to be good. In a practical use, “A” or “B” is preferable.

Variation rate (%) in film thickness=[(film thickness during non-exposure−film thickness after exposure)/film thickness during non-exposure]×100

“A” . . . The variation rate in film thickness is less than 5%.

“B” . . . The variation rate in film thickness is 5% or more and less than 10%.

“C” . . . The variation rate in film thickness is 10% or more.

TABLE 12
<Table for Results of EUV Evaluation>

| | | | | | | | Isolated | | |
|---|---|---|---|---|---|---|---|---|---|
| | | | | Upper | Upper layer | | pattern | | |
| | | | Rinsing | layer | film PB | PEB | resolving | | |
| Sample | Composition | Developer | liquid | film | (° C.) | (° C.) | power (nm) | DE | Outgassing |
| 1E | N1 | SG2 | SR1 | — | — | 90 | 14.0 | B | A |
| 2E | N2 | SG2 | SR1 | — | — | 90 | 14.2 | B | A |
| 3E | N3 | SG2 | SR1 | — | — | 90 | 14.3 | A | A |
| 4E | N4 | SG2 | SR1 | — | — | 90 | 14.1 | A | A |
| 5E | N5 | SG2 | SR1 | — | — | 90 | 14.2 | A | A |
| 6E | N6 | SG2 | SR1 | — | — | 90 | 14.4 | A | A |
| 7E | N7 | SG2 | SR1 | — | — | 90 | 14.2 | A | A |
| 8E | N8 | SG2 | SR1 | — | — | 90 | 14.1 | B | A |
| 9E | N9 | SG2 | SR1 | — | — | 90 | 14.0 | A | A |
| 10E | N10 | SG2 | SR1 | — | — | 90 | 14.0 | B | A |
| 11E | N11 | SG2 | SR1 | — | — | 90 | 14.2 | A | A |
| 12E | N12 | SG2 | SR1 | — | — | 90 | 14.4 | A | A |
| 13E | N13 | SG2 | SR1 | — | — | 90 | 14.1 | A | A |
| 14E | N14 | SG2 | SR1 | — | — | 90 | 14.1 | A | A |
| 15E | N15 | SG2 | SR1 | — | — | 90 | 14.2 | B | A |
| 16E | N16 | SG2 | SR1 | — | — | 90 | 14.0 | A | A |
| 17E | N17 | SG2 | SR1 | — | — | 90 | 14.3 | A | A |
| 18E | N18 | SG2 | SR1 | — | — | 90 | 14.3 | A | A |
| 19E | N19 | SG2 | SR1 | — | — | 90 | 14.2 | A | A |
| 20E | N20 | SG3 | SR2 | — | — | 90 | 14.0 | A | A |
| 21E | N21 | SG5 | SR5 | T-2 | 90 | 110 | 14.1 | A | A |
| 22E | N22 | SG5 | SR6 | — | — | 120 | 15.1 | A | A |
| 23E | N23 | SG4 | SR2 | — | — | 90 | 13.6 | A | A |
| 24E | N24 | SG4 | SR8 | — | — | 90 | 15.3 | A | A |
| 25E | N25 | SG6 | SR6 | T-5 | 120 | 90 | 15.4 | A | A |
| 26E | N26 | SG4 | SR6 | T-6 | 90 | 90 | 13.5 | A | A |
| 27E | N27 | SG5 | SR3 | T-7 | 120 | 130 | 14.2 | A | A |
| 28E | N28 | SG4 | SR9 | T-3 | 90 | 90 | 13.6 | A | A |
| 29E | N29 | SG4 | SR6 | T-4 | 90 | 90 | 13.6 | A | A |
| 30E | N30 | SG1 | SR6 | T-1 | 90 | 90 | 14.2 | A | A |
| 1ER | NR1 | SG1 | SR1 | — | — | 90 | 17.3 | B | C |
| 2ER | NR2 | SG1 | SR1 | — | — | 110 | 20.2 | B | A |
| 3ER | NR3 | SG1 | SR1 | — | — | 110 | 17.5 | C | A |
| 4ER | NR4 | SG1 | SR1 | — | — | 110 | 17.3 | A | A |
| 5ER | NR5 | SG1 | SR1 | — | — | 110 | 15.5 | C | A |

As shown in Table 12, samples 1E to 30E were excellent in pattern collapse performance and etching resistance.

In contrast, the sample 1ER in which a composition NR1 containing a resin (R-1) having no repeating unit (b) represented by General Formula (AI) was used, the sample 2ER in which a composition NR2 containing a resin (R-2) having no repeating unit (b) represented by General Formula (AI) was used, and the sample 3ER in which a composition NR3 containing a resin (R-3) having a content of the repeating unit (a) of less than 55% by mole with respect to all the repeating units of the resin (1), and having no repeating unit (b) represented by General Formula (AI) was used were insufficient in pattern collapse performance and etching resistance. In addition, the sample 4ER in which a resin (R-4) having no repeating unit (b) represented by General Formula (AI) was used was insufficient in pattern collapse performance.

In addition, the sample 5ER in which a resin (R-5) having a content of the repeating unit (a) of less than 55% by mole with respect to all the repeating units of the resin (1), and including the repeating unit (b) represented by General Formula (AI) was used was insufficient in etching resistance.

[Evaluation on EB Exposure]

Using the resist composition described in Table 7, a resist pattern was formed by the following procedure.

[Application and Baking (PB) after Application of Resist Composition]

A composition forming an organic film, DUV44 (manufactured by Brewer Science Inc.), was applied onto a 6-inch silicon wafer and baked at 200° C. for 60 seconds to form an organic film with a film thickness of 60 nm. Each of the resist compositions was applied thereonto and baked under the condition of 120° C. for 60 seconds to form a resist film with a film thickness of 40 nm.

[Exposure]

<Evaluation of Isolated Line Pattern>

The wafer prepared above was subjected to lithography using an electron beam irradiating apparatus (JBX6000FS/E manufactured by JEOL, Ltd.; acceleration voltage of 50 keV) such that an isolated line with line width/space width=1:100 and a line width of 20 nm were formed.

[Post-Exposure Baking (PEB)]

After irradiation, the wafer was taken out of the electron beam irradiating apparatus, and immediately heated on a hot plate under the conditions of the temperature described in Table 13 for 60 seconds.

[Development]

Development was performed by spray-discharging a developer (23° C.) for 30 seconds at a flow rate of 200 mL/min while rotating the wafer at 50 revolutions (rpm), using a shower-type development device (ADE3000S, manufactured by ACTES).

[Rinsing]

Thereafter, a rinsing treatment was performed by spray-discharging a rinsing liquid (23° C.) for 15 seconds at a flow rate of 200 mL/min while rotating the wafer at 50 revolutions (rpm).

Lastly, the wafer was dried by rotating it at a high speed for 60 seconds at 2,500 revolutions (rpm).

[Evaluation Test]

For the same item as “Evaluation of EUV Exposure” as described above, the resist pattern was evaluated by the same method as in the section except that “S-9220” (manufactured by Hitachi Seisakusho, Japan) was used as a scanning electron microscope. Further, with regard to the etching resistance and the outgassing performance, the evaluations were also by substantially the same method as in “Evaluation on EUV Exposure” as described above. Details of the results are shown in Table 13.

TABLE 13
<Table for Results of EB Evaluation>

| | | | | | Isolated | | |
|---|---|---|---|---|---|---|---|
| | | | | | pattern resolving | | |
| Sample | Composition | Developer | Rinsing liquid | PEB (° C.) | power (nm) | DE | Outgassing |
| 1B | N3 | SG4 | SR1 | 90 | 14.2 | B | A |
| 2B | N3 | SG4 | SR2 | 90 | 14.3 | B | A |
| 3B | N3 | SG4 | SR5 | 90 | 14.2 | A | A |
| 4B | N3 | SG4 | SR6 | 90 | 14.1 | A | A |
| 5B | N3 | SG5 | SR2 | 90 | 14.3 | A | A |
| 6B | N3 | SG4 | SR8 | 90 | 14.0 | A | A |
| 7B | N3 | SG2 | SR1 | 90 | 14.2 | A | A |
| 8B | N4 | SG4 | SR1 | 90 | 14.0 | B | A |
| 9B | N5 | SG4 | SR1 | 90 | 14.3 | A | A |
| 10B | N6 | SG4 | SR1 | 90 | 14.2 | B | A |
| 11B | N6 | SG3 | SR1 | 90 | 14.3 | A | A |
| 12B | N7 | SG4 | SR1 | 90 | 14.0 | A | A |
| 13B | N8 | SG4 | SR1 | 90 | 14.0 | A | A |
| 14B | N10 | SG4 | SR1 | 90 | 14.2 | A | A |
| 15B | N11 | SG4 | SR1 | 90 | 14.3 | B | A |
| 16B | N12 | SG4 | SR1 | 90 | 14.1 | A | A |
| 17B | N13 | SG2 | SR1 | 90 | 14.2 | A | A |
| 18B | N13 | SG2 | SR4 | 90 | 14.3 | A | A |
| 19B | N13 | SR4 | SR4 | 90 | 14.1 | A | A |
| 20B | N15 | SG2 | SR1 | 110 | 14.1 | A | A |
| 21B | N15 | SG4 | SR1 | 110 | 14.3 | A | A |
| 22B | N15 | SG4 | SR2 | 110 | 15.1 | A | A |
| 23B | N17 | SG4 | SR4 | 110 | 13.5 | A | A |
| 24B | N18 | SG4 | SR7 | 110 | 15.3 | A | A |
| 25B | N23 | SG4 | SR1 | 85 | 15.2 | A | A |
| 26B | N25 | SG4 | SR1 | 85 | 13.6 | A | A |
| 27B | N28 | SG4 | SR1 | 85 | 14.1 | A | A |
| 28B | N26 | SG4 | SR1 | 90 | 13.4 | A | A |
| 29B | N29 | SG4 | SR1 | 90 | 13.5 | A | A |
| 30B | N30 | SG4 | SR1 | 90 | 14.4 | A | A |
| 1BR | NR1 | SG1 | SR1 | 90 | 17.5 | B | C |
| 2BR | NR2 | SG1 | SR1 | 90 | 20.4 | B | A |
| 3BR | NR3 | SG1 | SR1 | 110 | 17.5 | C | A |
| 4BR | NR4 | SG1 | SR1 | 110 | 17.6 | A | A |
| SBR | NR5 | SG1 | SR1 | 110 | 15.5 | C | A |

As shown in Table 13, samples 1B to 30B were excellent in pattern collapse performance and etching resistance.

In contrast, the sample 1BR in which a composition NR1 containing a resin (R-1) having no repeating unit (b) represented by General Formula (AI) was used, the sample 2BR in which a composition NR2 containing a resin (R-2) having no repeating unit (b) represented by General Formula (AI) was used, and the sample 3BR in which a composition NR3 containing a resin (R-3) having a content of the repeating unit (a) of less than 55% by mole with respect to all the repeating units of the resin (1), and having no repeating unit (b) represented by General Formula (AI) was used were insufficient in pattern collapse performance and etching resistance. In addition, the sample 4BR in which a resin (R-4) having no repeating unit (b) represented by General Formula (AI) was used was insufficient in pattern collapse performance.

Furthermore, the sample 5BR in which a resin (R-5) having a content of the repeating unit (a) of less than 55% by mole with respect to all the repeating units of the resin (1), and including the repeating unit (b) represented by General Formula (AI) was used was insufficient in etching resistance.

In addition, also in the EB exposure evaluation shown in Table 13, the same tendency as in the EUV exposure evaluation (Table 12) was shown.

By the resist composition, the same effect was also obtained with KrF exposure.

What is claimed is:

1. A pattern forming method comprising:
(1) forming a film using an actinic ray-sensitive or radiation-sensitive resin composition;
(2) exposing the film with actinic rays or radiation; and
(3) developing the exposed film using a developer containing an organic solvent,
wherein the actinic ray-sensitive or radiation-sensitive resin composition contains an acid-decomposable resin (1) having a repeating unit (a) having an aromatic ring and a repeating unit (b) represented by General Formula (AI), and
the content of the repeating unit (a) is 55% by mole or more with respect to all the repeating units of the acid-decomposable resin (1), 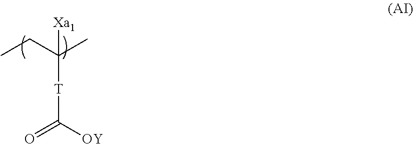
in General Formula (AI),
Xa₁ represents a hydrogen atom or an alkyl group,
T represents a single bond or a divalent linking group,
Y is a group that leaves by the action of an acid, and represents a group represented by General Formula (Y1),
—C(Rx1)(Rx2)(Rx3) General Formula (Y1):
in General Formula (Y1), Rx1 to Rx3 each independently represent an alkyl group or a cycloalkyl group, the total number of carbon atoms of Rx1 to Rx3 is 10 or less, two of Rx1 to Rx3 are bonded to form a ring, and the ring may include an ether bond or ester bond in the ring.

2. The pattern forming method according to claim 1,
wherein the acid-decomposable resin (1) has a repeating unit represented by General Formula (I) as the repeating unit (a), 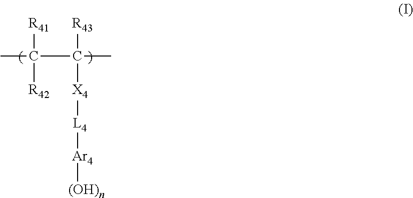
in General Formula (I),
R₄₁, R₄₂, and R₄₃ each independently represent a hydrogen atom, an alkyl group, a cycloalkyl group, a halogen atom, a cyano group, or an alkoxycarbonyl group, provided that R₄₂ may be bonded to Ar₄ to form a ring, and R₄₂ in such a case represents a single bond or an alkylene group,
X₄ represents a single bond, —COO—, or —CONR₆₄—, and R₆₄ represents a hydrogen atom or an alkyl group,
L₄ represents a single bond or a divalent linking group,
Ar₄ represents an (n+1)-valent aromatic ring group, and in a case where Ar₄ is bonded to R₄₂ to form a ring, Ar₄ represents an (n+2)-valent aromatic ring group, and
n represents an integer of 1 to 5.

3. The pattern forming method according to claim 1,
wherein the total number of carbon atoms of Rx1 to Rx3 in General Formula (Y1) of the repeating unit (b) is 8 or less.

4. The pattern forming method according to claim 1,
wherein the ring formed by the bonding of two of Rx1 to Rx3 in General Formula (Y1) of the repeating unit (b) is a 5- or 6-membered ring.

5. The pattern forming method according to claim 1,
wherein the ring formed by the bonding of two of Rx1 to Rx3 in General Formula (Y1) of the repeating unit (b) is a monocycle.

6. The pattern forming method according to claim 1,
wherein the content of the repeating unit (a) of the acid-decomposable resin (1) is 70% by mole or more with respect to all the repeating units of the acid-decomposable resin (1).

7. The pattern forming method according to claim 2,
wherein the content of the repeating unit (a) of the acid-decomposable resin (1) is 70% by mole or more with respect to all the repeating units of the acid-decomposable resin (1).

8. The pattern forming method according to claim 3,
wherein the content of the repeating unit (a) of the acid-decomposable resin (1) is 70% by mole or more with respect to all the repeating units of the acid-decomposable resin (1).

9. The pattern forming method according to claim 4,
wherein the content of the repeating unit (a) of the acid-decomposable resin (1) is 70% by mole or more with respect to all the repeating units of the acid-decomposable resin (1).

10. The pattern forming method according to claim 5,
wherein the content of the repeating unit (a) of the acid-decomposable resin (1) is 70% by mole or more with respect to all the repeating units of the acid-decomposable resin (1).

11. The pattern forming method according to claim 1,
wherein the content of the repeating unit (a) of the acid-decomposable resin (1) is 65 to 90% by mole with respect to all the repeating units of the acid-decomposable resin (1).

12. The pattern forming method according to claim 1,
wherein the repeating unit (a) of the acid-decomposable resin (1) includes a repeating unit having a phenolic hydroxyl group.

13. The pattern forming method according to claim 12,
wherein the content of the repeating unit having a phenolic hydroxyl group is 30 to 85% by mole with respect to all the repeating units of the acid-decomposable resin (1).

14. The pattern forming method according to claim 12,
wherein the repeating unit having a phenolic hydroxyl group is represented by formula (p1), 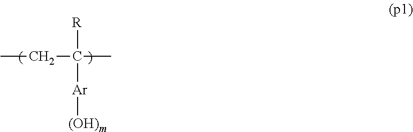
in formula (p1), R represents a hydrogen atom, a halogen atom, or a linear or branched alkyl group having 1 to 4 carbon atoms, a plurality of R's may be the same as or different from each other, Ar represents an aromatic ring, m represents an integer of 1 to 5.

15. The pattern forming method according to claim 1,
wherein T in General Formula (AI) of the repeating unit (b) represents an arylene group.

16. The pattern forming method according to claim 1,
wherein the actinic ray-sensitive or radiation-sensitive resin composition further includes a compound that generates an acid with actinic rays or radiation.

17. The pattern forming method according to claim 1,
wherein the actinic rays or radiation is an electron beam or an extreme ultraviolet ray.

18. The pattern forming method according to claim 1,
wherein the organic solvent is a ketone-based solvent or an ester-based solvent.

19. The pattern forming method according to claim 1, further comprising rinsing the developed film after developing.

20. A method for manufacturing an electronic device, comprising the pattern forming method according to claim 1.
